(19) United States
(12) Patent Application Publication
(10) Pub. No.: US 2021/0232977 A1
(43) Pub. Date: Jul. 29, 2021

(54) RESONANT MACHINE LEARNING ALGORITHMS, ARCHITECTURE AND APPLICATIONS

(71) Applicants: Shantanu Chakrabartty, St. Louis, MO (US); Oindrila Chatterjee, St. Louis, MO (US)

(72) Inventors: Shantanu Chakrabartty, St. Louis, MO (US); Oindrila Chatterjee, St. Louis, MO (US)

(73) Assignee: Washington University, St. Louis, MO (US)

(21) Appl. No.: 16/999,082

(22) Filed: Aug. 21, 2020

Related U.S. Application Data
(60) Provisional application No. 62/889,489, filed on Aug. 20, 2019.

(51) Int. Cl. G06N 20/10

(52) U.S. Cl. CPC G06N 20/10

(57) ABSTRACT

Devices, systems, and methods related to an energy-efficient machine learning framework which exploits structural and functional similarities between a machine learning network and a general electrical network satisfying the Tellegen's theorem are described.

### CROSS-REFERENCE TO RELATED APPLICATIONS

This application claims priority from U.S. Provisional Application Ser. No. 62/889,489 filed on Aug. 20, 2019, which is incorporated herein by reference in its entirety.

### STATEMENT REGARDING FEDERALLY SPONSORED RESEARCH OR DEVELOPMENT

This invention was made with government support under ECCS: 1550096 awarded by the National Science Foundation. The government has certain rights in the invention.

### FIELD OF THE DISCLOSURE

The present disclosure generally relates to machine learning methods. In particular the present disclosure relates to an energy-efficient learning framework which exploits structural and functional similarities between a machine learning network and a general electrical network satisfying the Tellegen's theorem.

### BACKGROUND OF THE DISCLOSURE

From an energy point of view, the dynamics of an electrical network is similar to that of a machine learning network. Both the networks evolve over a conservation manifold to self-optimize themselves to a low-energy state. In literature, this analogy has served as the basis for energy-based learning models where the network energy landscape is designed to match the learning objective function. The network variables then evolve according to some physical principles subject to network constraints to seek out an energy optimal state. Some notable examples of energy-based learning models include the Ising models, the Hopfield network, the Boltzmann machine and its variants. However, most of these formulations assume that the energy being minimized in the network is dissipative in nature, whereas in a physical electrical network, the total power S_{N} (also known as the apparent power) comprises not only the dissipative component (also referred to as the active-power) but also a latent or stored non-dissipative component (also referred to as the reactive-power). This is illustrated in FIG. 1(a) and can be mathematically expressed as:

Total Network Power S_{N}=Active Power P_{N}+j×Reactive Power Q_{N} Eqn. (1)

where j=\sqrt{−1} denotes the imaginary component.

While the active-power P_{N} represents the rate-of-energy loss in the network, the reactive-power Q_{N} represents the rate of change in stored energy in the network's electric and magnetic fields (typically modeled as lumped capacitive and inductive elements). In the design of electrical networks, reactive-power is generally considered to be a nuisance since it represents the latent power that does not perform any useful work. However, from the point of view of learning, the reactive-power could be useful not only for storing the network or learned parameters, but also to improve the dynamics of the network during learning.

Sonification, or the encoding of information in meaningful audio signatures, has emerged as a potential candidate for augmenting or replacing its visual counterpart because of various advantages it presents. Standard sonification methods existing in literature involve solving a learning or predictive task on the data and subsequently mapping the output to an audio signature, which is then used by the end user to take a decision. In this paper, we present a novel framework for sonification of high-dimensional data using the complex growth transform dynamical system model introduced in our previous work. In contrast to traditional sonification methods, the proposed technique integrates both the learning (or more generally, optimization) and sonification stages into the same module. The growth transform based sonification algorithm takes as input the data and optimization parameters underlying the learning or prediction task on one hand, and psychoacoustic parameters defined by the user on the other. Finally, it outputs a single-channel human-recognizable audio signature that encodes the high-dimensional space of the data, as well as the complexity of the optimization problem. We have also shown how different sonification strategies can be adopted, based on whether we want to use an existing audio clip, or customize the framework to create our own audio signal for sonification. Experiments on synthetic and real-world datasets of both static and time-varying nature demonstrate how the model reduces high-dimensional data into a low-bandwidth audio signature, which could potentially aid the end user in the decision-making process.

Other objects and features will be in part apparent and in part pointed out hereinafter.

### SUMMARY OF THE DISCLOSURE

In various aspects, a resonant machine learning processor is described that includes a network of internal nodes. Each internal node includes an LC tank with a variable capacitor with capacitance Cᵢ connected electrically in parallel with a variable inductor with inductance Lᵢ. Each internal node electrically connected to a ground node and to each remaining internal node of the network of internal nodes. Each node further includes a normalized voltage phasor Vᵢ, a normalized current phasor Iᵢ, and a phase angle ϕᵢ defined across each node of the network of internal nodes. During learning a plurality of learning parameters, the capacitance Cᵢ and the inductance Lᵢ of each node is modulated to adjust a relative magnitude of the normalized voltage phasor Vᵢ and the normalized current phasor Iᵢ to optimize a total active network power and to maintain a total network reactive network power at essentially zero until a steady state network resonance is achieved. After completion of learning, the steady state network resonance is maintained, and the plurality of learned network parameters are stored and sustained using resonant magnetic fields and resonant magnetic fields produced within the LC tanks of the network in internal nodes. The steady state network resonance is maintained without dissipating power. Optimizing the total active network power and maintaining the total network reactive network power at essentially zero may include modulating the capacitance Cᵢ and the inductance Lᵢ of each internal node according to a system objective function subject to at least one constraint:

$${min}_{\{ \vert {V}_{i} \vert , \vert {I}_{i} \vert , {ϕ}_{i} \} \}} ℒ ( \{ \vert {V}_{i} \vert , \vert {I}_{i} \vert , {ϕ}_{i} \} ) = ℋ ( \{ \vert {V}_{i} \vert , \vert {I}_{i} \vert \} ) + h Ψ ( \{ \vert {V}_{i} \vert , \vert {I}_{i} \vert \} ) + β {\sum }_{i = 1}^{N} \vert {V}_{i} {\vert}^{2} \vert {I}_{i} {\vert}^{2} {cos}^{2} {ϕ}_{i}$$

subject to Σᵢ₌₁^{N}(|Vᵢ|²+|Iᵢ|²)=1, |ϕᵢ|≤π, β≥0, where [symbol] is a loss function defined over the plurality of learning parameters αᵢ=|Vᵢ|²+|Iᵢ|²; Ψ is a regularization or penalty function; h is a hyperparameter that acts as a tradeoff between [symbol] (·) and Ψ(·); β is a hyperparameter that acts as a tradeoff between convergence of the network of internal nodes and dissipation of active power Σᵢ₌₁^{N}|Vᵢ∥Iᵢ| cos ϕᵢ; and N is the number of internal nodes.

In some aspects, the resonant machine learning processor may be a resonant support vector machine processor. Optimizing the total active network power and maintaining the total network reactive network power at essentially zero comprises modulating the capacitance Cᵢ and the inductance Lᵢ of each internal node according to a system objective function [symbol] _{SVM} subject to at least one constraint, comprising:

$${min}_{\{ \vert {V}_{i} \vert , \vert {I}_{i} \vert , {ϕ}_{i} \} \}} {ℒ}_{SVM} = \frac{1}{2} {\sum }_{i = 1}^{N} {\sum }_{j = 1}^{N} ( {\vert {V}_{i} \vert}^{2} + {\vert {I}_{i} \vert}^{2} ) K ( {x}_{i} , {x}_{j} ) \times ( {\vert {V}_{j} \vert}^{2} + {\vert {I}_{j} \vert}^{2} ) + h {\sum }_{i = 1}^{N} Ψ ( \vert {V}_{i} \vert , \vert {I}_{i} \vert , v ) + β {\sum }_{i = 1}^{N} {\vert {V}_{i} \vert}^{2} {\vert {I}_{i} \vert}^{2} {cos}^{2} {ϕ}_{i}$$

subject to Σᵢ₌₁^{N}, (|Vᵢ|²+|Iᵢ|²)=1, |ϕᵢ|≤π, β≥0, where the system function [symbol] _{SVM} is defined over a set of learning variables αᵢ=|Vᵢ|²+|Iᵢ|²; K(xᵢ, xᵢ) is a kernel function defined in terms of X=[xᵢ, . . . , xⱼ, . . . , x_{N}]; X is a D-dimensional input dataset of size N; v∈(0,1) is a parameter specifying a size of a control surface; Ψ is a penalty function; h defines a steepness of the penalty function; β is a hyperparameter that acts as a tradeoff between convergence of the plurality of nodes and dissipation of active power Σᵢ₌₁^{N}|Vᵢ∥Iᵢ|cos ϕᵢ; and N is the number of internal nodes.

In various other aspects, a resonant machine-learning network system is described that includes a computing device with at least one processor and a memory storing a plurality of modules. Each module includes instructions executable on the at least one processor. The plurality of modules include a resonant machine learning network module to define a plurality of interconnected nodes. Each node includes a normalized voltage phasor Vᵢ, a normalized current phasor Iᵢ, and a phase angle ϕᵢ defined across each node of the plurality of nodes. The plurality of modules further include a complex growth transform module to update the plurality of nodes according to complex growth transform model, and a resonant network convergence module to converge the plurality of nodes to a steady state solution by optimizing a system objective function [symbol] subject to at least one constraint. The system objective function [symbol] subject to at least one constraint may be given by:

$${min}_{\{ \vert {V}_{i} \vert , \vert {I}_{i} \vert , {ϕ}_{i} \} \}} ℒ ( \{ \vert {V}_{i} \vert , \vert {I}_{i} \vert , {ϕ}_{i} \} ) = ℋ ( \{ \vert {V}_{i} \vert , \vert {I}_{i} \vert \} ) + h Ψ ( \{ \vert {V}_{i} \vert , \vert {I}_{i} \vert \} ) + β {\sum }_{i = 1}^{N} {\vert {V}_{i} \vert}^{2} {\vert {I}_{i} \vert}^{2} {cos}^{2} {ϕ}_{i}$$

subject to:
Σᵢ₌₁^{N}, (|Vᵢ|²+|Iᵢ|²)=1, |ϕᵢ|≤π, β≥0, where [symbol] is a loss function defined over a set of learning variables αᵢ=|Vᵢ|²+|Iᵢ|²; Ψ is a regularization or penalty function; h is a hyperparameter that acts as a tradeoff between [symbol] (·) and Ψ(·); β is a hyperparameter that acts as a tradeoff between convergence of the plurality of nodes and dissipation of active power Σᵢ₌₁^{N}|Vᵢ∥Iᵢ|cos ϕᵢ; and N is the number of interconnected nodes.

In some aspects, the complex growth transform model may include a system of update equations given by

$$\frac{\partial {V}_{i} ( t )}{\partial t} = j ω {σ}_{{V}_{i}} ( t ) {V}_{i} ( t ) - Δ {σ}_{{V}_{i}} ( t ) {V}_{i} ( t ) ;$$

$$\frac{\partial {I}_{i} ( t )}{\partial t} = j ( ω + {ω}_{{ϕ}_{i}} ) {σ}_{{I}_{i}} ( t ) {I}_{i} ( t ) - Δ {σ}_{{I}_{i}} ( t ) {I}_{i} ( t ) ; and$$

$${τ}_{i} {ω}_{{ϕ}_{i}} + {ϕ}_{i} ( t ) = {g}_{{ϕ}_{i}} ( t ) ; where \text{:}$$

$${σ}_{{V}_{i}} ( t ) = \sqrt{\frac{1}{{V}_{i}^{*} η} ( - \frac{\partial ℒ}{\partial {V}_{i}} + λ {V}_{i}^{*} )} ;$$

$${σ}_{{I}_{i}} ( t ) = \sqrt{\frac{1}{{I}_{i}^{*} η} ( - \frac{\partial ℒ}{\partial {I}_{i}} + λ {I}_{i}^{*} )} , {ω}_{{ϕ}_{i}} = \frac{d {ϕ}_{i} ( t )}{d t} , \\ Δ {σ}_{{V}_{i}} ( t ) = 1 - {σ}_{{V}_{i}} ( t ) , \\ {Δσ}_{{I}_{i}} ( t ) = 1 - {σ}_{{I}_{i}} ( t ) , {g}_{{ϕ}_{i}} ( t ) = π \frac{λ {ϕ}_{i} - π \frac{\partial ℒ}{\partial {ϕ}_{i}}}{- {ϕ}_{i} \frac{\partial ℒ}{\partial {ϕ}_{i}} + λ π} , \\ η = {\sum }_{k = 1}^{N} ( {V}_{k} ( - \frac{\partial ℒ}{\partial {V}_{k}} + λ {V}_{k}^{*} ) + {I}_{k} ( - \frac{\partial ℒ}{\partial {I}_{k}} + λ {I}_{k}^{*} ) )$$

ω is an angular frequency of the plurality of nodes, τᵢ is a time constant associated with the development of ϕᵢ, and ( )* denotes a complex conjugate of a phasor.

The complex growth transform model may also include an annealing procedure that includes providing a value of β according to an annealing schedule defining a plurality of values of β at a plurality of times during optimization of the system objective function [symbol] subject. The annealing schedule may be selected from one of a constant schedule wherein the value of β remains constant, a switching schedule wherein the value of β switches from a first value to a second value at a switching time, and a logistic schedule, wherein the value of β changes according to a logistic curve.

In some additional aspects, the plurality of interconnected nodes may be divided into M subgroups where each node includes the voltage phasor Vᵢₖ, the current phasor Iᵢₖ, and the phase angle ϕᵢₖ defined across each node k=1, . . . , M. In these additional aspects, the system objective function [symbol] subject to at least one constraint may be given by:

$${min}_{\{ \vert {V}_{i k} \vert , \vert {I}_{i k} \vert , {ϕ}_{i k} \} \}} ℒ ( \{ \vert {V}_{i k} \vert , \vert {I}_{i k} \vert , {ϕ}_{i k} \} ) = ℋ ( \{ \vert {V}_{i k} \vert , \vert {I}_{i k} \vert \} ) + h Ψ ( \{ \vert {V}_{i k} \vert , \vert {I}_{i k} \vert \} ) + β {\sum }_{i = 1}^{N} {\vert {V}_{i k} \vert}^{2} {\vert {I}_{i k} \vert}^{2} {cos}^{2} {ϕ}_{i k}$$

subject to Σᵢ₌₁^{N}^{ₖ}(|Vᵢₖ|²+|Iᵢₖ|²)=1, |ϕᵢₖ|≤π, and β≥0, where [symbol] is a loss function defined over the set of learning variables αᵢₖ=|Vᵢₖ|²+|Iᵢₖ|²; Ψ is a regularization or penalty function; h is a hyperparameter that acts as a tradeoff between [symbol] (·) and Ψ(·); β is a hyperparameter that acts as a tradeoff between convergence of the plurality of nodes and dissipation of active power Σᵢ₌₁^{N}|Vᵢₖ∥Iᵢₖ| cos ϕᵢₖ; and Nₖ is the number of interconnected nodes within the k^{th} subgroup.

Also in these additional aspects, the complex growth transform model may include a system of update equations given by:

$$\frac{\partial {V}_{ik} ( t )}{\partial t} = j {ω}_{k} {σ}_{{V}_{ik}} ( t ) {V}_{ik} ( t ) - Δ {σ}_{{V}_{ik}} ( t ) {V}_{ik} ( t ) ;$$

$$\frac{\partial {I}_{ik} ( t )}{\partial t} = j ( {ω}_{k} + {ω}_{{ϕ}_{ik}} ) {σ}_{{I}_{ik}} ( t ) {I}_{ik} ( t ) - Δ {σ}_{{I}_{ik}} ( t ) {I}_{ik} ( t ) ; and$$

$${τ}_{ik} {ω}_{{ϕ}_{ik}} + {ϕ}_{ik} ( t ) = {g}_{{ϕ}_{ik}} ( t ) ; wherein$$

$${σ}_{{V}_{ik}} ( t ) = \sqrt{\frac{1}{{V}_{ik}^{*} {η}_{k}} ( - \frac{\partial ℒ}{\partial {V}_{ik}} + λ {V}_{ik}^{*} )} ;$$

$${σ}_{{I}_{ik}} ( t ) = \sqrt{\frac{1}{{I}_{ik}^{*} {η}_{k}} ( - \frac{\partial ℒ}{\partial {I}_{ik}} + λ {I}_{ik}^{*} )} ; {ω}_{{ϕ}_{ik}} = \frac{d {ϕ}_{ik} ( t )}{d t} ;$$

$$Δ {σ}_{{V}_{ik}} ( t ) = 1 - {σ}_{{V}_{ik}} ( t ) ;$$

$${Δσ}_{{I}_{ik}} ( t ) = 1 - {σ}_{{I}_{i} k} ( t ) , {g}_{{ϕ}_{ik}} ( t ) = π \frac{λ {ϕ}_{ik} - π \frac{\partial ℒ}{\partial {ϕ}_{ik}}}{- {ϕ}_{ik} \frac{\partial ℒ}{\partial {ϕ}_{ik}} + λ π} ;$$

$${η}_{k} = {\sum }_{l = 1}^{{N}_{k}} ( {V}_{lk} ( - \frac{\partial ℒ}{\partial {V}_{lk}} + λ {V}_{lk}^{*} ) + {I}_{lk} ( - \frac{\partial ℒ}{\partial {I}_{lk}} + λ {I}_{lk}^{*} ) ) ;$$

ωₖ is an angular frequency of the nodes within the k^{th} subgroup; τᵢₖ is a time constant associated with the development of ϕᵢₖ; and ( )* denotes a complex conjugate of a phasor.

In other additional aspects, the resonant machine-learning network system may be a resonant SVM system with a SVM system objective function [symbol] S_{VM} subject to at least one constraint given by:

$${min}_{\{ \vert {V}_{i} \vert , \vert {I}_{i} \vert , {ϕ}_{i} \} \}} {ℒ}_{SVM} = \frac{1}{2} {\sum }_{i = 1}^{N} {\sum }_{j = 1}^{N} ( {\vert {V}_{i} \vert}^{2} + {\vert {I}_{i} \vert}^{2} ) K ( {x}_{i} , {x}_{j} ) \times ( {\vert {V}_{j} \vert}^{2} + {\vert {I}_{j} \vert}^{2} ) + h {\sum }_{i = 1}^{N} Ψ ( \vert {V}_{i} \vert , \vert {I}_{i} \vert , v ) + β {\sum }_{i = 1}^{N} {\vert {V}_{i} \vert}^{2} {\vert {I}_{i} \vert}^{2} {cos}^{2} {ϕ}_{i}$$

subject to Σᵢ₌₁^{N}(|Vᵢ|²+|Iᵢ|²)=1, |ϕᵢ|≤π, β≥0, where the SVM system objective function [symbol] _{SVM} is defined over a set of learning variables αᵢ=|Vᵢ|²+|Iᵢ|²; K(xᵢ,xⱼ) is a kernel function defined in terms of X=[xᵢ, . . . , xⱼ, . . . , x_{N}]; X is a D-dimensional input dataset of size N; v∈(0,1) is a parameter specifying a size of a control surface; Ψ is a penalty function; h defines a steepness of the penalty function; β is a hyperparameter that acts as a tradeoff between convergence of the plurality of nodes and dissipation of active power Σᵢ₌₁^{N}|Vᵢ∥Iᵢ| cos ϕᵢ; and N is the number of interconnected nodes.

Other objects and features will be in part apparent and in part pointed out hereinafter.

### DESCRIPTION OF THE DRAWINGS

The patent or application file contains at least one drawing executed in color. Copies of this patent or patent application publication with color drawing(s) will be provided by the Office upon request and payment of the necessary fee.

Those of skill in the art will understand that the drawings, described below, are for illustrative purposes only. The drawings are not intended to limit the scope of the present teachings in any way.

FIG. 1A. The total or apparent power S_{N} of the electrical network comprising of the active-power P_{N} or the dissipated power and the reactive-power Q_{N} or the power used for energy-storage.

FIG. 1B. One goal of the disclosed resonant learning framework: minimizing active-power P_{N} during learning and ensuring P_{N}=0, post-learning or steady-state.

FIG. 1C. A second goal of the disclosed resonant learning framework: maintaining Q_{N}=0 in learning and post-learning phases.

FIG. 2A. Equivalent network model comprising of N electrical nodes, with an inductance and capacitance element associated with each of the nodes. Learning is equivalent to changing the values of inductive and capacitive elements.

FIG. 2B. In steady-state the network of FIG. 2A is driven into electrical resonance.

FIG. 3. Illustration showing that operating the complex domain allows different possible learning trajectories from an initial state to the final steady-state. Regularization with respect to the phase-factor could then be used to select the trajectory with an optimal active-power dissipation profile, and results in limit cycle oscillations in steady-state. The circles indicate the constant magnitude loci.

FIG. 4A. Cost function [symbol] plotted for the hyperparameter β=0.

FIG. 4B. Cost function [symbol] plotted for the hyperparameter β=1.

FIG. 4C. Cost function [symbol] plotted for the hyperparameter β=10.

FIG. 5A. Comparison of the resonant optimization model ( [symbol] ᵣ) with its non-resonant variant ( [symbol] ₙᵣ) for a quadratic objective function [symbol] _{N} shown in Equation 19. For this experiment, N=5, input frequency ω=π/10, and the mean response is estimated over 10 trials with random initializations of Vᵢ, Iᵢ, ϕᵢ∀ᵢ=1, . . . , 5; a comparison of the time-evolution of [symbol] _{N} for [symbol] ₙᵣ and [symbol] ᵣ is shown.

FIG. 5B. A comparison of the time-evolution of [symbol] _{N} (Σᵢ₌₁^{N}|Vᵢ|²|Iᵢ|²) for [symbol] ₙᵣ and Σᵢ₌₁^{N}|Vᵢ|²|Iᵢ|² cos² ϕᵢ for [symbol] ᵣ for the experiment illustrated in FIG. 5A. For all the curves, the solid line indicates the mean response, while the shaded region shows the standard deviation about the mean across the 10 trials. The true dissipation Σₙ₌₁^{N}|Vᵢ∥Iᵢ| for [symbol] ₙᵣ and Σᵢ₌₁^{N}|Vᵢ∥Iᵢ|cos ϕᵢ for [symbol] ᵣ) over the 10 trials are also shown in the figure.

FIG. 5C. Phasor representations of the LC tank voltages and currents for a single trial in the initial configuration for [symbol] ᵣ. For [symbol] ᵣ, β=1 for all the trials.

FIG. 5D. Phasor representations of the LC tank voltages and currents for a single trial in the final configuration [symbol] ᵣ. For [symbol] ᵣ, β=1 for all the trials.

FIG. 6A. Comparison of the performance of the resonant model [symbol] ᵣ for different choices of annealing schedule for β (N=5, ω=π/10), showing time evolution of [symbol] _{N} (inset shows a zoomed-in view of the cost evolution in the transient phase).

FIG. 6B. The time evolution of [symbol] _{N} for the experiment shown in FIG. 6A.

FIG. 6C. The time evolution of β for the experiment shown in FIG. 6A. In all the cases, the optimization process starts 0.1 s after the onset of the simulation. The curves corresponding to β=1 denote the case when β takes a constant value from t=0.1 s; β=logistic corresponds to the cases when β is slowly increased following a logistic curve from t=0.1 s, and takes on a maximum value of β=1; β=switching corresponds to the case when β switches from a minimum value (=0) to a maximum value (=1) at t=0.3 s, after the system has converged to the optimal solution.

FIG. 7A. Comparison of the active and reactive power dissipated at each node for the non-resonant model [symbol] ₙᵣ and the resonant model [symbol] ᵣ for the synthetic one-class SVM problem on a two-dimensional dataset (Dataset I), with N=300, v=0.1, to ω=π/4, and random initializations for Vᵢ, Iᵢ, ϕᵢ∀=1, . . . , N showing the values of the active power metric (=|Vᵢ∥Iᵢ|) at each node in the initial stage for [symbol] ₙᵣ. For both models, K(·, ·) was chosen to be a Gaussian kernel with kernel parameter σ=1, and β=1 throughout the optimization process for [symbol] ᵣ.

FIG. 7B. A summary of the values of the reactive power metric (=0) at each node in the initial stage respectively for [symbol] ₙᵣ.

FIG. 7C. Comparison of the active and reactive power dissipated at each node for the non-resonant model [symbol] ₙᵣ and the resonant model [symbol] ᵣ for the synthetic one-class SVM problem on a two-dimensional dataset (Dataset I), with N=300, v=0.1, to ω=π/4, and random initializations for Vᵢ, Iᵢ, ϕᵢ∀ᵢ=1, . . . , N showing the values of the active power metric (=|Vᵢ∥Iᵢ|) at each node in the final stage for [symbol] ₙᵣ.

FIG. 7D. A summary of the values of the reactive power metric (=0) at each node in the final stage for [symbol] ₙᵣ.

FIG. 7E. The values of the active power metric (=|Vᵢ∥Iᵢ|cos ϕᵢ) at each node in the initial stage for [symbol] ᵣ. (f), (h): For both models, K(·, ·) was chosen to be a Gaussian kernel with kernel parameter σ=1, and β=1 throughout the optimization process for [symbol] ᵣ.

FIG. 7F. The values of the reactive power metric (=|Vᵢ∥Iᵢ|sin ϕᵢ) at each node in the initial stage for [symbol] ᵣ.

FIG. 7G. The values of the reactive power metric (=|Vᵢ∥Iᵢ|sin ϕᵢ) at each node in the final stage for [symbol] ᵣ.

FIG. 7H. The values of the reactive power metric (=|Vᵢ∥Iᵢ|sin ϕᵢ) at each node in the final stage respectively for [symbol] ᵣ.

FIG. 8A. Comparison of the performance of the resonant model [symbol] ᵣ for different choices of annealing schedules for β for the one-class SVM problem, on Dataset I out of three different two-dimensional synthetic datasets. In all cases, N=300, v=0.1, ω=π/20, and K(·, ·) was chosen to be a Gaussian kernel with parameter value σ=1. Additionally for each dataset, Vᵢ, Iᵢ, ϕᵢ were randomly initialized ∀ᵢ=1, . . . , N: A contour plot with the decision boundary around the datapoints and support vectors (SVs) is shown. (e)-(h) show similar plots on Dataset II, while (i)-(l) show the plots corresponding to Dataset III.

FIG. 8B. Time evolution of [symbol] (inset shows a zoomed in view of the cost evolution in the transient phase) for the experiment shown in FIG. 8A.

FIG. 8C. Time evolution of [symbol] for the experiment shown in FIG. 8A.

FIG. 8D. Time evolution of β for different annealing schedules for the experiment shown in FIG. 8A. The curves corresponding to β=1 and 10 denote the cases when β takes a constant value throughout the simulation duration; β=logistic₁ and β=logistic₂ correspond to the cases when β is slowly increased following a logistic curve, and takes on maximum values of βₘₐₓ=1 and βₘₐₓ=10 respectively; β=switching corresponds to the case when β switches from a minimum value (βₘᵢₙ=0) to a maximum value (βₘₐₓ=10) at t=2 s, after the system has converged to the optimal solution.

FIG. 8E. Comparison of the performance of the resonant model [symbol] ᵣ for different choices of annealing schedules for β for the one-class SVM problem, on Dataset II out of three different two-dimensional synthetic datasets. In all cases, N=300, v=0.1, ω=π/20, and K(·, ·) was chosen to be a Gaussian kernel with parameter value σ=10. Additionally for each dataset, Vᵢ, Iᵢ, ϕᵢ were randomly initialized ∀ᵢ=1, . . . , N: A contour plot with the decision boundary around the datapoints and support vectors (SVs) is shown. (e)-(h) show similar plots on Dataset II, while (i)-(l) show the plots corresponding to Dataset III.

FIG. 8F. Time evolution of [symbol] (inset shows a zoomed in view of the cost evolution in the transient phase) for the experiment shown in FIG. 8E.

FIG. 8G. Time evolution of [symbol] for the experiment shown in FIG. 8E.

FIG. 8H. Time evolution of β for different annealing schedules for the experiment shown in FIG. 8E. The curves corresponding to β=1 and 10 denote the cases when β takes a constant value throughout the simulation duration; β=logistic₁ and β=logistic₂ correspond to the cases when β is slowly increased following a logistic curve, and takes on maximum values of βₘₐₓ=1 and βₘₐₓ=10 respectively; β=switching corresponds to the case when β switches from a minimum value (βₘᵢₙ=0) to a maximum value (βₘₐₓ=10) at t=2 s, after the system has converged to the optimal solution.

FIG. 8I. Comparison of the performance of the resonant model [symbol] ᵣ for different choices of annealing schedules for β for the one-class SVM problem, on Dataset III out of three different two-dimensional synthetic datasets. In all cases, N=300, v=0.1, ω=π/20, and K(·, ·) was chosen to be a Gaussian kernel with parameter value σ=20. Additionally for each dataset, Vᵢ, Iᵢ, ϕᵢ were randomly initialized ∀ᵢ=1, . . . , N: A contour plot with the decision boundary around the datapoints and support vectors (SVs) is shown.

FIG. 8J. Time evolution of [symbol] (inset shows a zoomed in view of the cost evolution in the transient phase) for the experiment shown in FIG. 8I.

FIG. 8K. Time evolution of [symbol] for the experiment shown in FIG. 8E.

FIG. 8H. Time evolution of β for different annealing schedules for the experiment shown in FIG. 8I. The curves corresponding to β=1 and 10 denote the cases when β takes a constant value throughout the simulation duration; β=logistic₁ and β=logistic₂ correspond to the cases when β is slowly increased following a logistic curve, and takes on maximum values of βₘₐₓ=1 and βₘₐₓ=10 respectively; β=switching corresponds to the case when β switches from a minimum value (βₘₐₓ=0) to a maximum value (βₘₐₓ=10) at t=2 s, after the system has converged to the optimal solution.

FIG. 9A. Robustness to random initialization: Comparison of the time-evolution of the cost [symbol] and (b) the dissipation metric profile [symbol] (Σₙ₌₁^{N}=|Vᵢ|²|Iᵢ|²) for the non-resonant model [symbol] ₙᵣ and Σᵢ₌₁^{N}|Vᵢ|²|Iᵢ|² cos² ϕᵢ for the resonant model [symbol] ^{r} respectively for the synthetic one-class SVM problem on Dataset I for N=300, v=0.1, ω=π/8 over 10 random initializations for Vᵢ, Iᵢ, ϕᵢ∀ᵢ=1, . . . , N. The regularization parameter was chosen to be β=1 for the entire duration of the optimization process for [symbol] ᵣ. For all the curves, the solid line indicates the mean response, while the shaded region shows the standard deviation about the mean across the trials.

FIG. 9B. Comparison of the time-evolution of the dissipation metric profile [symbol] (Σₙ₌₁^{N}|Vᵢ|²|Iᵢ|²) for the non-resonant model [symbol] ₙᵣ and Σᵢ₌₁^{N}|Vᵢ|²|Iᵢ|² cos² ϕᵢ for the resonant model r respectively for the synthetic one-class SVM problem on Dataset I for N=300, v=0.1, ω=π/8 over 10 random initializations for Vᵢ, Iᵢ, ϕᵢ ∀ᵢ=1, . . . , N. The regularization parameter was chosen to be β=1 for the entire duration of the optimization process for [symbol] ᵣ. For all the curves, the solid line indicates the mean response, while the shaded region shows the standard deviation about the mean across the trials.

FIG. 10A. Circuit based and phasor based representations for a one-class SVM problem showing support vectors, corresponding to resonant LC tanks.

FIG. 10A. Circuit based and phasor based representations for a one-class SVM problem interior points, corresponding to sinks/ground (VᵢIᵢ=0).

FIG. 11. LC tank resonator.

FIG. 12 is a block diagram schematically illustrating a system in accordance with one aspect of the disclosure.

FIG. 13 is a block diagram schematically illustrating a computing device in accordance with one aspect of the disclosure.

FIG. 14 is a block diagram schematically illustrating a remote or user computing device in accordance with one aspect of the disclosure.

FIG. 15 is a block diagram schematically illustrating a server system in accordance with one aspect of the disclosure.

FIG. 16 is a schematic overview of a method of complex domain optimization in accordance with one aspect of the disclosure.

FIG. 17 is a schematic diagram showing an energy-based learning method illustrated as an electrical analogy using phasors.

FIG. 19 is a schematic diagram showing an energy-based learning method illustrated as an electrical analogy using equivalent LC tank circuits.

FIG. 20 is a schematic diagram illustrating a mathematical formulation for resonant machine learning in accordance with one aspect of the disclosure.

FIG. 21 is a schematic diagram illustrating complex domain growth transforms.

FIG. 22 is a schematic diagram illustrating a solution to an optimization problem using complex domain growth transforms.

FIG. 23 is a schematic diagram illustrating the use of complex domain growth transforms to characterize evolutionary dynamics.

FIG. 24 is a schematic diagram illustrating a method of data sonification using a complex domain growth transform system in accordance with one aspect of the disclosure. Assume a generic optimization/learning problem defined by a pre-specified cost function [symbol] {pᵢₖ}) and gradients

$$\{ \frac{\partial ℋ}{\partial {p}_{i k}} \} ,$$

and acoustic parameters like sampling frequency, allowable frequency range of operation, maximum and minimum loudness values. The disclosed framework outputs a single channel audio waveform that encodes the underlying optimization process.

FIG. 25 Illustration of the sonification process: N waveforms ψ₁, . . . , ψ_{N}, representing each variable in the optimization problem, and each having different frequencies and amplitudes. The final sonified output is created by the superimposition of all the oscillator signals, Σᵢ₌₁^{N}ψᵢ.

FIG. 26. Each multidimensional variable/data vector is mapped into an individual growth transform limit cycle oscillator. Local and global couplings lead to a constant phase difference between each pair of oscillators in steady state. This results in a sudden shift of the frequency of the superimposed waveform ψₛᵤₘ(t) from the baseline frequency during the transient state, following which the frequency is restored to its baseline value in the steady state.

FIG. 27A. Dynamics of growth transform based complex dynamical system consisting of two oscillators for problem [symbol] ₁ (p)), in which both oscillators asymptotically reach their respective stable limit cycles in steady state (γ=1).

FIG. 27B. Dynamics of growth transform based complex dynamical system of FIG. 27A, in which both oscillators asymptotically reach their respective stable limit cycles in steady state (γ=1).

FIG. 28A. Representative time domain and phase plane plots for ψ₁, ψ₂, and ψₜₒₜₐₗ, corresponding to a one-dimensional variant of the optimization problem [symbol] ₂ (p)=p²−0.8, s.t. |p|≤2, showing a time domain plots of the waveforms, with zoomed in versions of the initial (I), transient (T) and steady state(S) regions respectively.

FIG. 28B. Phase portrait of ψ₁ vs. ψ₂, showing how the oscillators go from an initial state (I) of same amplitude and no phase difference, through a transient state (T) of varying amplitudes and varying phase difference, to a final steady state(S) where they have constant amplitudes, and a constant phase difference as well.

FIG. 29A. Illustration of the variation of the spectrogram and instantaneous frequency of ψₜₒₜₐₗ(t) for a two-dimensional variant of the optimization problem [symbol] ₂ (p), for a=0.5 and γ=1.

FIG. 29B. Illustration of the variation of the spectrogram and instantaneous frequency of ψₜₒₜₐₗ(t) for a two-dimensional variant of the optimization problem [symbol] ₂ (p), for a=1 and γ=1.

FIG. 29C. Illustration of the variation of the spectrogram and instantaneous frequency of ψₜₒₜₐₗ(t) for a two-dimensional variant of the optimization problem [symbol] ₂ (p), for a=2 and γ=1.

FIG. 29D. Zoomed-in version of the instantaneous frequency shift shown in FIG. 29A.

FIG. 29E. Zoomed-in version of the instantaneous frequency shift shown in FIG. 29B.

FIG. 29F. Zoomed-in version of the instantaneous frequency shift shown in FIG. 29C.

FIG. 29G. Illustration of the variation of the spectrogram and instantaneous frequency of ψₜₒₜₐₗ(t) for a two-dimensional variant of the optimization problem [symbol] ₂ (p), for a=0.5 and γ=2.

FIG. 29H. Illustration of the variation of the spectrogram and instantaneous frequency of ψₜₒₜₐₗ(t) for a two-dimensional variant of the optimization problem [symbol] ₂ (p), for a=1 and γ=2.

FIG. 29I. Illustration of the variation of the spectrogram and instantaneous frequency of ψₜₒₜₐₗ (t) for a two-dimensional variant of the optimization problem [symbol] ₂ (p), for a=2 and γ=2.

FIG. 29J. Zoomed-in version of the instantaneous frequency shift shown in FIG. 29G.

FIG. 29K. Zoomed-in version of the instantaneous frequency shift shown in FIG. 29H.

FIG. 29L. Zoomed-in version of the instantaneous frequency shift shown in FIG. 29I.

FIG. 30A. Time course of instantaneous frequency of ψₜₒₜₐₗ (t) for a quadratic variant of the optimization problem [symbol] ₂ (p) in which ξᵢₖ(t) is constant ∀i,k, t.

FIG. 30B is a spectrogram of the output of the optimization problem of FIG. 30A.

FIG. 30C is a time course of the instantaneous frequency shift using Hilbert transform corresponding to FIG. 30A.

FIG. 30D. Time course of instantaneous frequency of ψₜₒₜₐₗ (t) for a quadratic variant of the optimization problem [symbol] ₂ (p) in which ξᵢₖ(t) depends on the convergence rate of each variable ψᵢₖ(t).

FIG. 30E is a spectrogram of the output of the optimization problem of FIG. 30D.

FIG. 30F is a time course of the instantaneous frequency shift using Hilbert transform corresponding to FIG. 30D.

FIG. 30G. Time course of instantaneous frequency of ψₜₒₜₐₗ (t) for a quadratic variant of the optimization problem [symbol] ₂ (p) in which ξᵢₖ(t) exists only during the optimization stage and is an exponentially decaying function which is the same for all ψᵢₖ.

FIG. 30H is a spectrogram of the output of the optimization problem of FIG. 30G.

FIG. 30I is a time course of the instantaneous frequency shift using Hilbert transform corresponding to FIG. 30G.

FIG. 31A. Illustration of the sonification process in the musical composition based sonification approach.

FIG. 31B. Spectrogram of an original musical piece;

FIG. 31C. Raw frequency trajectories extracted from the music of FIG. 31B.

FIG. 31D. Spectrogram of the sonified output using the music of FIG. 31B.

FIG. 31E. Spectrogram of the distorted music, obtained by superimposing the sonified output signal on the original music signal.

FIG. 31F. Time evolution of the original musical composition, the sonified output and the distorted music signal.

FIG. 32A. A scatter graph of the ‘Iris’ dataset sonified using bark scale-based sonification and labeled according to cluster assignments.

FIG. 32B are frequency trajectories of the ‘Iris’ dataset sonified using bark scale-based sonification.

FIG. 32C is a time evolution of the sonified output for the bark scale-based sonification of the ‘Iris’ dataset.

FIG. 32D is a spectrogram of the sonified output for the bark scale-based sonification of the ‘Iris’ dataset.

FIG. 32E. A scatter graph of the ‘Iris’ dataset sonified using musical scale based sonification and labeled according to cluster assignments.

FIG. 32F are frequency trajectories of the ‘Iris’ dataset sonified using musical scale based sonification.

FIG. 32G is a time evolution of the sonified output for the musical scale based sonification of the ‘Iris’ dataset.

FIG. 32H is a spectrogram of the sonified output for the musical scale based sonification of the ‘Iris’ dataset.

FIG. 32I. A scatter graph of the ‘Iris’ dataset sonified using musical composition based sonification and labeled according to cluster assignments.

FIG. 32J are frequency trajectories of the ‘Iris’ dataset sonified using musical composition based sonification.

FIG. 32K is a time evolution of the sonified output for the musical composition based sonification of the ‘Iris’ dataset.

FIG. 32L is a spectrogram of the sonified output for the musical composition based sonification of the ‘Iris’ dataset.

FIG. 33A is a scatter graph of musical composition based sonification on synthetic dataset I with same number of points (N=2) but different number of clusters, with a basis set size of 3.

FIG. 33B shows frequency trajectories of the musical composition based sonification on synthetic dataset I of FIG. 33A.

FIG. 33C shows time evolution of the sonified output of the musical composition based sonification on synthetic dataset I of FIG. 33A.

FIG. 33D is a spectrogram of the sonified output of the musical composition based sonification on synthetic dataset I of FIG. 33A.

FIG. 33E is a scatter graph of musical composition based sonification on synthetic dataset II with same number of points (N=2) but different number of clusters, with a basis set size of 3.

FIG. 33F shows frequency trajectories of the musical composition based sonification on synthetic dataset II of FIG. 33E.

FIG. 33G shows time evolution of the sonified output of the musical composition based sonification on synthetic dataset II of FIG. 33E.

FIG. 33H is a spectrogram of the sonified output of the musical composition based sonification on synthetic dataset II of FIG. 33E.

FIG. 33I is a scatter graph of musical composition based sonification on synthetic dataset III with same number of points (N=2) but different number of clusters, with a basis set size of 3.

FIG. 33J shows frequency trajectories of the musical composition based sonification on synthetic dataset III of FIG. 33I.

FIG. 33K shows time evolution of the sonified output of the musical composition based sonification on synthetic dataset III of FIG. 33I.

FIG. 33L is a spectrogram of the sonified output of the musical composition based sonification on synthetic dataset III of FIG. 33I.

FIG. 34A is a scatter graph of musical composition based sonification on synthetic dataset I with same number of points (N=2) but different number of clusters, with a basis set size of 5.

FIG. 34B shows frequency trajectories of the musical composition based sonification on synthetic dataset I of FIG. 34A.

FIG. 34C shows time evolution of the sonified output of the musical composition based sonification on synthetic dataset I of FIG. 34A.

FIG. 34D is a spectrogram of the sonified output of the musical composition based sonification on synthetic dataset I of FIG. 34A.

FIG. 34E is a scatter graph of musical composition based sonification on synthetic dataset II with same number of points (N=2) but different number of clusters, with a basis set size of 5.

FIG. 34F shows frequency trajectories of the musical composition based sonification on synthetic dataset II of FIG. 34E.

FIG. 34G shows time evolution of the sonified output of the musical composition based sonification on synthetic dataset II of FIG. 34E.

FIG. 34H is a spectrogram of the sonified output of the musical composition based sonification on synthetic dataset II of FIG. 34E.

FIG. 34I is a scatter graph of musical composition based sonification on synthetic dataset III with same number of points (N=2) but different number of clusters, with a basis set size of 5.

FIG. 34J shows frequency trajectories of the musical composition based sonification on synthetic dataset III of FIG. 34I.

FIG. 34K shows time evolution of the sonified output of the musical composition based sonification on synthetic dataset III of FIG. 34I.

FIG. 34L is a spectrogram of the sonified output of the musical composition based sonification on synthetic dataset III of FIG. 34I.

FIG. 35A scatter graph of musical composition based sonification on synthetic dataset III with same number of points (N=500) and the same number of clusters, but with different cluster geometries with a basis set size of 3.

FIG. 35B shows frequency trajectories of the musical composition based sonification on synthetic dataset III of FIG. 35A.

FIG. 35C is a spectrogram of the sonified output of the musical composition based sonification on synthetic dataset III of FIG. 35A.

FIG. 35D scatter graph of musical composition based sonification on synthetic dataset III with same number of points (N=500) and the same number of clusters, but with different cluster geometries with a basis set size of 3.

FIG. 35E shows frequency trajectories of the musical composition based sonification on synthetic dataset IV of FIG. 35D.

FIG. 35F is a spectrogram of the sonified output of the musical composition based sonification on synthetic dataset IV of FIG. 35D.

There are shown in the drawings arrangements which are presently discussed, it being understood, however, that the present embodiments are not limited to the precise arrangements and are instrumentalities shown. While multiple embodiments are disclosed, still other embodiments of the present disclosure will become apparent to those skilled in the art from the following detailed description, which shows and describes illustrative aspects of the disclosure. As will be realized, the invention is capable of modifications in various aspects, all without departing from the spirit and scope of the present disclosure. Accordingly, the drawings and detailed description are to be regarded as illustrative in nature and not restrictive.

### DETAILED DESCRIPTION OF THE INVENTION

In various aspects, an energy-efficient learning framework is described which exploits structural and functional similarities between a machine learning network and a general electrical network satisfying the Tellegen's theorem. The described formulation ensures that the network's active-power is dissipated only during the process of learning, whereas the network's reactive-power is maintained to be zero at all times. As a result, in steady-state, the learned parameters are stored and self-sustained by electrical resonance determined by the network's nodal inductances and capacitances. Based on this approach, three novel concepts are introduced: (a) a learning framework where the network's active-power dissipation is used as a regularization for a learning objective function that is subjected to zero total reactive-power constraint; (b) a dynamical system based on complex-domain, continuous-time growth transforms which optimizes the learning objective function and drives the network towards electrical resonance under steady-state operation; and (c) an annealing procedure that controls the trade-off between active-power dissipation and the speed of convergence. As a representative example, the proposed framework may be used for designing resonant support vector machines (SVMs), and it is demonstrated below that the support-vectors correspond to an LC network with self-sustained oscillations. It is also shown that this resonant network dissipates less active-power compared to its non-resonant counterpart.

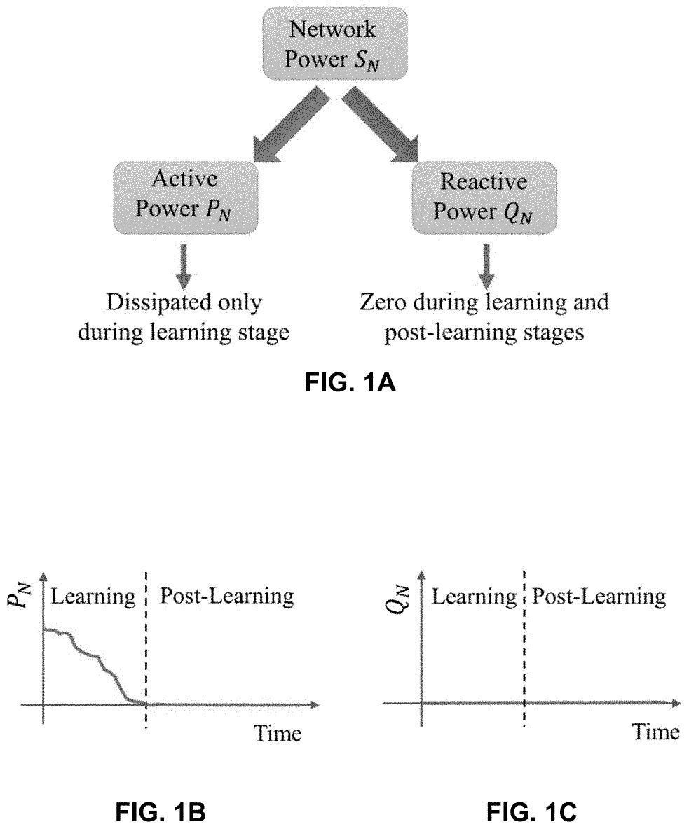

In various aspects, a framework which exploits both active and reactive network power for learning and memory is disclosed. The objective of this framework in various aspects is to achieve a network power profile, as illustrated in FIGS. 1(b) and (c). During learning, the network optimizes its active-power (P_{N}) and under steady-state condition or post-learning, ensures P_{N}=0. The reactive-power (Q_{N}), on the other hand, is maintained at zero. This implies that the stored energy (mathematically quantifiable as the time-integral of the reactive-power) is conserved across the learning and post-learning phases respectively. Thus, during the post-learning phase or in steady-state, the network does not dissipate any power, and the reactive energy is used to maintain the current network state or memory.

In various aspects, this steady-state condition corresponds to a state of electrical resonance, and this concept is generalized to a framework of resonant machine learning below. To reach this steady-state condition, as described in additional detail below, a dynamical system based on complex-domain continuous-time growth-transforms is presented that extends previous work on growth transform networks using real-variables. The complex-domain formulation allows manipulation of the relative phase between the voltage and current variables associated with the network nodes and thus is used to optimize the active-power dissipation during learning.

In general, the disclosed approach may be applied to different learning networks. By way of non-limiting example, described in detail below, the disclosed framework is used to design resonant one-class support vector machines (SVMs). In this context, the performance of the resonant SVM model is compared with its non-resonant variant. A brief discussion of additional applications of the disclosed framework as applied to other network-based models that do not involve learning, for instance, the coupled oscillator networks as described in additional detail below.

In the various aspects described below, various mathematical expressions may include variables as defined in Table 1 below.

TABLE 1
Notations

| Variable | Definition |
|---|---|
| [symbol] ₊ | One-dimensional positive real vector space |
| [symbol] ^{N} | N-dimensional real vector space |
| [symbol] | One-dimensional complex vector space |
| \|z\| | magnitude of a complex variable z |
| Re(z) | real part of a complex variable z |
| Im(z) | imaginary part of complex variable z |
| z* | complex conjugate of a complex variable z |
| z(t) | a continuous-time complex variable at time t |
| zₙ | a discrete-time complex variable at the n^{th} time step |

Optimization and Electrical Resonance

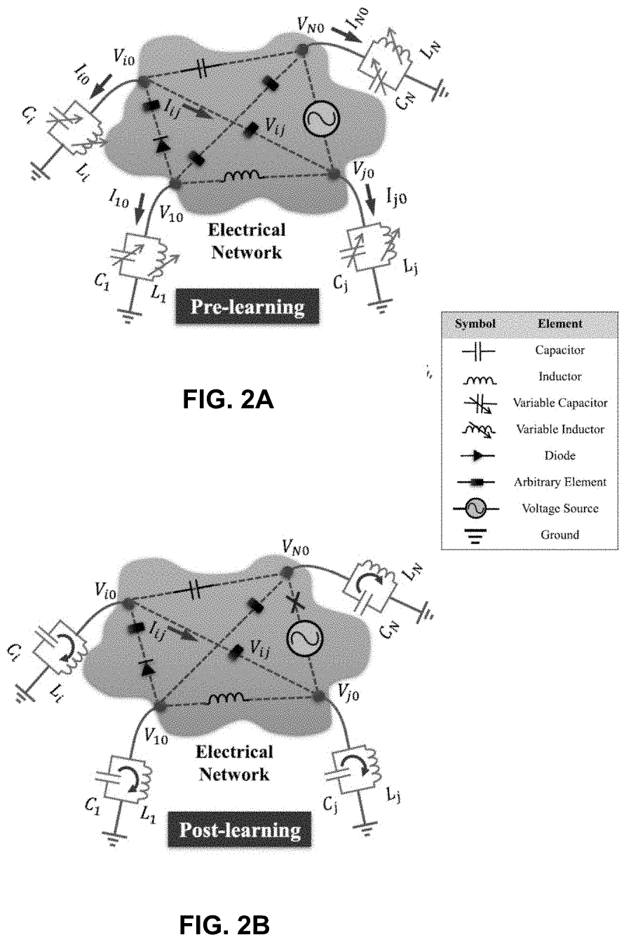

Consider an electrical network as shown in FIG. 2(a), comprising of N internal nodes. The voltage difference between the i^{th} and j^{th} nodes is denoted by Vᵢⱼ, with Vo being the i^{th} nodal voltage with respect to ground terminal (referred to as the 0^{th} node). Similarly, the current flowing between the i^{th} and j^{th} nodes is given by Iᵢⱼ, and Iᵢ₀ denotes the current flowing out of the i^{th} node into the ground terminal. Tellegen's theorem, as expressed by Eqn. (2) below, states that the total complex electrical power or apparent power is zero.

ΣᵢVᵢⱼI*ᵢⱼ=0 Eqn. (2)

Isolating the apparent power flowing from the nodes to the ground terminal from that flowing between the internal nodes results in the expression of Eqn. (3):

$${\sum }_{i \neq j , 0 , j \neq 0} ( {V}_{i j} ) {I}_{i j}^{*} + {\sum }_{i} ( {V}_{i 0} ) {I}_{i 0}^{*} = 0 ⇒ {\sum }_{i}^{N} ( {V}_{i 0} ) {I}_{i 0}^{*} = - {\sum }_{i} ( {V}_{i j} ) {I}_{i j}^{*} ⇒ {S}_{T} = - {S}_{N} ⇒ {P}_{T} + j {Q}_{T} = - {P}_{N} - j {Q}_{N} ⇒ \vert {P}_{T} \vert = \vert {P}_{N} \vert ⇒ \vert {Q}_{T} \vert = \vert {Q}_{N} \vert \qquad Eqn . ( 3 )$$

where S_{T}=Σᵢ(Vᵢ₀)Iᵢ₀* is the nodal apparent power, and P_{T}=Σᵢ Re{Vᵢ₀Iᵢ₀} and are the total active and reactive power consumed at the nodes. Similarly, S_{N}, P_{N} and Q_{N} represent the apparent, active and reactive power consumed due to current flow between the network nodes (other than the ground terminal). Note that this result holds even if active-power sources are embedded in the network, as shown in FIG. 2A.

Thus, Equations (3) imply that if the active-power at the nodes of the network P_{T} is minimized subject to the constraint that the nodal reactive power Q_{T}=0, then this formulation is equivalent to minimizing the network active-power P_{N} while ensuring that the network reactive power Q_{N}=0. This result can be expressed as:

$${min}_{\{ {V}_{i} {I}_{i} ∈ ℂ \}} 𝒟 = {\sum }_{i} {\vert Re \{ {V}_{i} {I}_{i}^{*} \} \vert}^{2} \\ s . t . {\sum }_{i} Im \{ {V}_{i} {I}_{i}^{*} \} = 0 \qquad Eqn . ( 4 )$$

where Vᵢ₀=V and Iᵢ₀=Iᵢ. If it is assumed that the i^{th} node is associated with a lumped capacitance Cᵢ, and a lumped inductance Lᵢ, ensuring zero nodal reactive-power implies

$${\sum }_{i}^{N} {{V}_{i} ( {C}_{i} \frac{d {V}_{i}}{d t} )}^{*} + ( {L}_{i} \frac{d {I}_{i}}{d t} ) {I}_{i}^{*} = 0 \qquad Eqn . ( 5 )$$

where

$$( {c}_{i} \frac{{dv}_{i}}{d t} ) and ( {L}_{i} \frac{d {I}_{i}}{d t} )$$

represent the current flowing through Cᵢ and the voltage across Lᵢ respectively. Equation (5) is equivalent to:

Σᵢ^{N}(½Cᵢ|V|²+½Lᵢ|Iᵢ|²=E₀ Eqn. (6)

where |Vᵢ|²=VᵢVᵢ* and |Iᵢ|²=IᵢIᵢ*, implying that the total network reactive energy is conserved to be equal to some constant value E₀.

Satisfying the constraint described above is equivalent to sustaining a condition of electrical resonance. The optimization problem as expressed in Eqn. (4) can be transformed as:

$$\begin{matrix}{min}_{\{ \vert {V}_{i} \vert , \vert {I}_{i} \vert ∈ {ℝ}_{+ ,} {ϕ}_{i} ∈ ℝ \}} 𝒟 = {\sum }_{i} {\vert {V}_{i} \vert}^{2} {\vert {I}_{i} \vert}^{2} cos {ϕ}_{i} & Eqn . ( 7 ) \\ s . t . {\sum }_{i}^{N} ( \frac{1}{2} {C}_{i} {\vert {V}_{i} \vert}^{2} + \frac{1}{2} {L}_{i} {ϕ}_{i}^{2} = {E}_{0} , \vert {ϕ}_{i} \vert \leq π {∀}_{{i}_{-}} & Eqn . ( 8 )\end{matrix}$$

where ϕᵢ denotes the phase-angle between the voltage and current phasors at the i^{th} node.

Note that the optimization in Equation (7) may result in three types of solutions in steady-state: (a) (|Iᵢ|≠0, |Vᵢ|≠0, |ϕᵢ|=π/2) which corresponds to a resonant LC tank; (b) (|Iᵢ|=0, |Vᵢ|≠0) which corresponds to an electrically isolated or floating node; and (c) (|Iᵢ|≠0, |Vᵢ|=0) which corresponds to a short-circuit condition. In various examples, described below, these steady-state resonance conditions are illustrated using a simple LC tank. Note that in all cases, active power is dissipated only during the learning phase, where Cᵢ and Lᵢ change to change the relative magnitude of the voltage and current variables. FIG. 2(b) illustrates this resonant condition of the network in the post-learning stage, whereby any active power sources in the network get electrically isolated from the rest of the network. The lumped capacitance and inductance associated with the LC network at the terminal nodes, adapt such that the resonant frequency condition in maintained in steady-state, as illustrated in the examples described below. This implies that in steady-state, the learned network parameters are stored and sustained by the resonant electric and magnetic fields of the LC tanks.

The constraint as expressed in Equation (8) can be simplified by normalizing with respect to E₀ such that:

Σᵢ^{N}(|Vᵢ|²+|Iᵢ|²)=1 Eqn. (9)

where

$${V}_{i} ← \sqrt{\frac{{C}_{i}}{2 {E}_{0}}} {V}_{i} and {I}_{i} ← \sqrt{\frac{{L}_{i}}{2 {E}_{0}}} {I}_{i}$$

represent the dimension-less voltages and currents.

Henceforth, unless stated otherwise, subsequent expressions are derived in terms of dimensionless quantities. The optimization framework in Equation (7) is extended to include a general optimization function [symbol] , expressed as:

$${min}_{\{ \vert {V}_{i} \vert , \vert {I}_{i} \vert , {ϕ}_{i} \}} ℒ ( \{ \vert {V}_{i} \vert , \vert {I}_{i} \vert , {ϕ}_{i} \} ) = ℋ ( \{ \vert {V}_{i} \vert , \vert {I}_{i} \vert \} ) + β 𝒟 \} ) \\ s . t . {\sum }_{i}^{N} ( \vert {V}_{i} {\vert}^{2} + {\vert {I}_{i} \vert}^{2} ) = 1 , \vert {ϕ}_{i} \vert \leq π {∀}_{i} \qquad Eqn . ( 10 )$$

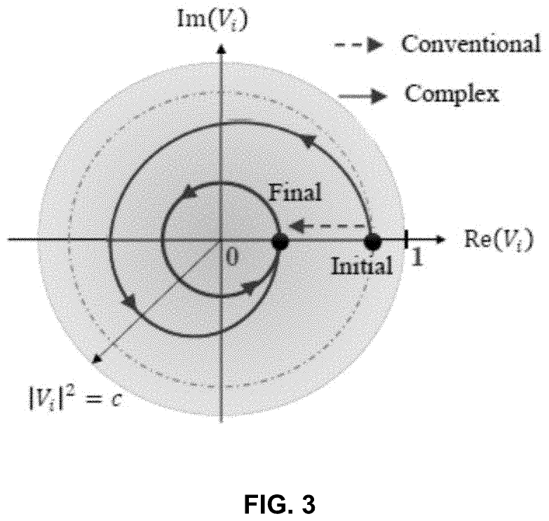

In this formulation, the active-power dissipation [symbol] in Equation (10) acts as a regularization function with β≥0 being a hyper-parameter. Note that the objective function [symbol] {|Vᵢ|, |Iᵢ|}) is only a function of the magnitudes of the voltages and currents and is independent of the phase-angle ϕᵢ, This ensures independent control of the magnitudes and the phase to achieve the desired objective of optimizing the active-power dissipation. This is illustrated in FIG. 3 where controlling the phase allows different paths from the initial to the final state, whereas evolution over the real-domain allows only one possible path. The complex-domain approach thus results in steady-state limit cycle oscillations that encode the final solution. Compared to other complex-domain machine learning frameworks, the proposed formulation avoids non-linear processing of phase/frequency which produces unwanted higher-order harmonics. This would have made it difficult to maintain the network in the state of resonance (at specific set of frequencies) under steady-state.

The two important properties of the optimization framework in Equation (10) are as follows:

For a convex cost function [symbol] :

$${min}_{\{ \vert {V}_{i} \vert , \vert {I}_{i} \vert , {ϕ}_{i} \}} ℒ ( \{ \vert {V}_{i} \vert , \vert {I}_{i} \vert , {ϕ}_{i} \} ) = {min}_{\{ \vert {V}_{i} \vert , \vert {I}_{i} \vert \}} ℋ ( \{ \vert {V}_{i} \vert , \vert {I}_{i} \vert \} ) \qquad Eqn . ( 11 )$$

This result follows from the three possible solutions of optimization framework of Eqn. (7).

If β is slowly annealed to a sufficiently high value, then ϕᵤ→π/2 under steady state for i: |Vᵢ∥Iᵢ|≠0. This implies that the network achieves zero active power dissipation in steady state. Note that the method also holds for non-convex objective functions as well. In this case however, the network might show resonant behavior at a locally optimal solution.

By way of non-limiting example, consider a single-variable quadratic optimization problem of the form [symbol] ₁(x)=x², subject to the constraint |x|≥1, x∈ [symbol] . Substituting x=|V|²−|I|², the problem can be mapped as described in additional detail below into a form equivalent to Equation (10):

$$\begin{matrix}{min}_{\{ \vert {V}_{i} \vert , \vert {I}_{i} \vert , ϕ \}} {ℒ}_{1} = {( {\vert V \vert}^{2} - {\vert I \vert}^{2} )}^{2} + β ( {\vert V \vert}^{2} ( {\vert I \vert}^{2} {cos}^{2} ϕ & Eqn . ( 12 ) \\ s . t . {\vert V \vert}^{2} + {\vert I \vert}^{2} = 1 , \vert ϕ \vert \leq π & Eqn . ( 13 )\end{matrix}$$

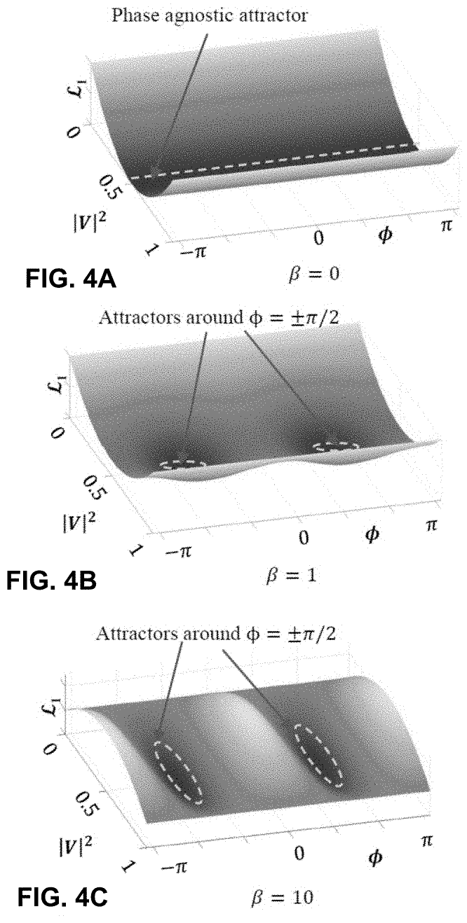

FIGS. 4A, 4B, and 4C plot [symbol] ₁ for different values of β. As shown in FIG. 4A, and as expected for β=0, the cost function has several minima (or attractors), whereas for β>0, the minima corresponds to ϕ=±π/2, for which the active-power dissipation is zero. FIGS. 4B and 4C show that controlling β will control the optimization landscape (without changing the location of the attractors) and will determine the attractor trajectory. In various aspects described in additional detail below, this feature may be exploited to optimize the active-power dissipation profile during the learning phase.

### III. Complex Growth Transforms

In various aspects, the optimization framework described in Equation (10) involves complex phasors and hence entails the use of learning models operating in the complex domain for reaching the optimal solution. To this end, a dynamical system may be used to solve this optimization problem. The main result is summarized in Table 2 and details of the proof are provided in additional detail below.

Theorem 1: The system of nonlinear dynamical equations given by Equations (15)-(18) in Table 2 converge to the optimal point of Equation (14) in the steady state, with zero energy dissipation i.e., Σₙ₌₁^{N}|Vᵢ∥Iᵢ|cos ϕᵢ=0. A formal proof of Theorem I is provided below.

In some aspects, the optimization framework given by Equations (12)-(13) may be extended to a multi-variable space, as expressed by:

$$\begin{matrix}{min}_{\{ \vert {V}_{i} \vert , \vert {I}_{i} \vert , ϕ \}} {ℒ}_{1} = {\sum }_{i = 1}^{N} {( {\vert {V}_{i} \vert}^{2} - {\vert {I}_{i} \vert}^{2} )}^{2} + β {\sum }_{i = 1}^{N} {\vert {V}_{i} \vert}^{2} {\vert {I}_{i} \vert}^{2} {cos}^{2} {ϕ}_{i} & Eqn . ( 19 ) \\ s . t . {\sum }_{i = 1}^{N} {( {\vert {V}_{i} \vert}^{2} - {\vert {I}_{i} \vert}^{2} )}^{2} = 1 , {ϕ}_{i} \leq π {∀}_{i} & Eqn . ( 20 )\end{matrix}$$

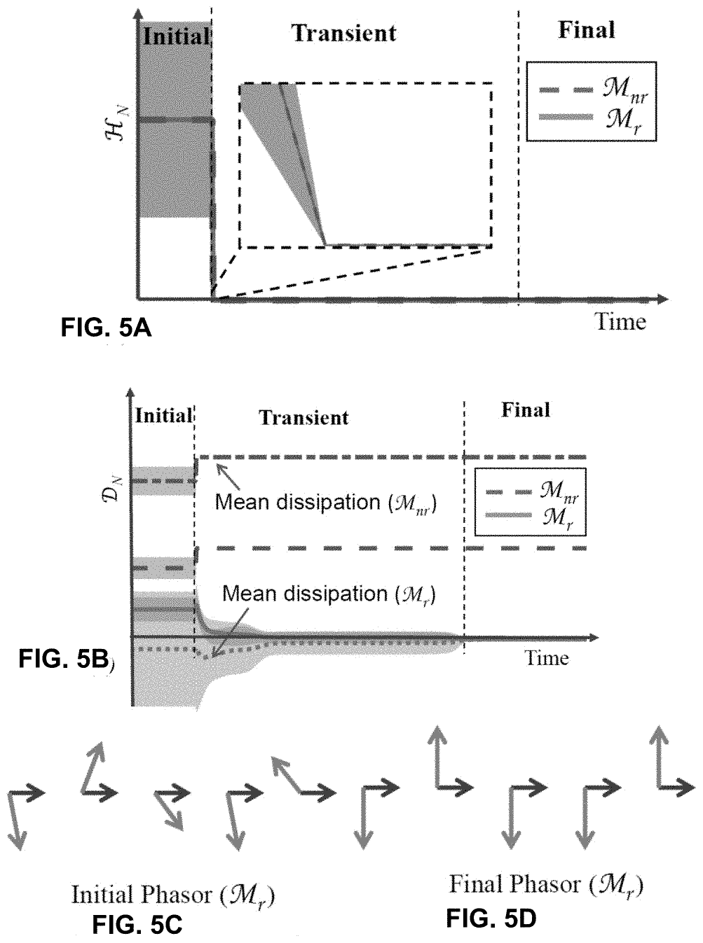

The optimal solution is reached when ϕᵢ=±π∀ᵢ which implies [symbol] _{N}=0. For the sake of comparison, we will consider two variants: (a) the non-resonant model ( [symbol] ₙᵣ) where β=0, and (b) the resonant model ( [symbol] ᵣ), where β≠0. FIGS. 5(a) and (b) show a comparison of the cost [symbol] _{N} and the regularization metric [symbol] _{N}(Σᵢ₌₁^{N}(|Vᵢ|²|Iᵢ|²)) for [symbol] ₙᵣ and Σᵢ₌₁^{N}(∥Vᵢ|²|Iᵢ|² cos² ϕᵢ)) for [symbol] ᵣ), for N=5 and ω=π/10. In the case of [symbol] ₙᵣ, [symbol] _{N}= [symbol] _{N} and in the case of [symbol] ᵣ, [symbol] _{N}= [symbol] _{N}+βD_{N}, with β=1. The solid line indicates the mean response across 10 trials with random initializations of Vᵢ, Iᵢ and ϕᵢ. The shaded region shows the standard deviation across the trials in each case. Also shown in FIG. 5(b) are the true active-power dissipation profiles (Σᵢ₌₁^{N}|Vᵢ∥Iᵢ| for [symbol] ᵣ and Σᵢ₌₁^{N}|Vᵢ∥Iᵢ|cos ϕᵢ for [symbol] r) over the 10 trials.

In various aspects, under steady-state conditions, the model [symbol] ₙᵣ dissipates power. However for the model [symbol] ᵣ the steady-state active-power goes to zero. This is illustrated in FIG. 5B. FIG. 5C shows the initial phasor configuration for the currents and voltages at each node of the network for a single trial for [symbol] ᵣ. Here, the voltage phasor Vᵢ is assumed to be aligned with the horizontal axis, and the current phasor Iᵢ is assumed to be at an angle ϕᵢ with respect to the horizontal, ∀ᵢ. FIG. 5D shows the steady-state phasor configuration for [symbol] ᵣ for the same trial. The voltage and current phasors are orthogonal to each other for all the nodes, thus verifying the zero active-power dissipation.

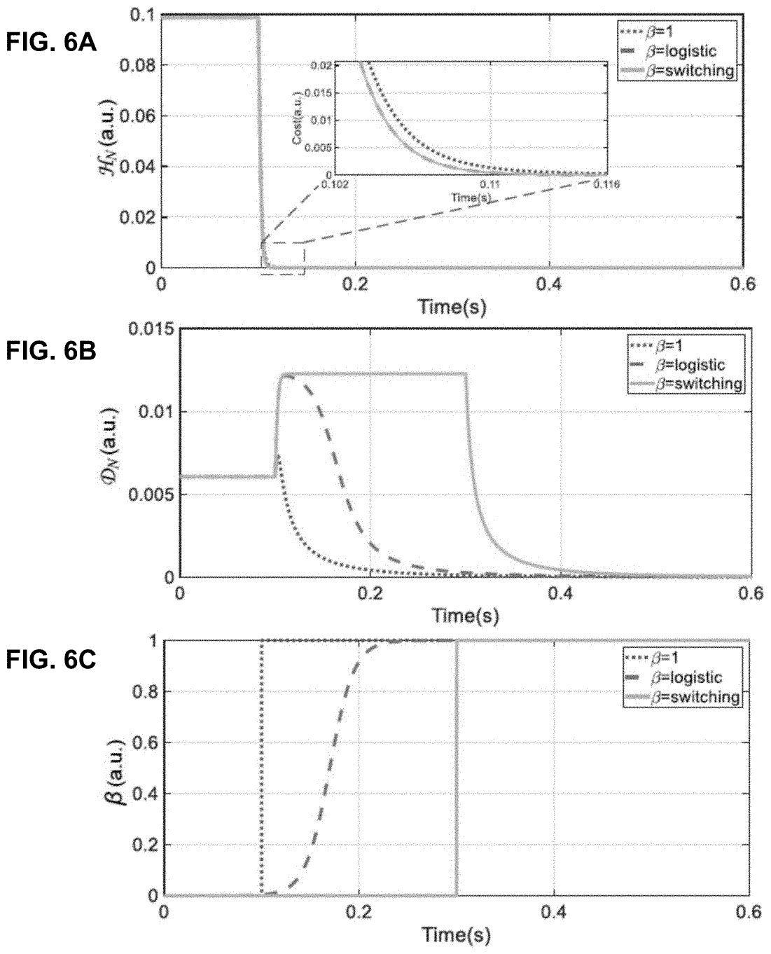

By way of non-limiting example, the hyperparameter β was annealed and its impact on the active-power dissipation metric [symbol] _{N} and the convergence of the object function [symbol] ₙ for the model [symbol] ᵣ was evaluated. FIGS. 6A, 6B, and 6C present a comparison of the performance of [symbol] ᵣ for different choices of annealing schedule for β, with the angular frequency ω=π/10 as before. FIG. 6A shows the time evolution of the objective function [symbol] _{N}, FIG. 6B shows the time evolution of the dissipation metric [symbol] _{N} and FIG. 6C shows the annealing schedules adopted for β. In all the cases, the optimization process started after 0.1 s from the onset of the simulation. The curves corresponding to β=1 denote the case when β takes a constant value from t=0.1 s; β=logistic corresponds to the case when β is slowly increased from βₘᵢₙ=0 following a logistic curve of the form

$$β = {β}_{min} + \frac{{β}_{max} - {β}_{min}}{1 + exp ( - k ( t + {t}_{0} ) )}$$

from t=0.1 s, and takes on a maximum value of βₘₐₓ=1 (k and to are hyperparameters determining the steepness and mid-point of the sigmoid respectively); β=switching corresponds to the case when β switches from a minimum value (βₘᵢₙ=0) to a maximum value (βₘₐₓ=1) at t=0.3 s, after the system has converged to the optimal solution. In all of the cases, the model is observed to converge to the optimal solution, irrespective of the choice of β. However, different annealing schedules for β lead to different active-power dissipation profiles. For example, a constant value of β throughout the duration of the experiment would lead to faster minimization of the active-power dissipation metric, but at the cost of slower convergence. The opposite trend can be seen when β is slowly annealed to a sufficiently high value throughout the course of the optimization. The annealing schedule thus acts as a trade-off between the speed of convergence, and the rate of minimization of the active power.

Table 2: Complex growth transform dynamical system
For an optimization problem of the form:

$${min}_{\{ \vert {V}_{i} \vert , \vert {I}_{i} \vert , ϕ \}} {ℒ}_{1} = {\sum }_{i = 1}^{N} {( {\vert {V}_{i} \vert}^{2} - {\vert {I}_{i} \vert}^{2} )}^{2} + β {\sum }_{i = 1}^{N} {\vert {V}_{i} \vert}^{2} {\vert {I}_{i} \vert}^{2} {cos}^{2} {ϕ}_{i} \\ s . t . {\sum }_{i = 1}^{N} {( {\vert {V}_{i} \vert}^{2} - {\vert {I}_{i} \vert}^{2} )}^{2} = 1 , \vert {ϕ}_{i} \vert \leq π {∀}_{i} = 1 , … , N , β \leq 0 \qquad ( 14 )$$

If [symbol] ({Vᵢ,Iᵢ}) is Lipschitz continuous in the domain D=(|ᵢ|, |Iᵢ|): Σᵢ₌₁^{N}(|Vᵢ|²+|Iᵢ|²), the following system of nonlinear dynamical equations

$$\begin{matrix}\frac{\partial {V}_{i} ( t )}{\partial t} = j ω {σ}_{{V}_{i}} ( t ) {V}_{i} ( t ) - Δ {σ}_{{V}_{i}} ( t ) {V}_{i} ( t ) , & ( 15 ) \\ \frac{\partial {I}_{i} ( t )}{\partial t} = j ( ω + {ω}_{{ϕ}_{i}} ) {σ}_{{I}_{i}} ( t ) {I}_{i} ( t ) - Δ {σ}_{{I}_{i}} ( t ) {I}_{i} ( t ) , & ( 16 )\end{matrix}$$

and τᵢω_{ϕi}+ϕᵢ(t)=g_{ϕi}(t),∀ᵢ=1, . . . ,N (17)
ensures that

$$\frac{\partial ℒ}{\partial t} \leq 0 , \qquad ( 18 )$$

where

$${σ}_{{V}_{i}} ( t ) = \sqrt{\frac{1}{{V}_{i}^{*} η} ( - \frac{\partial ℒ}{\partial {V}_{i}} + λ {V}_{i}^{*} )} , \\ {σ}_{{I}_{i}} ( t ) = \sqrt{\frac{1}{{I}_{i}^{*} η} ( - \frac{\partial ℒ}{\partial {I}_{i}} + λ {I}_{i}^{*} )} , {ω}_{{ϕ}_{i}} = \frac{d {ϕ}_{i}}{dt} , \\ Δ {σ}_{{V}_{i}} ( t ) = 1 - {σ}_{{V}_{i}} ( t ) , \\ Δ {σ}_{{I}_{i}} ( t ) = 1 - {σ}_{{I}_{i}} ( t ) , and$$

$${g}_{{ϕ}_{i}} ( t ) = π \frac{λ {ϕ}_{i} - π \frac{\partial ℒ}{\partial {ϕ}_{i}}}{- {ϕ}_{i} \frac{\partial ℒ}{\partial {ϕ}_{i}} + λ π} , with$$

$$η = {\sum }_{k = 1}^{N} ( {V}_{k} [ - \frac{\partial ℒ}{\partial {V}_{k}} + λ {V}_{k}^{*} ] + {I}_{k} [ - \frac{\partial ℒ}{\partial {I}_{k}} + λ {I}_{k}^{*} ] ) ,$$

ω is an arbitrary angular frequency, and τᵢ is the time-constant associated with the evolution of ϕᵢ.

A. Model Properties and Extensions

In various aspects, the dynamical system represented by Equations (15)-(18) and the resonant optimization framework also exhibits the following properties and extensions.

In one aspect, energy constraints can be imposed over subgroups of nodes in the network: In one aspect, the reactive energy conservation constraint is imposed between subgroups of nodes, instead of on the network as a whole, i.e., Σᵢ₌₁^{N}^{ₖ}(|Vᵢₖ|²+|Iᵢₖ|²)=1 ∀k=1, . . . , M. Here M=number of sub-groups and Nₖ=number of nodes in the k^{th} subgroup.

The update equations in this case are given by:

$$\frac{\partial {V}_{i k} ( t )}{\partial t} = j {ω}_{k} {σ}_{{V}_{i k}} ( t ) {V}_{i k} ( t ) - Δ {σ}_{{V}_{i k}} ( t ) {V}_{i k} ( t ) \\ \frac{\partial {I}_{i k} ( t )}{\partial t} = j ( {ω}_{k} + {ω}_{{ϕ}_{i k}} ) {σ}_{{I}_{i k}} ( t ) {I}_{i k} ( t ) - Δ {σ}_{{I}_{i k}} ( t ) {I}_{i k} ( t ) \\ {τ}_{i k} {ω}_{{ϕ}_{i k}} + {ϕ}_{i k} ( t ) = {g}_{{ϕ}_{i k}} ( t ) , {∀}_{i} , k \qquad Eqn . ( 21 )$$

where ωₖ is the constant angular frequency of the kth subgroup of nodes, and

$${ω}_{{ϕ}_{i k}} = \frac{d {ϕ}_{i k}}{dt} .$$

In various other aspects, system dynamics and reactive-energy constraints remain invariant under the imposition of a global phase. The network dynamics remain invariant to the imposition of a global phase component on all the network variables, and the conservation constraint is also satisfied in this case. The governing equations are given by:

$$\frac{\partial {V}_{i} ( t )}{\partial t} = j ( ω + {ω}_{{ϕ}_{g}} ) {σ}_{{V}_{i}} ( t ) {V}_{i} ( t ) - Δ {σ}_{{V}_{i}} ( t ) {V}_{i} ( t ) , \\ \frac{\partial {I}_{i} ( t )}{\partial t} = j ( ω + {ω}_{{ϕ}_{g}} + {ω}_{{ϕ}_{i}} ) {σ}_{i} ( t ) {I}_{i} ( t ) - {Δσ}_{{I}_{i}} ( t ) {I}_{i} ( t ) \qquad Eqn . ( 22 )$$

where ϕ_{g} is the global phase and

$${ω}_{{ϕ}_{g}} = \frac{d {ϕ}_{g}}{dt} .$$

In various additional aspects, reactive-energy constraints remain invariant with varying network dynamics under the imposition of a relative phase: The conservation constraints are satisfied on the introduction of a relative phase component between the voltage and current phasors of each node, even though the overall network dynamics change. The governing equations are given by:

$$\frac{\partial {V}_{i} ( t )}{\partial t} = j ( ω + {ω}_{{ϕ}_{{V}_{i}}} ) {σ}_{{V}_{i}} ( t ) {V}_{i} ( t ) - Δ {σ}_{{V}_{i}} ( t ) {V}_{i} ( t ) , \\ \frac{\partial {I}_{i} ( t )}{\partial t} = j ( ω + {ω}_{{ϕ}_{{I}_{i}}} + {ω}_{{ϕ}_{i}} ) {σ}_{{I}_{i}} ( t ) {I}_{i} ( t ) - Δ {σ}_{{I}_{i}} ( t ) {I}_{i} ( t ) \qquad Eqn . ( 23 )$$

where ϕᵢ=ϕ_{I}_{ᵢ}−ϕ_{V}_{ᵢ} is the relative external phase shift applied between the voltage and current phasors of the i^{th} node,

$${ω}_{{ϕ}_{{V}_{i}}} = \frac{d {ϕ}_{{V}_{i}}}{dt} and {ω}_{{ϕ}_{{I}_{i}}} = \frac{d {ϕ}_{{I}_{i}}}{dt} .$$

In another additional aspect, the model is dissipative and converges to limit cycle oscillations in steady state. The second order time derivatives of Equations (15) and (16) lead to the following:

$$\begin{matrix}\frac{{\partial }^{2} {V}_{i}}{\partial {t}^{2}} = j ω {σ}_{{V}_{i}} {\dot{V}}_{ι} + j ω {V}_{i} {\dot{σ}}_{{V}_{i}} - Δ {σ}_{{V}_{i}} {\dot{V}}_{i} + {\dot{σ}}_{{V}_{i}} {V}_{i} = \frac{- {ω}^{2} {σ}_{{V}_{i}}^{2} {V}_{i}}{limit cycles} + \frac{[ 1 + j ω ] {\dot{σ}}_{{V}_{i}} {V}_{i} - 2 j ω {σ}_{{V}_{i}} Δ {σ}_{{V}_{i}} {V}_{i} + {( Δ {σ}_{{V}_{i}} )}^{2} {V}_{i}}{dissipation} & Eqn . ( 24 ) \\ \frac{{\partial }^{2} {I}_{i}}{\partial {t}^{2}} = j ( ω + {ω}_{{ϕ}_{i}} ) {σ}_{{I}_{i}} {\dot{I}}_{ι} + j ( ω + {ω}_{{ϕ}_{i}} ) {I}_{i} {\dot{σ}}_{{I}_{i}} - Δ {σ}_{{I}_{i}} {\dot{I}}_{i} + {\dot{σ}}_{{I}_{i}} {I}_{i} = \frac{- {( ω + {ω}_{{ϕ}_{i}} )}^{2} {σ}_{{I}_{i}}^{2} {I}_{i}}{limit cycles} + \frac{\begin{matrix}[ 1 + j ( ω + {ω}_{{ϕ}_{i}} ) ] {\dot{σ}}_{{I}_{i}} {I}_{i} - \\ 2 j ( ω + {ω}_{{ϕ}_{i}} ) {σ}_{{I}_{i}} Δ {σ}_{{I}_{i}} {I}_{i} + {( Δ {σ}_{{I}_{i}} )}^{2} {I}_{i}\end{matrix}}{dissipation} & Eqn . ( 25 )\end{matrix}$$

The first terms in the RHS of Equations (24) and (25) correspond to stable limit cycle oscillations of all the phasors, while the other terms correspond to the dissipative effects in the network. This demonstrates that the network as a whole is essentially a coupled dissipative system that is capable of self-sustained oscillations under steady-state. Each individual state variable describing the network thus returns to the same position in its respective limit cycle at regular intervals of time, even when subjected to small perturbations.

### IV. Resonant Machine Learning Framework

In various aspects, the frameworks described above can be applied for constructing resonant machine learning networks. In general, the framework can applied to any learning network that optimizes a cost-function defined over a set of learning variables αᵢ as

$${min}_{\{ {α}_{i} \}} ℋ ( \{ {α}_{i} \} ) + h Ψ ( \{ {α}_{i} \} ) s . t . {\sum }_{i = 1}^{N} {α}_{i} = 1 , \\ {α}_{i} \geq 0 ∀ i = 1 , … , N . \qquad Eqn . ( 26 )$$

Here [symbol] ({αᵢ}) represents a loss-function which depends on the learning problem (e.g. supervised, unsupervised or semi-supervised) and the dataset under consideration (e.g., training data). The second term Ψ(·) in the objective function is any linear or nonlinear function which represents either (a) a regularization function, or (b) a penalty function used to satisfy optimization constraints. h is a hyperparameter which acts as a trade-off between [symbol] (·) and Ψ(·). Because αᵢ could be viewed as probability measure, the optimization framework in Equation (26) naturally lends itself to probabilistic learning models.

The above problem can be mapped to the resonant learning framework described above by substituting αᵢ=|Vᵢ|²+|Iᵢ|², to arrive at the following problem:

$${min}_{\{ \vert {V}_{i} \vert , \vert {I}_{i} \vert , \vert {ϕ}_{i} \vert \}} ℋ ( \{ \vert {V}_{i} \vert , \vert {I}_{i} \vert \} ) + h Ψ ( \{ \vert {V}_{i} \vert , \vert {I}_{i} \vert \} ) + β {\sum }_{i = 1}^{N} \vert {V}_{i} {\vert}^{2} \vert {I}_{i} {\vert}^{2} {cos}^{2} {ϕ}_{i} \\ s . t . {\sum }_{i = 1}^{N} \vert {V}_{i} {\vert}^{2} + \vert {I}_{i} {\vert}^{2} = 1 , \vert {ϕ}_{i} \vert \leq π ∀ i = 1. … , N \qquad Eqn . ( 27 )$$

Note that non-probabilistic learning problems can also be mapped to the probabilistic framework by imposing an additional constraint, as discussed in additional detail below.

A. One-Class Resonant SVM

In various aspects, the framework in Equation (27) can be used to design a resonant one-class SVM. The solution of a generic one-class SVM is obtained by solving the following optimization problem:

$${min}_{\{ {α}_{i} \}} \frac{1}{2} {\sum }_{i = 1}^{N} {\sum }_{j = 1}^{N} {α}_{i} K ( {x}_{i} , {x}_{j} ) {α}_{j} \\ s . t . {\sum }_{i = 1}^{N} {α}_{i} = 1 , 0 < {α}_{i} < \frac{1}{v N} ∀ i = 1 , … , N \qquad Eqn . ( 28 )$$

where X=[x₁, . . . , xᵢ, . . . , x_{N}]∈ [symbol] ^{N×D} is the D dimensional input dataset of size N, v∈{0, 1} is a parameter which controls the size of the decision surface, K(·, ·) is a positive definite Kernel function satisfying Mercer's conditions, and αᵢ's are the learning parameters.

The optimization problem above can be reformulated by replacing the inequality constraint with a smooth penalty or loss function Ψ(·) including, but not limited to, a logarithmic barrier, e.g.,

$$Ψ ( {α}_{i} , v ) = - log ( \frac{1}{v N} - {α}_{i} ) ,$$

yielding:

$$ℋ = \frac{1}{2} {\sum }_{i - 1}^{N} {\sum }_{j - 1}^{N} {α}_{i} K ( {x}_{i} , {x}_{j} ) {α}_{j} + h {\sum }_{i - 1}^{N} Ψ ( {α}_{i} , v ) \\ s . t . {\sum }_{i = 1}^{N} {α}_{i} = 1 \qquad Eqn . ( 29 )$$

The parameter h determines the steepness of the penalty function, where h→∞ implies an almost-accurate inequality constraint. An equivalent complex-domain representation in terms of voltages and currents in an LC network can be arrived at by considering αᵢ=|Vᵢ|²+|Iᵢ|² ∀i. In this case, the network is considered to be globally energy constrained, and all the individual units in the network have the same frequency co. The redefined learning problem is defined as follows:

$${min}_{\{ \vert {V}_{i} \vert , \vert {I}_{i} \vert \}} ℋ = {\sum }_{i = 1}^{N} {\sum }_{j = 1}^{N} ( \vert {V}_{i} {\vert}^{2} + \vert {I}_{i} {\vert}^{2} ) K ( {x}_{i} , {x}_{j} ) \times ( \vert {V}_{j} {\vert}^{2} + \vert {I}_{j} {\vert}^{2} ) + h {\sum }_{i = 1}^{N} Ψ ( \{ \vert {V}_{i} \vert , \vert {I}_{i} \vert , v \} ) \\ s . t . {\sum }_{i = 1}^{N} \vert {V}_{i} {\vert}^{2} + \vert {I}_{i} {\vert}^{2} = 1. \qquad Eqn . ( 30 )$$

Introducing the active-power dissipation regularization results in the following problem:

$${min}_{\{ \vert {V}_{i} \vert , \vert {I}_{i} \vert , \vert {ϕ}_{i} \vert \}} ℒ = {\sum }_{i = 1}^{N} {\sum }_{j = 1}^{N} ( \vert {V}_{i} {\vert}^{2} + \vert {I}_{i} {\vert}^{2} ) K ( {x}_{i} , {x}_{j} ) \times ( \vert {V}_{j} {\vert}^{2} + \vert {I}_{j} {\vert}^{2} ) + h {\sum }_{i = 1}^{N} Ψ ( \{ \vert {V}_{i} \vert , \vert {I}_{i} \vert , v \} ) + β {\sum }_{i = 1}^{N} \vert {V}_{i} {\vert}^{2} \vert {I}_{i} {\vert}^{2} {cos}^{2} {ϕ}_{i} \\ s . t . {\sum }_{i = 1}^{N} \vert {V}_{i} {\vert}^{2} + \vert {I}_{i} {\vert}^{2} = 1 , \vert {ϕ}_{i} \vert \leq π {∀}_{i} \qquad Eqn . ( 31 )$$

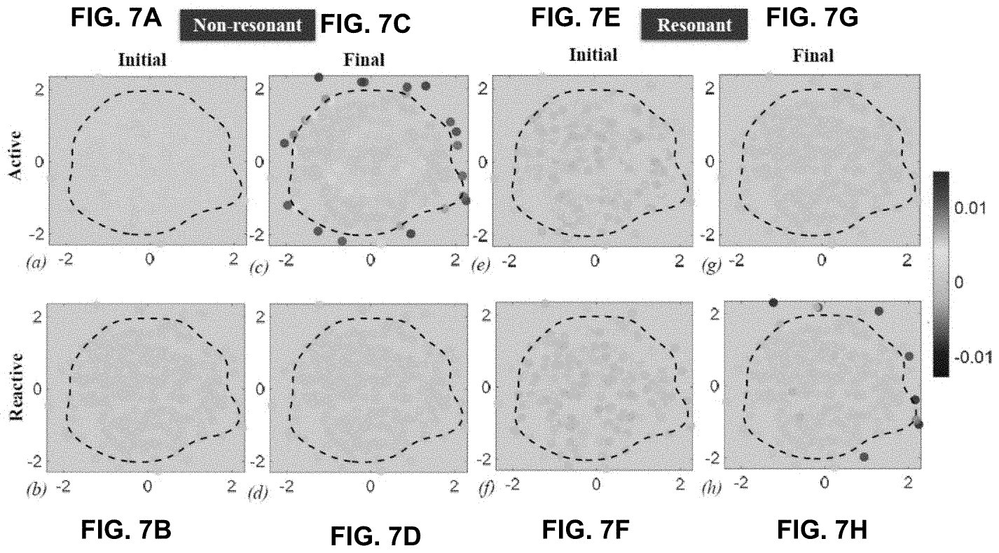

The update equations in this case are of the form shown in Equations (15)-(18) as described above. FIG. 7 shows a comparison of the active and reactive power metrics of each node of the non-resonant model, [symbol] ₙᵣ and the resonant model for a synthetic one-class SVM problem on a two-dimensional dataset (Dataset I). Here N=300, v=0.1, and ω=n/4, with random initializations for Vᵢ, Iᵢ, ϕᵢ∀i=1, . . . , N. A constant value of the regularization hyperparameter (3=1 was considered throughout the duration of the optimization process for Hr. FIGS. 7(a) and (c) show the values of the active power metric (=|Vᵢ∥Iᵢ|) at each node in the initial and final stages respectively for while FIGS. 7(b) and (d) show the values of the reactive power metric (=0) at each node in the initial and final stages respectively for, [symbol] ₙᵣ. Similarly, FIGS. 7(e) and (g) show the values of the active power metric (=|Vᵢ∥Iᵢ|cos ϕᵢ) at each node in the initial and final stages respectively fort while FIGS. 7(f) and (h), finally, show the values of the reactive power metric (=Vᵢ∥Iᵢ|sin ϕᵢ) at each node in the initial and final stages respectively for [symbol] ᵣ.

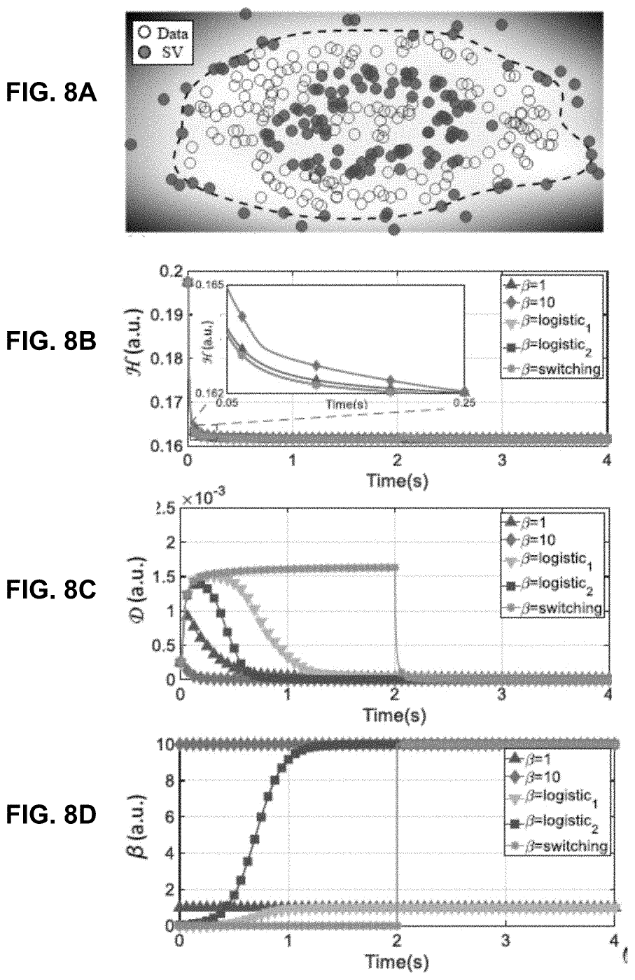

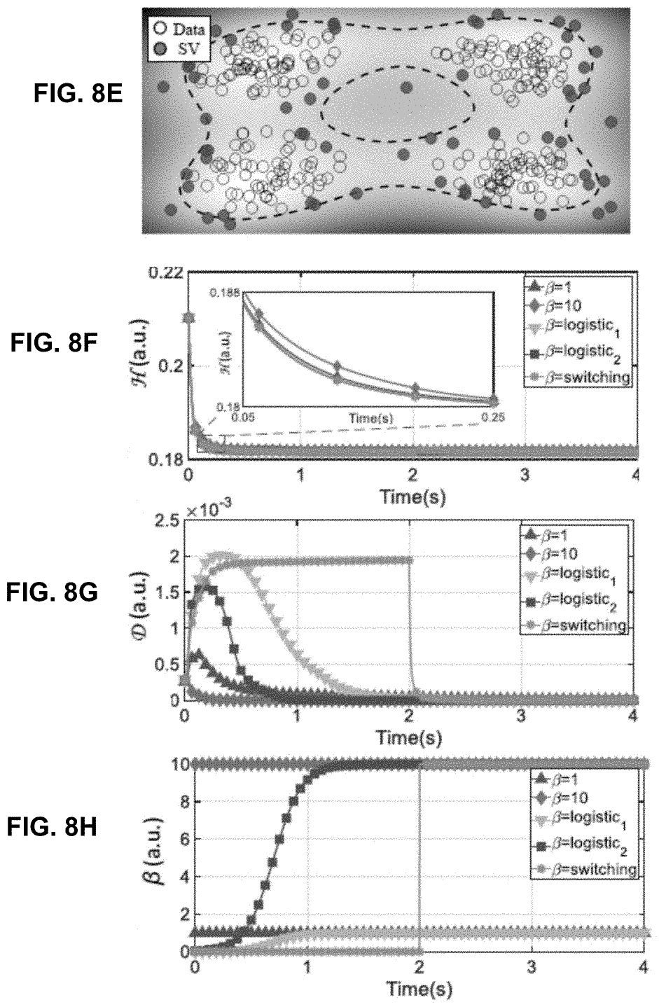

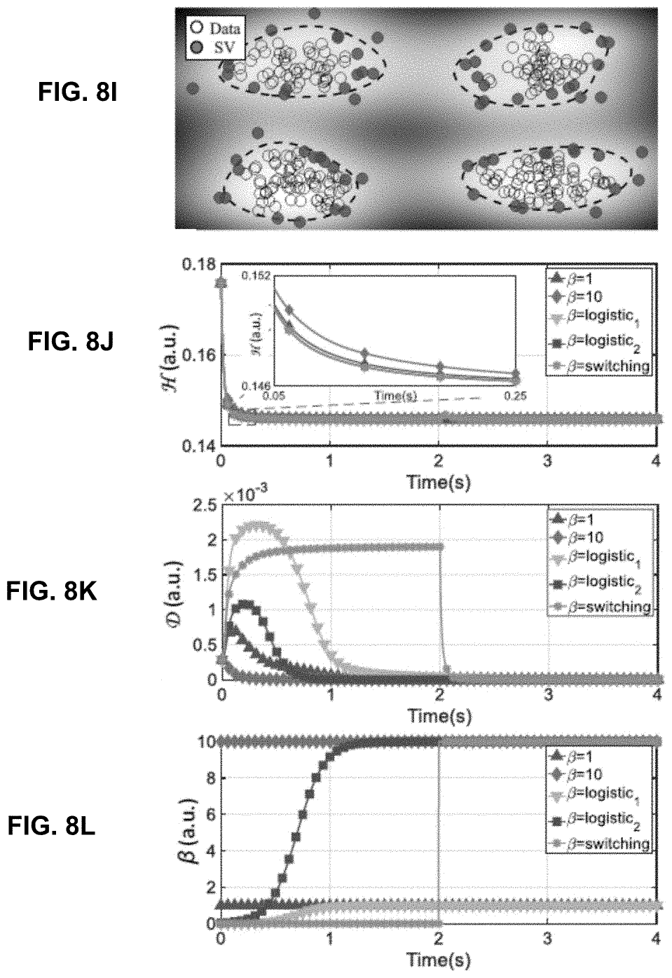

FIG. 8 shows a comparison of the performance of the resonant model for different choices of annealing schedules for β on three different two-dimensional synthetic datasets. In all cases, N=300, v=0.1, ω=π/20, and K(·, ·) was chosen to be a Gaussian kernel with parameter values σ=1, 10 and 20 respectively for synthetic Dataset I, II and III. Additionally for each dataset, Vᵢ, Iᵢ, and ϕᵢ were randomly initialized ∀i=1, . . . , N. FIG. 8(a) shows the contour plot with the decision boundary around the datapoints, along with the support vectors (SVs) for Dataset I, while FIGS. 8(b), (c) and (d) show the time evolutions of the cost [symbol] , the dissipation metric [symbol] and the hyperparameter β for different annealing schedules. The curves corresponding to β=1 and 10 denote the cases when β takes a constant value throughout the simulation duration. β=logistic₁ and β=logistic₂ correspond to the cases when β is slowly increased following a logistic curve of the form

$$β ( t ) = {β}_{min} + \frac{{β}_{max} - {β}_{min}}{1 + exp ( - κ ( t + {t}_{0} )}$$

and takes on maximum values of Omax=1 and Omax=10 respectively starting from r3 min=0. Finally, (3=switching corresponds to the case when 13 switches from a minimum value ((3 min=0) to a maximum value Wmax=10) at t=2 s, after the system has converged to the optimal solution. FIGS. 8(e)-(h) show similar plots on Dataset II, while FIGS. 8(i)-(l) show the plots corresponding to Dataset III. It can be seen that since the optimization problem is convex, the model converges to the optimal solution for every dataset, irrespective of the annealing schedule for β or the dataset complexity. However, the dissipation profiles corresponding to a particular annealing schedule strongly depend on the complexity of the dataset. In general, however, higher values of β typically lead to lower dissipation profiles during the learning process. Also, the model shows a much slower convergence in terms of the actual objective function for a constant non-zero value of β throughout the optimization compared to the case when β is slowly annealed to a sufficiently high value. The choice of a proper annealing schedule for β would thus involve a trade-off between the speed of convergence and the rate of power dissipation.

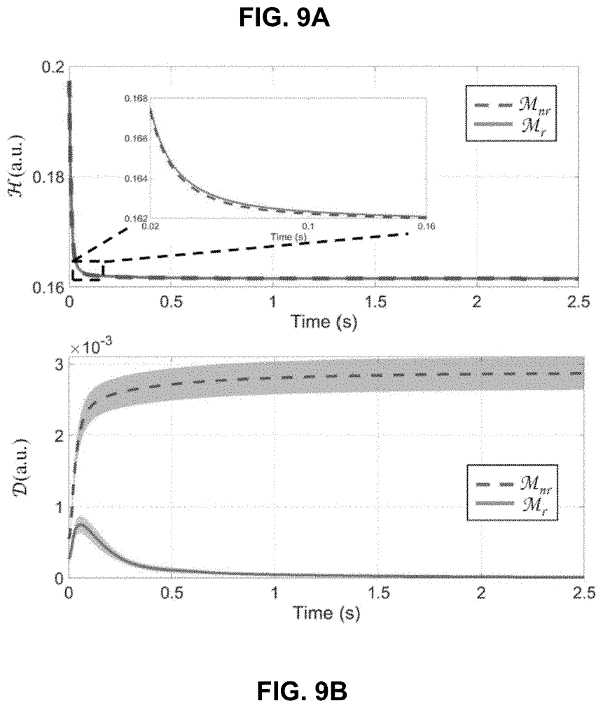

FIGS. 9(a) and (b) demonstrate the robustness of the disclosed framework to different initial conditions by providing a comparison of the time evolutions of the cost [symbol] and the dissipation metric [symbol] ( [symbol] _{N} Σᵢ₌₁^{N}|Vᵢ|²|Iᵢ|²) for the non-resonant model, [symbol] ₙᵣ and Σᵢ₌₁^{N}|Vᵢ|²|Iᵢ|² cos² ϕᵢ for the resonant model, [symbol] ᵣ respectively), when applied to Dataset I. The results for 10 random initializations of Vᵢ, Iᵢ and ϕᵢ, ∀i are shown illustrated in FIGS. 9(a) and (b). In all cases, v=0.1 and ω=n/8, and in addition K(·, ·) was chosen to be a Gaussian kernel with parameter value σ=1. Note that even though the 10 trials had different initializations of Vᵢ and Iᵢ, each trial had the same initial value of αᵢ in all cases, and consequently there is no deviation between the cost evolution curves for both, [symbol] ₙᵣ and [symbol] ᵣ. The dissipation evolution is however different across different trials for both the models. However, the dissipation attains a final value of zero for [symbol] ᵣ for all the trials, while there is a finite dissipation for [symbol] ₙᵣ in all cases.

In various aspects, a complex-domain formulation of a machine learning network that ensures that the network's active power is dissipated only during the process of learning whereas the network's reactive power is maintained to be zero at all times is disclosed. It was demonstrated that the active power dissipation during learning can be controlled using a phase regularization parameter. Also, the framework is robust to variations in the initial conditions and to the choice of the input/driving frequency co. The proposed approach thus provides a physical interpretation of machine learning algorithms, where the energy required for storing learned parameters is sustained by electrical resonances due to nodal inductances and nodal capacitances.

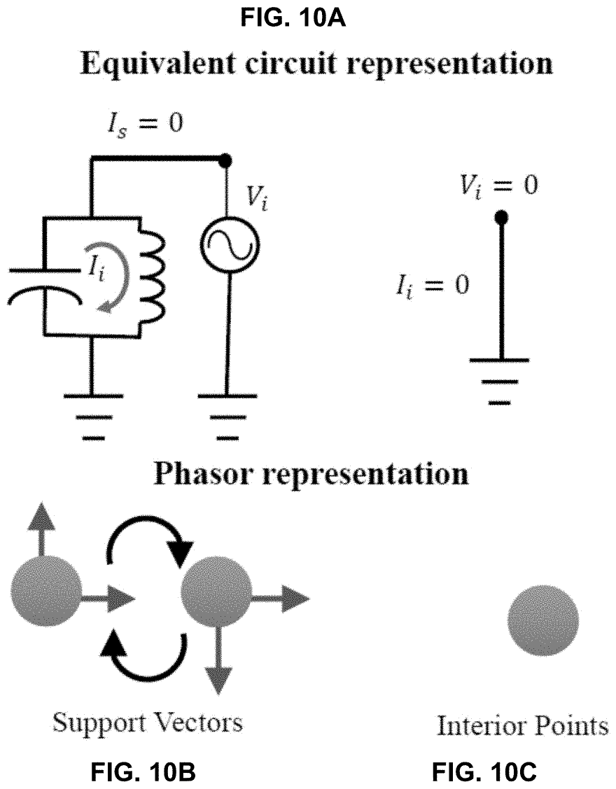

For instance, the solution of the one-class SVM, described in detail above, could be interpreted as follows, as illustrated in FIG. 10. The support vectors have voltage and current magnitudes with a ±n/2 phase shift between them, and hence can be interpreted as resonant LC tanks; In addition, the interior points well inside the boundary have both zero voltage and current magnitudes, and can be essentially treated as floating sinks.

In various additional aspects, network dynamics may be incorporated into the free frequency variable, and the phase information associated with each node may be utilized in the learning process. Although the methods and experimental results described herein are based on an unsupervised learning setting, the methods disclosed herein are suitable for use in developing an energy-efficient framework for supervised learning problems. Although the dynamical system models described herein are based on complex-domain growth transforms, the formulation is general enough to be applicable to other complex-domain learning models, where the disclosed approach may demonstrate a richer set of dynamics, robustness with respect to noise, and better convergence properties in the case of classification problems. Moreover, the phase information aspect of the disclosed methods may provide additional insights in the context of many complex valued physical signals (or complex domain transforms of physical signals, e.g., Fourier or wavelet transforms). Because the framework described herein preserves both the magnitude and phase information, the disclosed methods enable enhanced flexibility compared to other complex domain learning models in terms of phase manipulation/cancellation.

In addition to implementing classic machine learning algorithms, the complex growth transform dynamical system disclosed herein may also be used for designing synchronized networks of coupled oscillators. Such networks can be potentially used for solving different computing tasks like optimization, pattern matching etc. as is achievable using coupled oscillatory computing models. An oscillator network designed in this fashion is capable of demonstrating stable, self-sustaining oscillatory dynamics, whereby the network can return to its initial stable limit cycle configuration following small perturbations, while simultaneously minimizing some underlying system-level objective function. The framework disclosed herein may also be used to study connections between learning and synchronization and/or the emergence of a rhythmic periodic pattern exhibited by a group of coupled oscillators, which may enable enhanced understanding of a variety of periodic processes pervading complex networks of different biological, physical, social and quantum ensembles. In this regard, the existing mathematical models for such collective behavior are mostly phenomenological or bottom-up, and in general do not provide a network-level perspective of the underlying physical process. The disclosed growth-transform formulation, thus, could provide new network-level insights into the emergence of phase synchronization, phase cohesiveness and frequency synchronization in coupled-oscillator networks.

Data Sonification Using Complex Growth Transform Dynamical Systems

With the multitude of interdisciplinary data available in recent times, the search for better techniques for perceptualizing data before applying it to any learning or predictive task has continued to be one of the most important research areas over the past few decades. While visualization still remains the modality of choice for most applications, research on sonification, or the representation of data using human-recognizable audio signatures, is gaining momentum as a complementary or alternative modality to visual perception.

Some of the advantages of data sonification/audification, which make them ideal candidates for potentially augmenting, and in some specific applications, replacing visualization for analyzing the properties of the dataset, are as follows:

Temporal resolution for auditory perception is better than that for visual perception. This makes them suitable for time-varying data with complex patterns, which might otherwise be missed by visual displays.

Audio is orientation-agnostic and has a wider spatial range, since the user is not required to be oriented towards a particular direction. In contrast, objects need to be within the field of vision for the visual system. Humans typically respond faster to auditory feedback when compared to visual feedback.

In scenarios where the visual scene is crowded with multiple displays, or the visual system is otherwise occupied, auditory signals can be used as a means of drawing the user's attention to a particular segment of the visual field.

Auditory perception provides a natural alternative to shrinking display sizes, especially for monitoring and alerting applications.

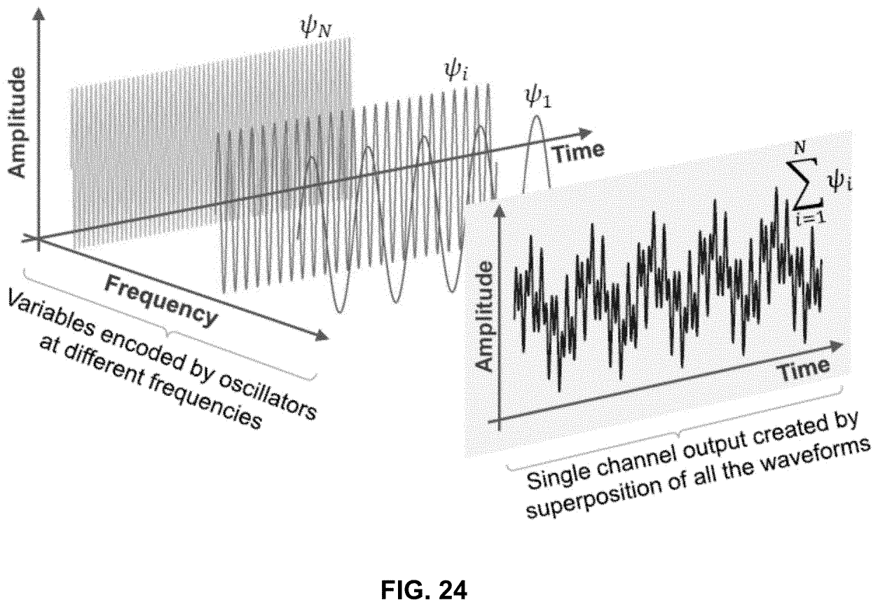

In this paper, we present a novel framework for sonifying high-dimensional data using a class of complex dynamical systems based on Baum-Eagon growth transforms. Given a continuously differentiable optimization problem defined on a conservation manifold, and sonification parameters like the sampling frequency, spectral range, maximum allowable loudness, maximum power content of the output signal etc., the proposed algorithm produces an audio signature which encodes both the complexity of the optimization problem, as well as the complexity of the dataset. The scope of the paper is illustrated in FIG. 24. At the core of the approach is a variant of the complex growth transform dynamical system. In this method, the variables involved in the optimization process are projected into a network of interacting limit cycle oscillators which correspond to the steady state solution of the optimization problem. The main model along with its properties is presented below, along with a detailed derivation of the same. In addition, various different choices of sonification strategies which can be adopted for the sonification module are described below in various aspects, all within the same basic framework.

The disclosed sonification method inherently maps a high-dimensional data into a lower-dimensional single-channel audio signal. This is particularly suitable when dealing with low throughput systems having limited capacity/bandwidth. The algorithm automatically combines the learning and sonification stages into a single module. This is unlike the sonification-based decision making algorithms existing in literature, which typically accomplish learning the decision parameters and mapping the same to different sound parameters in subsequent stages. However, similar to other sonification techniques, this method too involves a human-in-the-loop component, since the decision is ultimately taken by the end user.

In addition, the disclosed sonification method is versatile and can be tailored to accommodate a variety of learning models, problem dimensionality and dataset sizes. Additionally, the complex growth transform dynamical system provides a wide range of tunable parameters which can be customized for different applications.

A. Visualization of High-Dimensional Data

A variety of methods for visualization of high-dimensional data have been previously described. While elementary visualization schemes make use of different visual attributes like color, shape, size, spatial location etc. for representing information, almost all the standard visualization techniques typically use these after mapping the data to a lower dimensional (usually two or three dimensional) space. Some of the most commonly used techniques used in practice include linear techniques like PCA, LDA and their variants that only preserve the global structure of the data, while nonlinear methods like Locally Linear Embedding, Isomap, Laplacian EigenMap etc have been designed to preserve both global and local information. However, they are usually not very adept in preserving both global and neighborhood information in a single map. Stochastic neighborhood preserving approaches like tSNE and its variants have been proposed to alleviate these problems, however they suffer from scalability issues and do not perform well on noisy data. A more recent technique called PHATE proposed in the context of high-dimensional biological data was shown to preserve both local and global information, while simultaneously being scalable and noise robust.

However, these techniques are suitable for time-invariant or static data, and analysis of time-varying high-dimensional using these methods would involve visualizing the data frame-wise in a lower dimensional space. Though time-varying methods based on variants of the visualization techniques for static data have been proposed, e.g. m-tSNE, they lack interpretability and suffer from the same limitation of being restricted to only three dimensions for representing the data. Though other visual attributes like color, size, shape etc. can be used in conjunction with the three spatial dimensions, these may not be enough for complex datasets with very high dimensionality and can cause information overload of the visual system. The sheer magnitude and dimensionality of data available in recent times are slowly pushing the users to the limits of comprehension and interpretability of visual information. Additionally, existence of complex, time-varying patterns in the data are sometimes difficult to capture using only the visual faculties. Thus, employing sonification as an alternative or complementary modality would help users to interpret the data more effectively, or to draw their attention to the important aspects of the data which can then be monitored/analyzed by visual inspection.

B. Data Sonification and its Applications

Sonification, similar to its visual counterpart, provides a number of attributes which can be used for representing information, like pitch, loudness, timbre, rhythm, duration, harmonic content etc. At least two different sonification methods exist in literature depending on how the data is mapped into an audio signal. Of these, the parameter mapping method, where different variables can be mapped into different attributes of the sound signal to create a sonified signature, is the most commonly used. Parameter mapping based sonification has been used to a wide range of applications, ranging from sonifying astronomical data like gravitational waves and photons emitted by the Higgs bosons, to synthesizing novel protein structures and detecting anomalies in medical data (e.g. CT scans of Alzheimer's patients, EEG and ECG signals, skin cancer detection, epileptic seizure detection), detection of anomalous events etc. Sonification based detection of intrusion in networks, analysis of stock market data, and in therapeutic treatment of freezing of gait in Parkinson's patients by mapping kinematic data to the frequency of the sonified signal. More recently, sonification has been applied to the analysis of RNA sequences in different strains of the Covid19 virus. Unlike the visualization schemes, sonification offers a much wider parameter space for the variables to be mapped into. For example, humans can perceptualize sound signals anywhere from 20 Hz to 20 kHz, and frequency differences as low as 3 Hz are easily discernible by the human auditory system. However, in tasks that require the user to take a decision based on the data properties, usually the data is first passed through a machine learning or optimization module which learns the manifold the data resides in, and then maps the output to different properties of the sound signal to be sonified.

III. Sonification of an Optimization Problem Using Complex Growth Transforms

In this section, we introduce a novel framework for sonifying high-dimensional data while simultaneously solving an underlying optimization problem, by using a variant of the complex domain dynamical system model proposed in our previous work. The sonification algorithm has been summarized in Table 3, while the proof has been outlined in Appendix VIII-A. The method is not restricted to optimization problems defined over a probabilistic simplex, and can be extended to problems defined by constraints of the form |pᵢₖ|≤γ, γ>0 by a mapping procedure shown below.

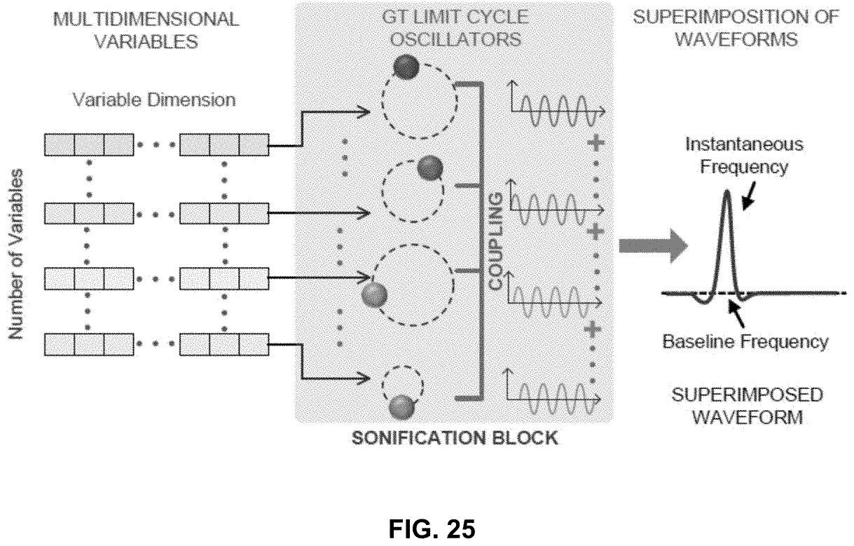

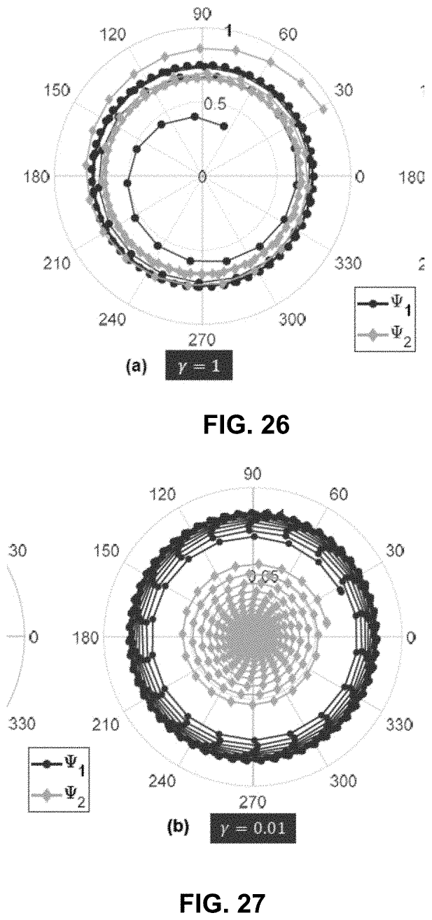

Note that the disclosed method is a type of parameter mapping based sonification, since different attributes of the data or optimization process are mapped to different parameters of the output sound signal. In particular, each variable or data point can be mapped to a complex growth transform limit cycle oscillator, subgroups of which are globally coupled together by some conservation constraint. This is illustrated in FIG. 25 for a group of N oscillators represented by sinusoidal waveforms Ψ₁, . . . , Ψ_{N} having different frequencies and amplitudes, and the output sonified signal is a complex single-channel waveform obtained by a superposition of all the oscillator waveforms, ie., Σᵢ₌₁^{N}Ψᵢ. The variables involved can be mapped into the baseline and relative frequencies, while both the amplitudes and frequencies get modulated during the optimization process. For example, if all the variables get mapped to the same constant value of baseline and relative frequencies, each oscillator frequency drifts from this constant value during the transient phase following which it again returns to the original trajectory. The frequency deviation during the transient phase should ideally encode the complexity of the optimization problem. This approach is illustrated in FIG. 26. Next, we show how different types of cost function [symbol] produce different types of sonified signatures. Without loss of generality, we will consider here that all the oscillators in the network have identical natural frequencies for better visualization of the network dynamics. We will consider both local and global couplings to demonstrate various properties of the optimization model. The sonified output signal is obtained by the superposition of all the wave functions generated by each individual oscillator, i.e., Ψₛᵤₘ(t)=Σᵢ₌₁^{N}Σₖ₌₁^{K}Ψᵢₖ(t).

TABLE 2

| Complex growth transform dynamical system | |
|---|---|
| Given a D-dimensional dataset X ∈ [symbol] ^{N×D}, and an optimization | |
| $\text{problem defined using the cost function} ℋ ( \{ {p}_{ik} \} ) \text{and gradients} \frac{\partial ℋ}{\partial {p}_{ik}} ,$ | |
| where pᵢₖ, i = 1, . . . , N, k = 1, . . . , K are the optimization variables | |
| Given desired psychoacoustic parameters og the sonified output | |
| signal like the sampling frequency Fₛ, bandwidth (f₁, f₂), maximum | |
| loudness M, maximum RMS power content Sᵣₘₛ | |
| For an optimization of the form: | |
| ${minimize}_{P ∈ D ⋐ {ℝ}_{+}^{N \times K}} ℋ ( P )$ $s . t . {\sum }_{k = 1}^{K} {p}_{ik} = 1 , ∀ i = 1 , … , N , {p}_{ik} \geq 0 , ∀ i , k$ | (32) (33) |
| Considering mapping pᵢₖ = \|ψik\|², if [symbol] (\|ψᵢₖ\|) is Lipschitz continous | |
| in D = {\|ψᵢₖ\|: Σₖ₌₁^{K}\|ψᵢₖ\|²} = 1, ∀i = 1, . . . , N, ψᵢₖ ∈ [symbol] }, the | |
| following system of complex nonlinear dynamical equations | |
| converges to the steady state solution of the above | |
| $\frac{\partial {ψ}_{ik} ( t )}{\partial t} = j ( {ω}_{ik}^{′} ( t ) + {ξ}_{ik} ( t ) {ψ}_{ik} + {ψ}_{ik} {△σ}_{ik} ( t ) \\ where {△σ}_{ik} = \sqrt{1 + {sin}^{2} ( {θ}_{i , n - 1} ) ( {σ}_{ik , n - 1}^{2} - 1 )} - 1 , \\ {σ}_{ik} = \sqrt{\frac{( - \frac{\partial ℋ}{\partial {ψ}_{ik}} + {λψ}_{ik}^{*} )}{{ψ}_{ik}^{*} {\sum }_{l = 1}^{K} {ψ}_{il} ( - \frac{\partial ℋ}{\partial {ψ}_{ik}} + {λψ}_{ik}^{*}}} , {ω}_{ik}^{′} = \frac{d {ϕ}_{i} ( t )}{dt} and \\ {ϕ}_{ik} = atan \{ tan ( {θ}_{i} ) {σ}_{ik} \} . {ω}_{i} = \frac{d {θ}_{i}}{dt}$ | (34) |
| is the baseline frequency of the i^{th} subgroup, and ξᵢₖ is the relative | |
| frequency associated with the ik-th variable. | |
| The baseline frequencies ωᵢ’s and the relative frequencies ξᵢₖ’s may | |
| be constant or time-varying themselves, and can be defined using | |
| any of the sonification strategies in Section IV. | |
| The final sonified output is obtained by superimposing all the | |
| waveforms corresponding to the individual oscillators, and then | |
| scaling it to have a maximum loudness (or intensity) M, or | |
| maximum RMS power Sᵣₘₛ, denoted by the scaling factor sₛᵤₘ: | |
| ψₛᵤₘ (t) = sₛᵤₘ Σᵢ₌₁^{N} Σₖ₌₁^{K} ψᵢₖ (t) | (35) |

By way of non-limiting example, consider a simple one-dimensional quadratic optimization problem given by:

$${ℋ}_{1} ( p ) = 8 {p}^{2} - 2 p s . t . \vert p \vert \leq γ \qquad Eqn . ( 36 )$$

Taking p=|ψ₁|²−|ψ₂|², where ψ₁, ψ₂∈ [symbol] , the above problem can be solved by using the complex growth transform dynamical system model. FIG. 27 shows the polar coordinate evolution plots of the waveforms ψ₁ and ψ₂ respectively, for two different choices of the parameter γ: (a) γ=1 and (b) γ=0.01. It can be seen that the oscillators corresponding to ψ₁ and ψ₂ converge to steady limit cycle oscillations for larger values of γ. However, for very small γ values, only the oscillator with the maximum amplitude shows sustained oscillations, while the other converges to the fixed point of zero and stops oscillating. The coupled oscillator network can thus be thought of as some form of a frequency tuner for sufficiently small values of γ.

By way of another non-limiting example, consider the following quadratic optimization problem:

$${ℋ}_{2} ( p ) = \frac{1}{2} a {p}^{T} Q p - {c}^{T} p s . t . \vert {p}_{i} \vert \leq γ ∀ i , a , γ ∈ {+}_{} , \\ and \\ C ∈ {N}^{} , Q ∈ {N \times N}^{} . \qquad Eqn . ( 37 )$$

Taking p=|ψ₁|²−|ψ₂|², where ψ₁, ψ₂∈ [symbol] , the above problem can be solved by using the complex growth transform dynamical system model. The final sonified output is then given by:

ψₛᵤₘ(t)=Σᵢ₌₁^{N}ψᵢ₁+ψᵢ₂(t).

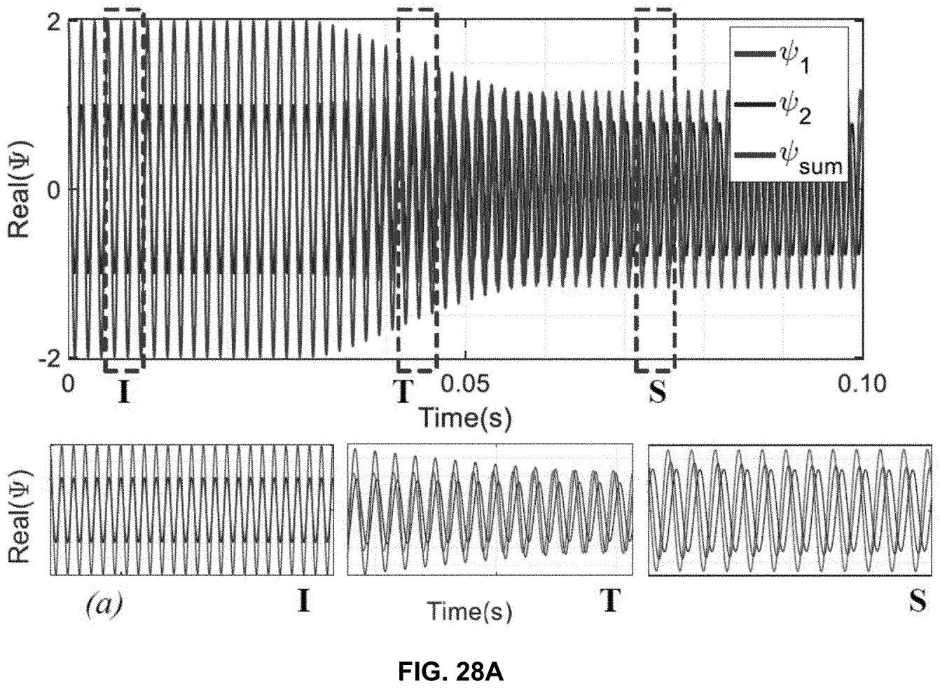

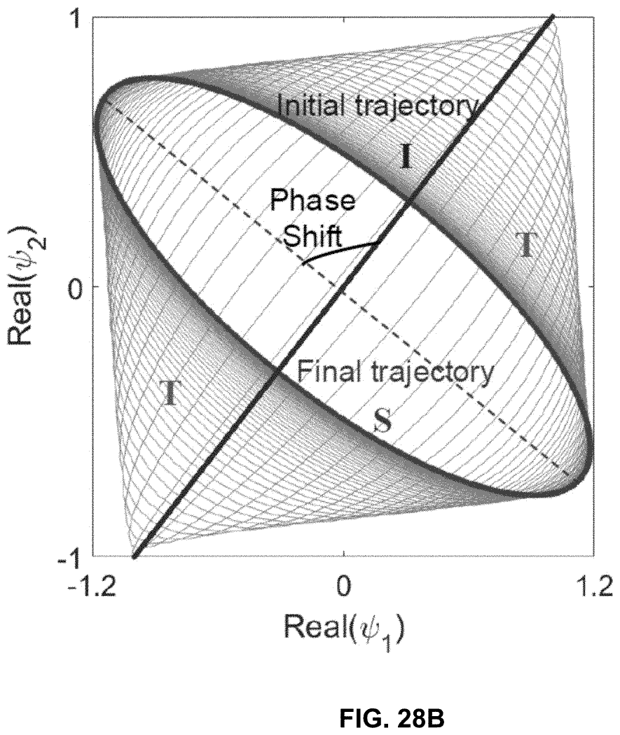

FIG. 28 shows the time evolutions and phase portrait for a one-dimensional problem (N=1), with a=1, Q=1, c=0.8 and γ=2. The sampling frequency was considered to be 22 kHz, and the natural/baseline frequency Ωᵢₖ=ω was chosen to be 600 Hz and the relative frequency ξᵢₖ was considered to be zero for all the oscillators. The simulation duration was 0.1 s, with the optimization onset being at 0.03 s for same initial amplitudes of ψ₁ and ψ₂, and zero initial phase difference between the waveforms. FIG. 28(a) shows the time evolutions for the waveforms ψ₁, ψ₂, and ψₛᵤₘ, along with their zoomed in views during the initial (I), transient (T) and steady-state (S) stages respectively. FIG. 28(b) shows the phase portrait between the real parts of ψ₁ and ψ₂. It can be seen that the two waveforms evolve over time from an initial state (I) of same amplitude and zero phase difference, through a transient phase (T) of varying amplitudes and phase difference, to a final steady state where ψ₁ and ψ₂ have constant values of amplitudes, and a constant phase difference between them. This thus results in a non-zero phase shift of the final trajectory of ψₛᵤₘ(t) from its initial trajectory.

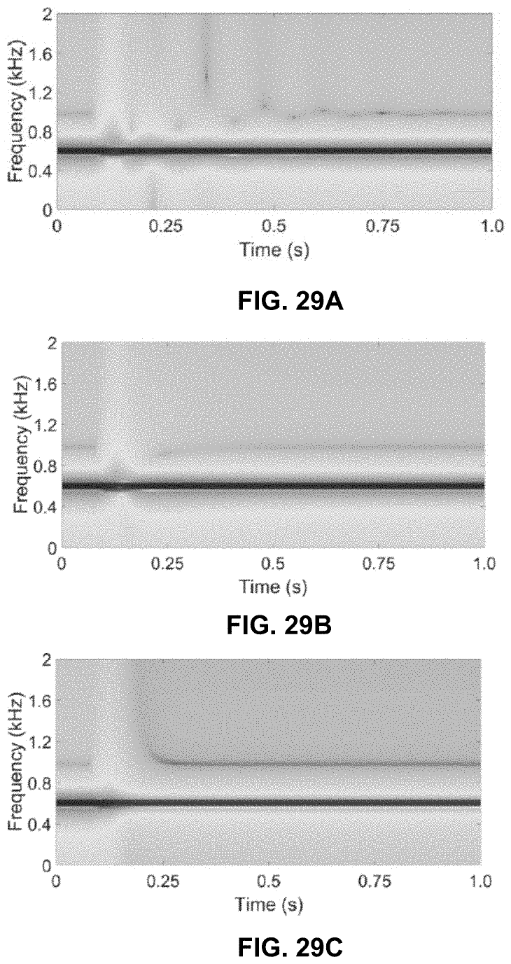

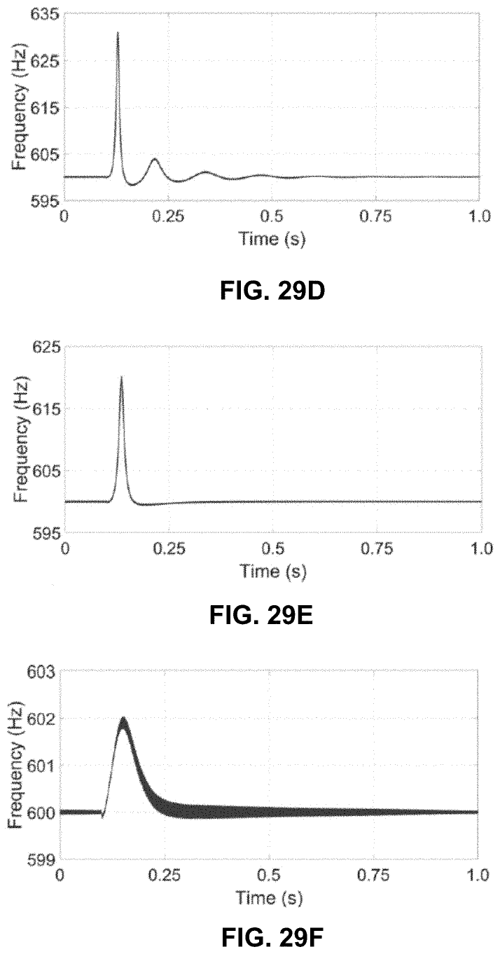

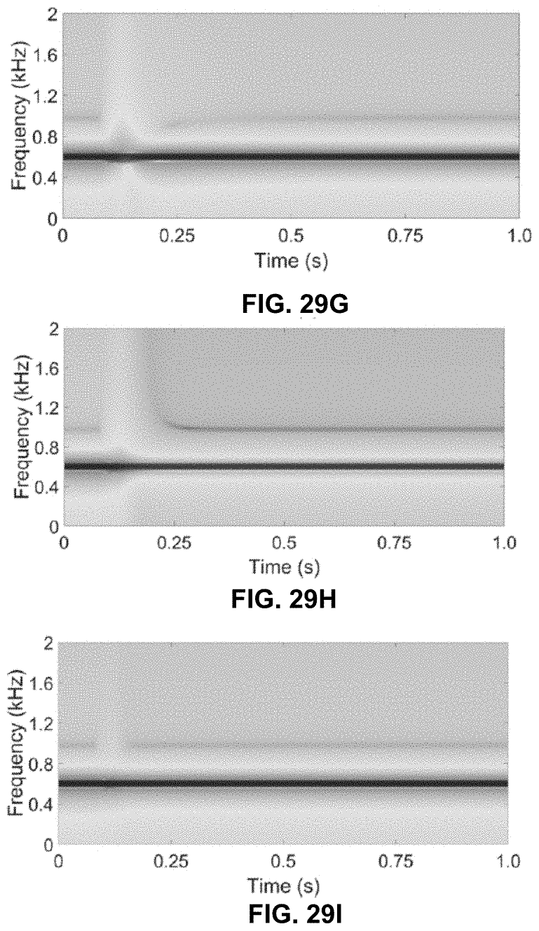

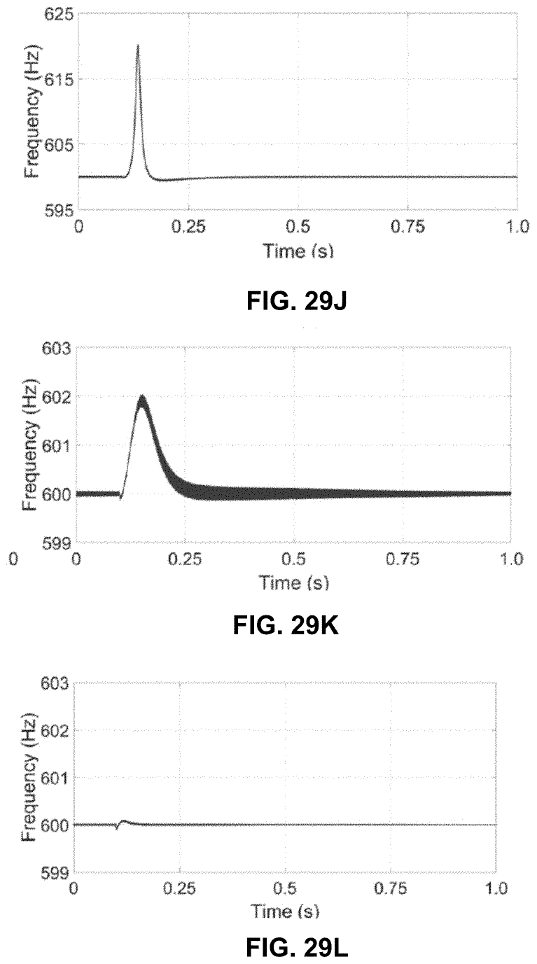

FIG. 29 demonstrates the model behavior for a two-dimensional form of the previous non-limiting example (i.e., N=2). As before, we consider all the four oscillators in this case, namely ψ₁₁, ψ₁₂, ψ₂₁, ψ₂₂ to have the same value of natural frequency ω=600 Hz and relative frequency ξᵢₖ=0. Simulations were carried out with Q=I₂, c=0.8 I₂, and considering different values of the optimization landscape steepness and the total energy available γ. FIGS. 29(a), 29(b), and 29 (c) show the spectrograms for the waveform ψₛᵤₘ(t), considering different levels of steepness level a=0.5, 1 and 2 respectively, and γ=1. In all cases, the spectrogram was computed using a 1024-point Short Time Fourier Transform (STFT) with a sliding Kaiser window of size 1024 and steepness parameter 5, with an overlap size of 1023. FIGS. 29(d)-(f) similarly show similar results for the same set of values fora and for a higher value of γ=2. The simulation duration is 1.0 s, and the optimization process starts 0.1 s after the start of the simulation. From the figures we can conclude that: (a) the duration of the transient phase as well as the magnitude of frequency shift during the same decreases with increase in the value of a, e, a steeper curve implies a faster optimization process and hence smaller values of frequency deviation; (b) higher value of the total energy γ leads to shorter transient phases with smaller frequency drifts. Thus in a sense, the complexity of the optimization problem is encoded in the final phase shift of the output signal from its initial phase.

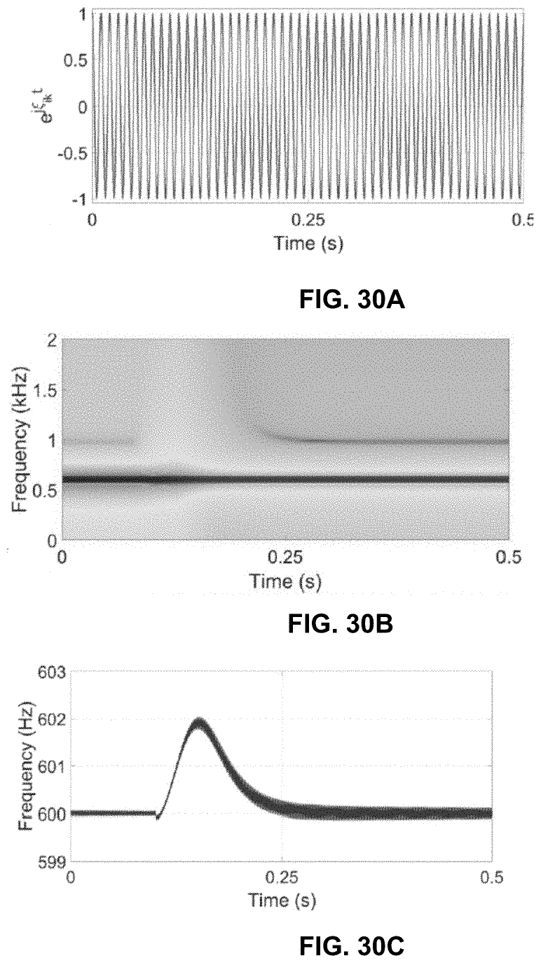

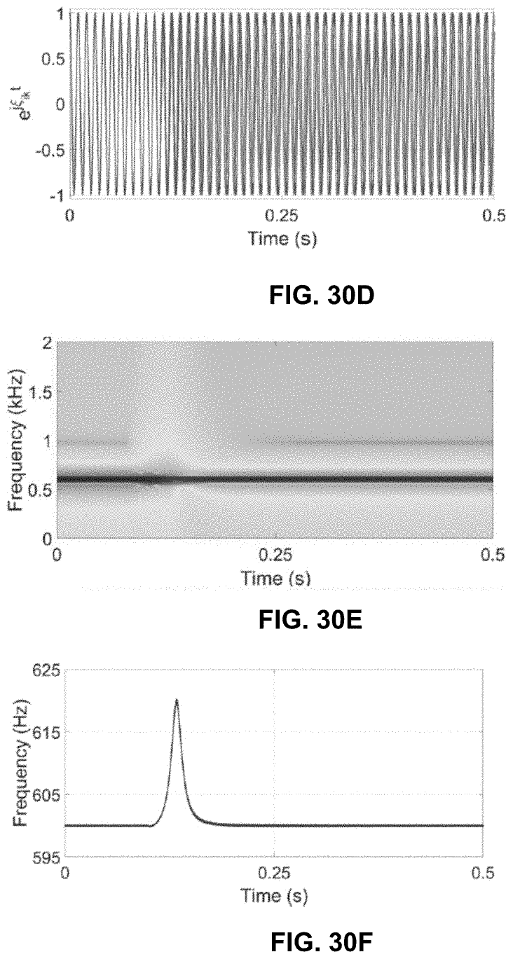

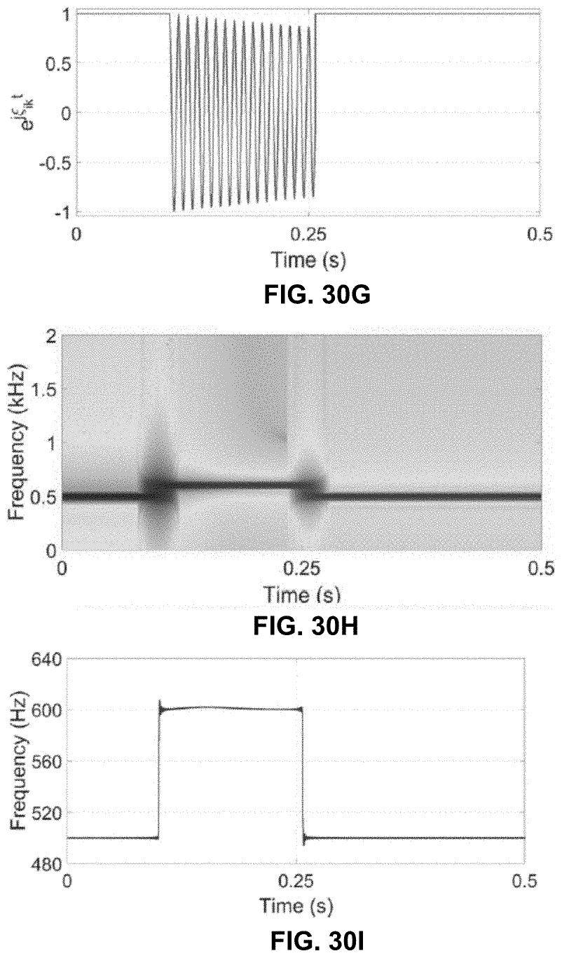

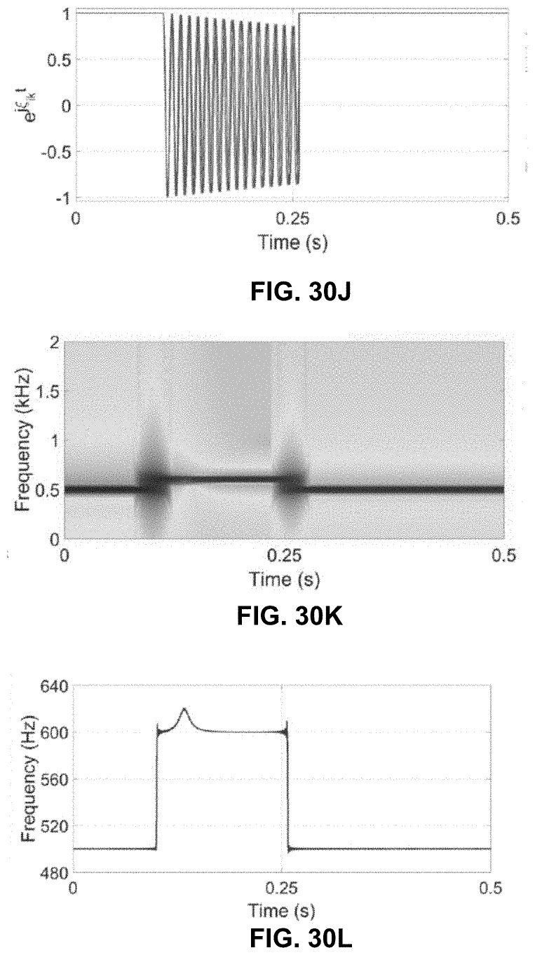

FIG. 30 similarly shows the spectrogram and instantaneous frequency plots for different choices of time evolution of the relative frequency ξᵢₖ∀i, k, again for the optimization problem of the previous non-limiting example and the same parameter settings as used in the simulations in FIG. 29. The natural frequency was chosen to be 100 Hz for all the oscillators, while the total simulation duration and the onset of optimization were is and 0.2 s respectively in all the following set of experiments.

Case 1: For the first set of simulations, the relative frequencies are chosen to be ξᵢₖ=ξ=500 Hz for all the oscillators, and no amplitude modulations or frequency modulations were added to the relative frequency trajectories. The plots of exp(jξᵢₖ t), which is a unit amplitude sinusoid with a constant frequency for all the oscillators in this case, are shown in FIG. 30(a). FIGS. 30(b) and 30(c) show the corresponding spectrogram and instantaneous frequency shift using Hilbert transform on the superimposed waveform ψₛᵤₘ(t).

Case 2: FIGS. 30(d)-(f) show similar results for the case when each relative frequency trajectory ξᵢₖ is modulated by the corresponding value of σᵢₖ, where σᵢₖ→1 in steady state, i.e., ξᵢₖ(t)=ξσᵢₖ(t). This type of frequency modulation thus incorporates information about the optimization process in the sonified output, and leads to faster convergence and larger frequency deviation compared to the output in Case 1.

Case 3: In this case, a varying amplitude term constant for each oscillator was added to the relative frequency term, and no frequency modulation was added. The multiplicative term in the update equation is thus replaced by exp(jξᵢₖt)←exp((−ρ+jξ)t), where ρ=1 was chosen for the experiment. FIGS. 30(g)-(i) show the relative frequency modulations, spectrogram and frequency deviation respectively for this case.

Case 4: In the last set of experiments, both the amplitude and frequency of the relative frequency trajectories were modulated for all the oscillators, i.e., exp(jξᵢₖt)←exp((−ρ+jξσᵢₖ(t))t). In both Cases 3 and 4, the relative frequencies were applied only during the transient phase of the simulation, and was set to zero during the initial stage as well as after convergence to a steady state. It can be seen that the frequency shift during the transient phase in Case 4 is significantly higher than all the other stages.

Based on the above experiments, we can thus encode information about the complexity of the optimization problem and the total energy available to the network. Also, different encoding strategies can be employed by exploiting the relative frequencies of the oscillators. Additionally, frequency selectors/tuners can also be implemented by assigning sufficiently lower levels of energy to the oscillator network, such that only the oscillator with the maximum energy content is sustained.

Sonification Strategies

Different sonification strategies can be adopted by considering different mapping schemes for both the baseline frequencies ωᵢ, and the relative frequencies ξᵢₖ. In a sense, the sonification process can be thought of as projecting high-dimensional data into a low-dimensional basis space cre-ated by predetermined frequency trajectories. We will present here three different strategies of sonifying data: (a) using frequencies equally spaced on the Bark-scale, (b) creating chords based on a musical scale of choice, and (c) extracting dominant frequency trajectories from a chosen musical piece and mapping the basis set of frequencies to these trajectories. For generating human recognizable auditory signatures, all the baseline and relative frequencies should lie within the range of human perception, i.e., 20 Hz-20 kHz. Furthermore, the largest frequency assigned to a variable should be less than the Nyquist frequency to avoid aliasing.

Some of the desirable characteristics of a candidate sonification strategy are as follows: 1) Different data distributions should be encoded by different sound signatures, depending on the underlying optimization task; 2) The complexity of the dataset or the underlying optimization problem should affect the output sound signature; and 3) For time-varying data, drift in the data distribution over time should lead to a drift in the sonified signal as well.

For example, if we consider clustering as the underlying optimization problem, where the number of allowable clusters (K) is fixed a priori, then we would ideally want the sonified output to give an indication of (a) the instantaneous cluster densities, (b) instantaneous separation between the clusters and (c) the time it takes for the optimization problem to converge to the optimal cluster assignments.

A. Bark Scale-Based Sonification

This method involves mapping the relative/baseline frequencies to equally spaced frequencies on the Bark scale. Any number of frequency trajectories can be selected if masking is acceptable in the end application. However, if we want to eliminate masking effects from the output sonified signal, the Bark scale frequencies should be chosen in a way such that the critical bands around these frequencies do not overlap with each other. Since the Bark scale has 24 critical bands, this implies that the number of frequencies in the basis set are limited to a maximum of 24 if we want to avoid masking. Additionally, the sonification module should be designed in a way that each frequency trajectory remains within its critical band on the Bark scale, even during the transient phase. The advantage of this method is that changes in each frequency trajectory (i.e., each sonified variable) can be discerned unambiguously, since there is no mixing of trajectories throughout the duration of sonification.

B. Musical Chord-Based Sonification

This approach is similar to the Bark scale-based approach, with the relative (or baseline) frequencies being mapped to a predetermined musical scale, e.g., the equally-tempered Western scale. Depending on the user requirements, we may create a chord by choosing notes in a single octave as the basis set. We can also select notes over multiple octaves, associating a different timbre to each, giving the impression of multiple different instruments being played. For example, we can map the frequencies to every other note in a diatonic scale such that they form a triad (e.g., the notes C, E and G form the C major triad in the equally-tempered scale around A₄=440 Hz). Similarly, four or more random notes from the same octave to create a generic chord. The method also allows for the creation of arpeggios (or a broken chord being played multiple times in succession) by suitably defining periodic repetitions of the set of chords. Overlapping of the frequency trajectories corresponding to different sonification variables may or may not occur, depending on (a) the pairwise distances between the frequency trajectories, and (b) the maximum extent of frequency perturbation caused by the sonification module. Additionally, since humans are more adept at recognizing time-varying audio signatures compared to static tones, a small slowly varying sinusoidal variation may be added on top of the original frequency trajectories. The amplitudes and frequencies of these sinusoidal variations may be either (a) kept constant, or made to vary based on (b) the convergence properties of the optimization problem, or on (c) the instantaneous statistical properties of the sonification variables.

C. Sonification Using an Existing Musical Piece

This method of sonification involves extracting a certain number of dominant frequency trajectories (depending on the desired size K of the basis set) from an existing musical piece. Additionally, the following steps need to be taken for extracting the dominant frequency trajectories from the chosen musical piece.

Typically, a musical piece may be much longer in duration compared to the simulation duration, and has a much higher sampling rate (44 kHz). Thus we would need to extract a segment of the entire composition and compress its time scale to ensure a proper mapping. Next, we analyze the spectrogram of the time-scaled musical sample and extract K dominant frequency components in each time window of the spectrogram, based on the power content of each frequency component in that window. Finally, we carry out upsampling and interpolation to form continuous frequency trajectories that represent K most dominant components of the musical composition.

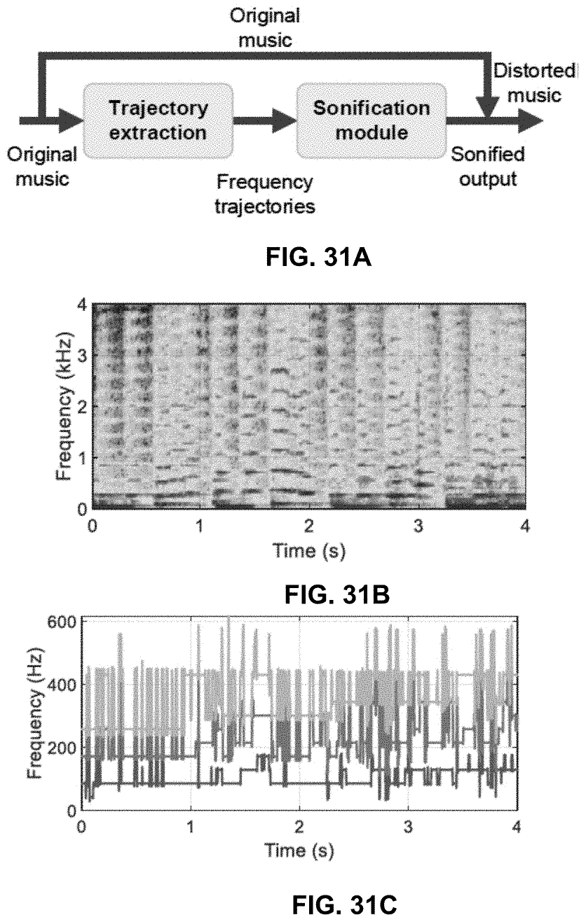

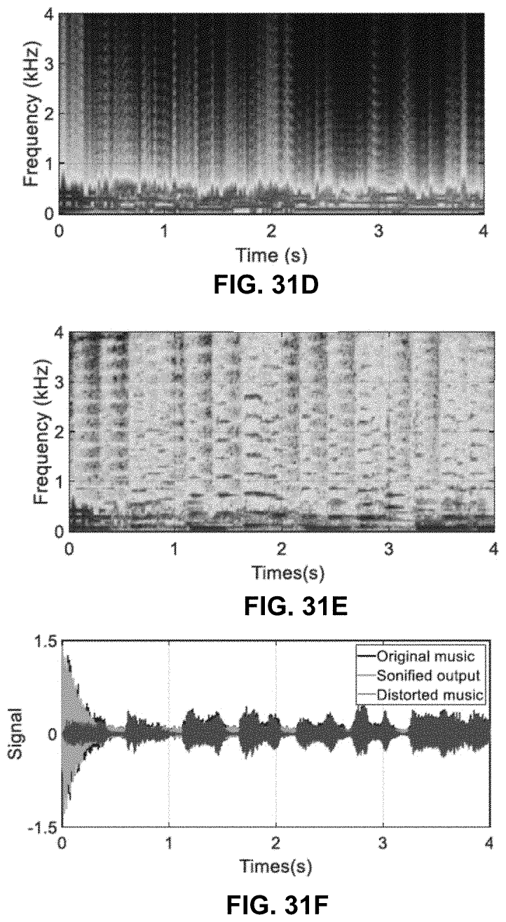

The sonification variables are then mapped to these frequency trajectories. During the sonification process, these trajectories undergo perturbations from their original time signature in the transient phase, depending on the dataset complexity and the optimization problem being solved. The baseline frequency perturbations may either remain unmodified, or can be made a function of the convergence properties only. They might also be made to depend on certain statistical properties of the dataset or the optimization variables. Finally, for better interpretability, the output of the sonification module can be treated as a “noise” signal and superimposed on the original musical composition. The degree of deviation of this super-imposed signal from the original composition thus encodes the complexity of the dataset and the optimization process. FIG. 31 shows an overview of the musical composition based sonification technique for a sample optimization problem, considering a basis set of size 3.

Experiments on Synthetic Datasets

A. Sonification of a Clustering Problem

As a case study, we will consider a data clustering problem, where the goal is to sonify the data by mapping each data cluster to a particular tone or frequency trajectory, and with the amplitude of each trajectory encoding the cluster density. Since the focus of the paper is on advocating a new sonification framework and not improving the efficiency of the particular clustering algorithm chosen, for the sake of simplicity we will consider a similarity-based probabilistic clustering approach. This involves solving a non-negative matrix factorization problem that minimizes the distance between a similarity matrix computed pairwise between the data points, and the actual likelihoods of the different data points to be clustered together in space. Considering a D-dimensional dataset X∈ [symbol] ^{N×D} and W∈ [symbol] ^{N×N} being the similarity matrix which computes some pairwise distance between the data points, the following optimization problem assigns each of the data points to each of K possible clusters:

$$ℋ ( P , β ) = {‖ W - β {P}^{T} P ‖}_{2}^{2} s . t . {\sum }_{k = 1}^{K} pik = 1 ∀ i = 1 , … , N \qquad Eqn . ( 39 )$$

Here, pᵢₖ denotes the probability of the i^{th} data point of belonging to the k^{th} cluster, and β denotes a scaling factor such that βpᵢpⱼ represents the true likelihood of the i^{th} data point of belonging to the k^{th} cluster. In this approach, each wᵢⱼ is assumed to be normally distributed about its corresponding true likelihood with mean μ and variance σ²∀i, k. Note that the similarity matrix can be chosen to encode any pairwise distance metric between the data points, e.g., W can be the RBF Kernel computed pairwise between the data points by mapping them to a high-dimensional space. Note that the sonification approach is generic enough and can be applied to other types of clustering algorithms like k-means, Gaussian mixture models, etc. Following the procedure outlined in Table 3 above, we can apply the mapping pᵢₖ=|ψᵢₖ|², ψᵢₖ∈ [symbol] . Sonification of the clustering problem can then be achieved in the following manner.

We assign the same baseline frequency to all the sub-groups (individual data points in this case), i.e., ωᵢ=ω∀i. Each cluster is assigned to a particular relative frequency trajectory according to the sonification strategy chosen, i.e., ξᵢₖ=ξₖ ∀i. Depending on the sonification strategy, the unperturbed version of the relative frequencies ξₖ (t) may be chosen according to one of the strategies described below.

Bark scale based: Each of the K clusters is mapped to a distinct frequency on the Bark scale (with or without masking effects, depending on the frequency spacing). A slow sinusoidal variation may be added about each orig-inal frequency trajectory depending on the instantaneous cluster density, as well as the convergence characteristics of the optimization problem. The relative frequencies are thus modulated over time governed by the following equation:

ξₖ(t)←ξₖ(t)[1+aₖ sin(2πbₖΔfₖ(t)t]sₖ Eqn. (40)

where

$$Δ {f}_{k} ( t ) = K \frac{{c}_{k} ( t ) - {c}_{k} ( 0 )}{{c}_{k} ( 0 )} , \\ {S}_{k} = \frac{1}{N} {\sum }_{i = 1}^{N} {σ}_{i k} .$$

aₖ, bₖ are real-valued scalar quantities, cₖ(0)=N/K is the initial cluster density (assuming the data points to be uniformly distributed among the clusters), and cₖ (t)=Σᵢ₌₁^{N}|ψᵢₖ|² an is the instantaneous cluster density of the k^{th} cluster.

Musical chord based: Each of the K clusters is mapped to a distinct frequency on a chosen musical scale. In this case too, a slow sinusoidal variation may be added about each original frequency trajectory depending on the instantaneous cluster density, as well as the convergence characteristics of the optimization problem. The evolution equations for ξₖ(t) are similar to those for the Bark scale-based method.

(c) Using an existing musical composition: Each of the K clusters is mapped to a distinct frequency trajectory extracted from the musical compostions. The instantaneous statistical properties of each cluster as well as the convergence properties of the optimization variables may be used as a scaling factor, in order to enhance the perturbations caused by the growth transform optimization framework. In this case, the evolution equations may have a sinusoidal variation as in the previous two approaches, or may be of the following form:

ξₖ(t)→ξₖ(t)[1+aₖΔfₖ(t)]sₖ Eqn. (41)

This is because the original frequency trajectories vary over time, and hence an additional sinusoidal perturbation for recognizing the audio signature in the steady state might not be necessary.

The update equation for β is given by:

$$β ← \frac{Tr ( {WP}^{T} P )}{{‖ {P}^{T} P ‖}^{2}} , \qquad Eqn . ( 42 )$$

while those of the complex waveforms ψᵢₖ are obtained using the complex growth transform updates in Table 3. The time evolution of ξₖ(t)∀i occurs according to the update rules, depending on the chosen sonification strategy.

The final output of the sonification module is obtained by superimposing the waveforms of all the oscillators, i.e., ψₛᵤₘ(t) Σᵢ₌₁^{N}Σₖ₌₁^{K}ψᵢₖ(t)

Next, we demonstrate the properties of the sonification technique when applied to the clustering problem for different sonification strategies, actual number of clusters in the dataset, dataset complexity (i.e., cluster alignments) and the number of clusters assigned a priori (i.e., the size of the basis set of frequencies K).

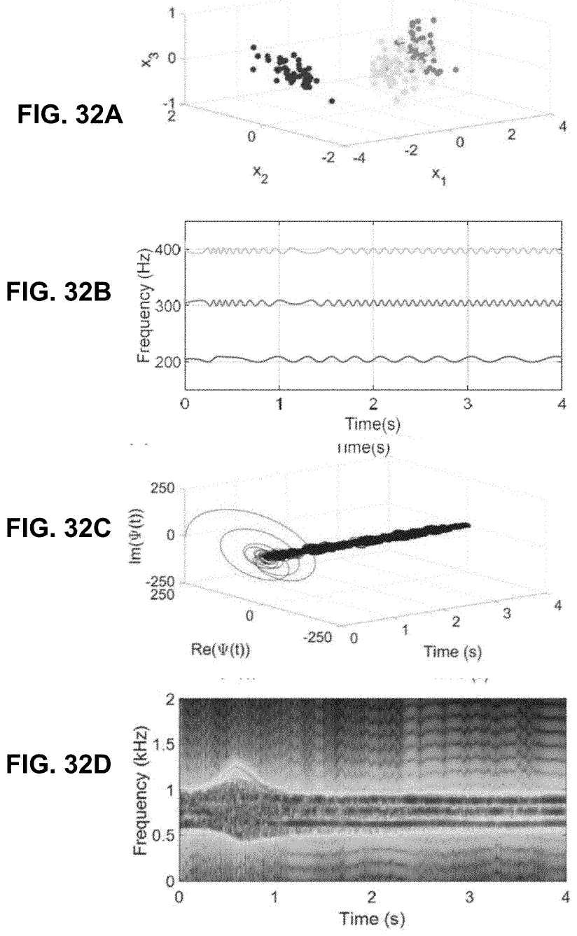

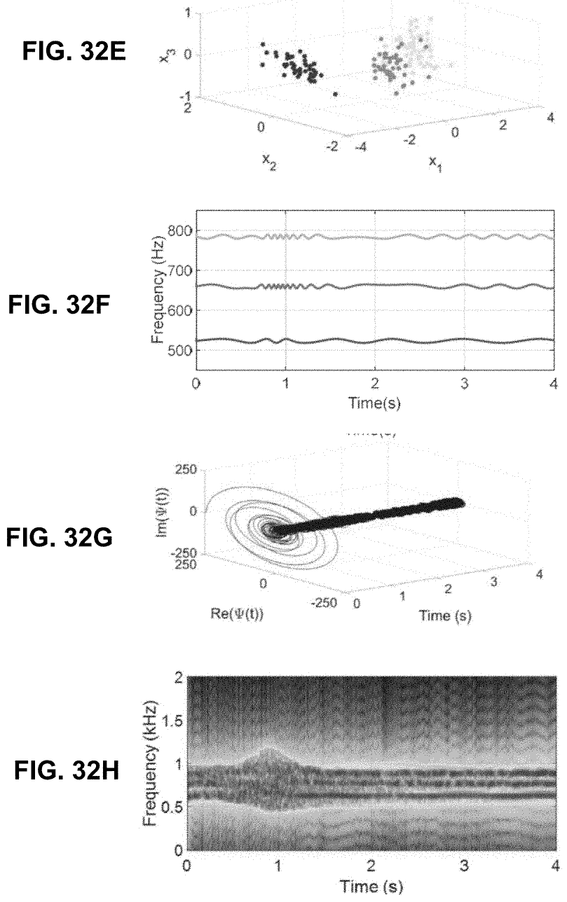

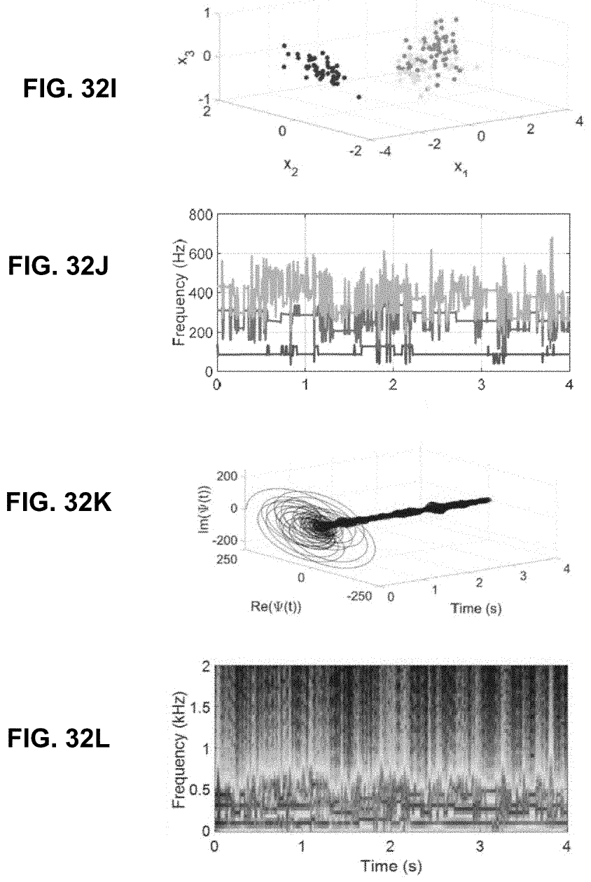

FIG. 32 shows the results on the ‘Iris’ dataset (N=150), considering a basis of size K=3, for all three types of sonification strategies discussed above. FIG. 32(a) shows a PCA plot of the data for reference, where the data points have been colored according to their cluster assignments by the complex growth transform based clustering algorithm. FIG. 32(b) shows the frequency evolution plots of the relative frequency trajectories chosen according to the Bark scale, with added sinusoidal variations, as discussed before. FIGS. 32(c) and 32(d) show the corresponding time evolution plot and the spectrogram respectively of the sonified output signal ψₛᵤₘ(t). FIGS. 32(e)-(h) show similar results for the musical scale based technique, while FIGS. 32(i)-(l) show those corresponding to the musical composition based sonification.

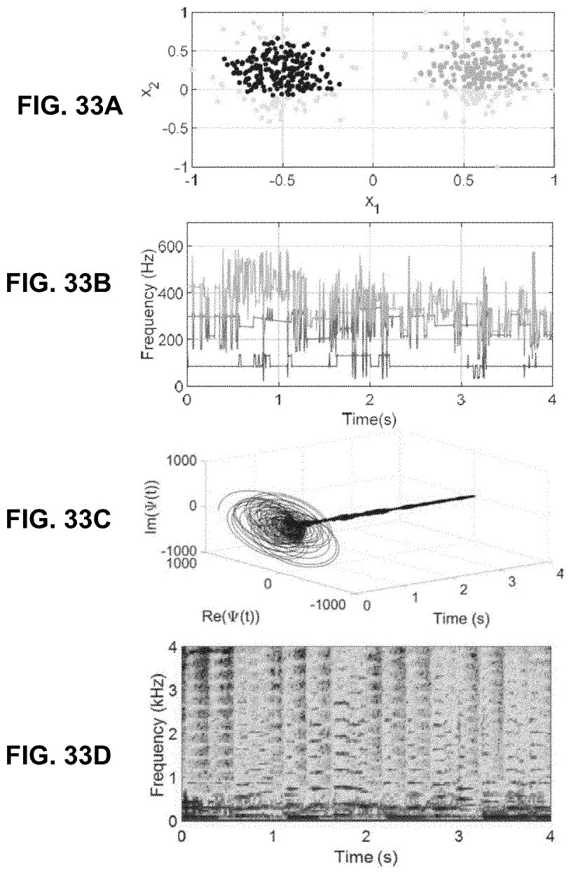

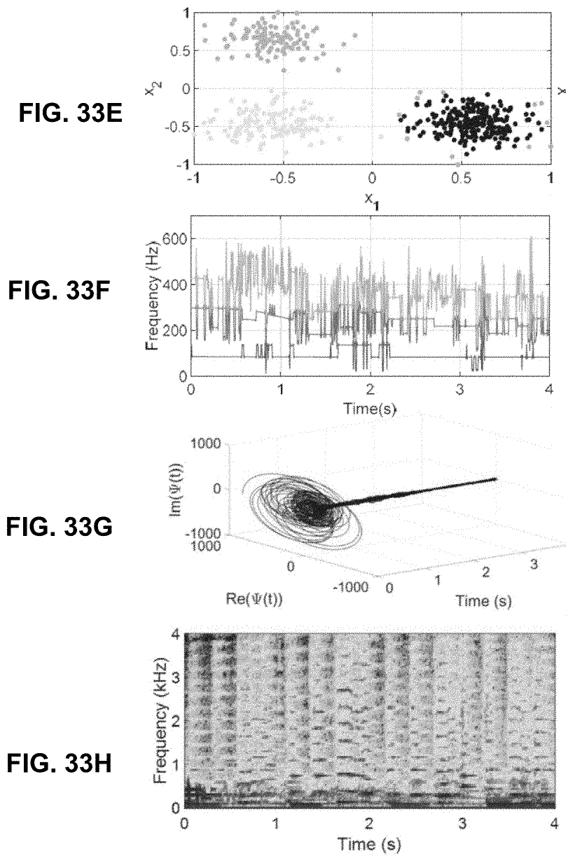

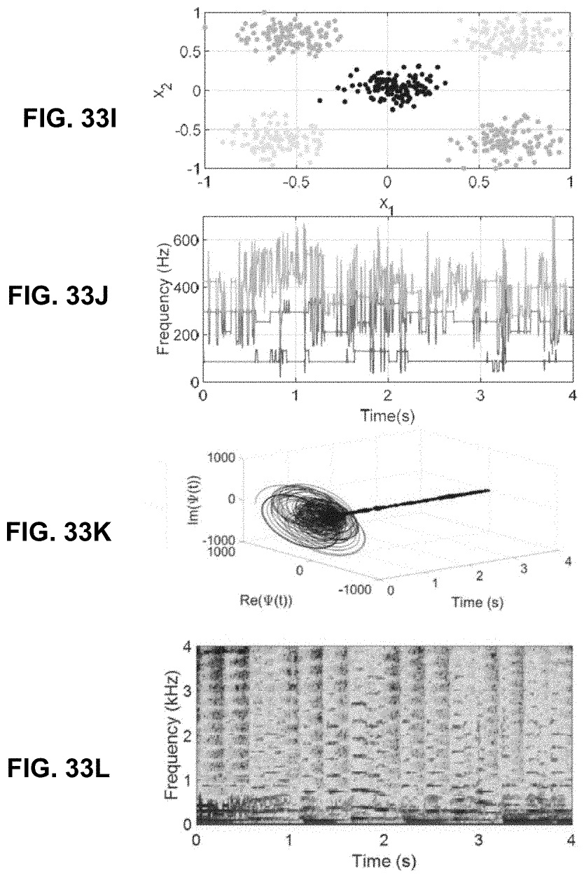

FIG. 33 shows the results of the sonification approach on synthetic Datasets I, II and III, each containing N=500 data points, but the number of underlying clusters being 2,3 and 5 respectively. FIG. 33(a) shows a scatter plot of Dataset I, with the points color-coded according to their cluster assignment, FIG. 33(b) shows the frequency evolutions, while FIGS. 33(c) and (d) show the time evolution and spectrogram of the sonified output, respectively. We consider the basis set to consist of 3 frequency trajectories (i.e., K=3) according to the musical composition based sonification strategy. FIG. 33 shows similar results on Datasets I, II and III, for a basis set of frequencies of size K=5.

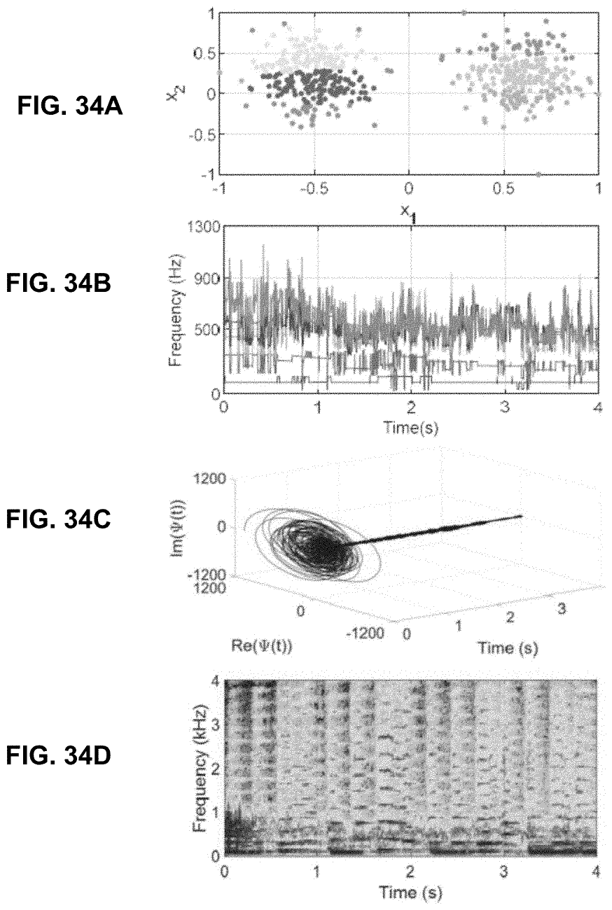

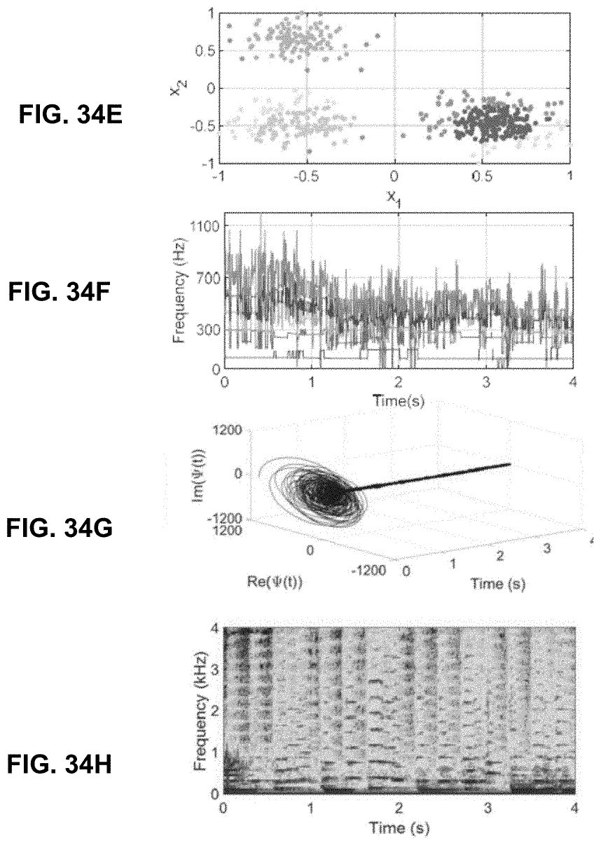

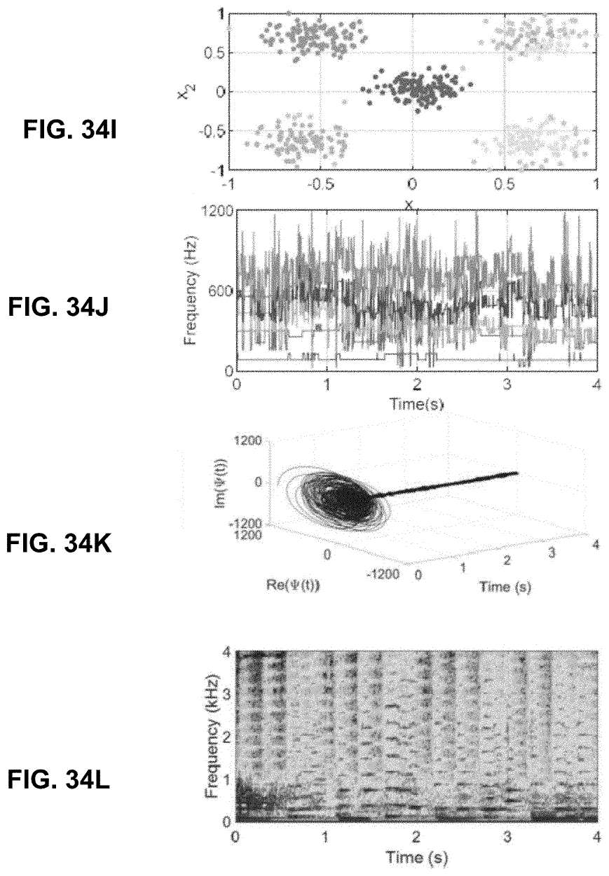

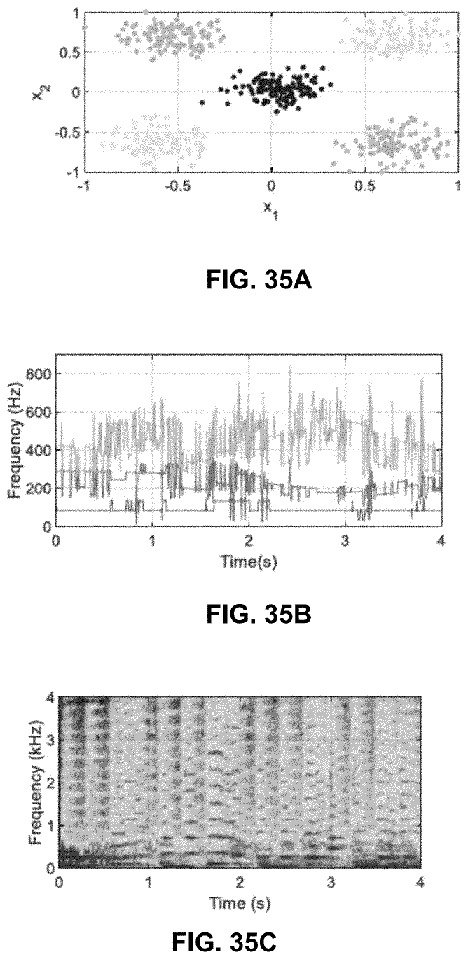

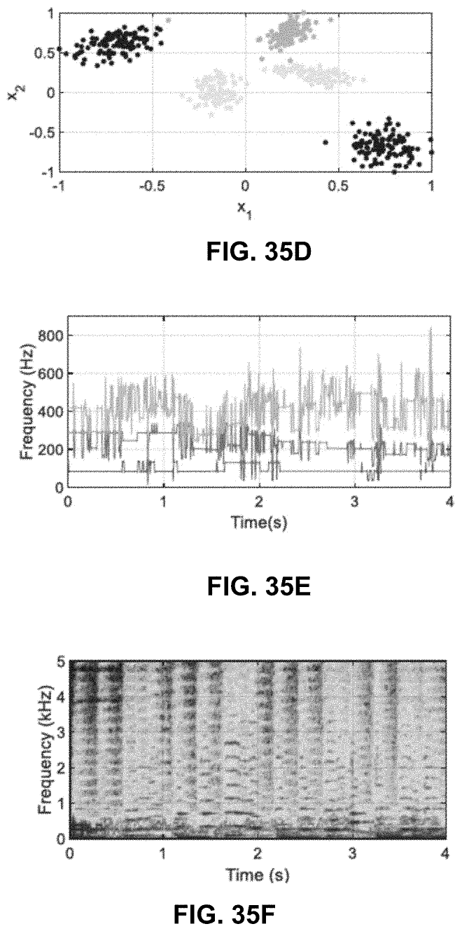

FIG. 34 shows the results of the experiments on Datasets III and IV, where both have the same number of data points (N=500) and 5 underlying clusters, but differ in the cluster alignments and geometries (which represents different data complexities).

Derivation of the Sonification Algorithm

Theorem 1: Considering ψ∈D^{C}={Ψ∈ [symbol] ^{N×K}:Σₖ₌₁^{K}|ψᵢₖ|²∀i=1, . . . , N}⊂ [symbol] ^{N×K}, a time evolution of the form given below converges to limit cycles corresponding to the optimal point of a Lipschitz continuous objective function H(|Ψ|²):

ψ_{ik,n}←ψ_{ik,n-1}[cos(θ_{i,n-1})+j sin(θ_{i,n-1})σ_{ik,n-1}(|ψₙ₋₁|²)] Eqn. (43)

where σᵢₖ→1 ∀i=1, . . . , N, k=1, . . . , M in steady state.

Proof: Consider a constrained optimization problem of the following form:

$$ℋ ( P ) , s . t . {\sum }_{k = 1}^{K} pik = 1 ∀ i = 1 , … , N , {p}_{i k} \geq 0 ∀ i , k \qquad Eqn . ( 44 ) , Eqn . ( 45 )$$

As described above, we used the Baum-Eagon inequality to show that the optimal point of a generic Lipschitz continuous cost function H(P), P∈D⊂ [symbol] ^{N×K}, the optimal point of the optimization problem represented by Eqns. (44) and (45), corresponds to the steady state solution of a multiplicative update-based discrete-time growth transform dynamical system model given by:

$${p}_{ik , n} ← [ ( 1 - {α}_{i , n - 1} ) {p}_{ik , n - 1} + {α}_{i , n - 1} {p}_{ik , n} {g}_{ik , n - 1} {P}_{n - 1} , \\ where \\ {g}_{ik , n - 1} {P}_{n - 1} = \frac{( - \frac{\partial H}{\partial {p}_{i k}} + λ )}{{Σ}_{l = 1}^{K} {p}_{il} ( \frac{\partial H}{\partial {p}_{il}} + λ )} , ∀ i = 1 , \text{...} M , and 0 \leq {α}_{i} \leq 1 ∀ i . \qquad Eqn . ( 46 )$$

The constant λ∈ [symbol] ₊ is chosen to ensure that

$$\vert - \frac{\partial H}{\partial {p}_{i k}} + λ \vert > 0 , {∀}_{i} , k .$$

The convergence also holds if the time-constants ai are time-varying, since this would still ensure the invariance of the manifold D.

Taking g_{ik,n-1}(Pₙ₋₁)=σᵢₖ²(Pₙ₋₁)∀i,k and α_{i,n-1}=sin² θ_{i,n-1}, we get:

p_{ik,n}←γ[(1−α_{i,n-1})p_{ik,n-1}+α_{i,n-1}p_{ik,n-1}(Pₙ₋₁)]←γ[cos²θ_{i,n-1}p_{ik,n-1}+sin²θ_{i,n-1}p_{ik,n-1}σ_{ik,n-1}²(Pₙ₋₁)] Eqn. (47)

Representing p_{ik,n}=ψ_{ik,n}ψ_{ik,n}, ψ_{ik,n}∈ [symbol] , the update equations become:

ψ_{ik,n}ψ_{ik,n}*←ψ_{ik,n-1}[cos(θ_{i,n-1})+sin(θ_{i,n-1})σ_{ik,n-1}(Pₙ₋₁)]×ψ_{i*k,n-1}[cos(θ_{i,n-1})+j sin(θ_{i,n-1})σ_{ik,n-1}(Pₙ₋₁)]* Eqn. (48)

Considering H(P)=H(|ψ|²) to be analytic in D^{C}, since by Wirtinger's calculus,

$$\begin{matrix}\frac{\partial H}{\partial {ψ}_{ik , n - 1}} = \frac{\partial H}{\partial {ψ}_{ik , n - 1} {ψ}_{ik , n - 1}^{*}} \cdot ( \frac{\partial {ψ}_{ik , n - 1} {ψ}_{ik , n - 1}^{*}}{\partial {ψ}_{ik , n - 1}} ) = \frac{\partial H}{\partial {ψ}_{ik , n - 1} {ψ}_{ik , n - 1}^{*}} \cdot {ψ}_{i k , n - {1}_{-}}^{*} , \\ we have & Eqn . ( 49 ) \\ {σ}_{i k , n - 1} ( {\vert {ψ}_{n - 1} \vert}^{2} ) = \sqrt{\frac{( - \frac{\partial H}{\partial {ψ}_{ik , n - 1}} + {λψ}_{ik , n - 1}^{*} )}{{ψ}_{ik , n - 1}^{*} {\sum }_{l = 1}^{K} {ψ}_{il , n - 1} ( \frac{\partial H}{\partial {ψ}_{il , n - 1}} + {λψ}_{il , n - 1}^{*} )}} & Eq . ( 50 )\end{matrix}$$

The discrete time update equations for ψ_{ij|n} is thus given by:

ψ_{ik,n}←ψ_{ik,n-1}[cos(θ_{i,n-1})+j sin(θ_{i,n-1})σ_{ik,n-1}(|Ψₙ₋₁|²)] Eqn. (51)

Theorem 2: A continuous-time variant of the coupled oscillator model given by Equation (43) is given by:

$$\frac{\partial {ψ}_{i k}}{\partial t} = j {ω}_{i} ( t ) {σ}_{i k} ( t ) {ψ}_{i j} \qquad Eqn . ( 52 )$$

Proof: Note that Eqn. (52) can be rewritten as:

ψ_{ik,n}←ψ_{ik,n-1}\tilde{σ}_{ik,n-1}exp jϕ_{ik,n-1}) Eqn. (53)

where \tilde{σ}_{ik,n-1}=\sqrt{1+sin²(θ_{i,n-1})(σ_{ik,n-1}²−1)}, σ_{ik,n-1} has been used to represent σᵢₖ (|ψₙ₋₁|²), and ϕ_{ik,n-1}=a tan{tan(θ_{i,n-1})σ_{ik,n-1}}.

Since

ψ_{ik,n}−ψ_{ik,n-1}←ψ_{ik,n-1}\tilde{σ}_{ik,n-1}[exp(jϕ_{ik,n-1})−1]+ψ_{ik,n-1}[\tilde{σ}_{ik,n-1}−1], Eqn. (54)

In the limiting case, this reduces to the continuous time update equation of the complex variable ψᵢₖ(t):

$$\frac{\partial {ψ}_{i k}}{\partial t} = j {ω}_{i k}^{′} ( t ) {ψ}_{i k} + {ψ}_{i k} Δ {σ}_{i j} ( t ) , \qquad Eqn . ( 55 )$$

where Δσ_{ik,n}=\tilde{σ}_{ik,n-1}−1, and ϕ_{ik,n-1}=ω′_{ik,n-1}Δt, where Δt is the sampling interval.

In the steady state, since H is Lipschitz continuous in

$${D}^{C} , {σ}_{i k} ( t ) {\to }^{t \to ∞} 1 ,$$

the dynamical system thus becomes:

$$\frac{\partial {ψ}_{i k} ( t )}{\partial t} = j {ω}_{i} ( t ) {ψ}_{i k} ( t ) , \qquad Eqn . ( 56 )$$

where θᵢ=ωᵢΔt. This thus implies that the steady state response of the complex variable ψᵢₖ(t) corresponds to steady oscillations with a constant angular frequency of ωᵢ.

Theorem 3: Different oscillation frequencies can be assigned to each each element in the dynamical system represented by Equation (43) by adding an instantaneous relative phase term as follows:

$$\frac{\partial {ψ}_{i k} ( t )}{\partial t} = j ( {ω}_{i k}^{′} ( t ) + {ξ}_{i k} ( t ) ) {ψ}_{i k} + {ψ}_{i k} Δ {σ}_{i k} ( t ) \qquad Eqn . ( 57 )$$

Proof: Considering φ_{ik,n-} to be the instantaneous relative phase of the ik^{th} element with respect to an absolute reference at the nt^{h} time instance, we have:

ψ_{ik,n}←ψ_{ik,n-1}\tilde{σ}_{ik,n-1}exp(jϕ_{ik,n-1})exp(jφ_{ik,n-1}) Eqn. (58)

This leads us to the following system of dynamical system equations:

ψ_{ik,n}−ψ_{ik,n-1}←ψ_{ik,n-1}\tilde{σ}_{ik,n-1}[exp(j(ϕ_{ij,n-1}+φ_{ik,n-1}))−1]+ψ_{ij,n-1}[\tilde{σ}_{ik,n-1}−1], Eqn. (59)

which in the limiting case leads to Equation (25), considering φ_{ik,n-1}=ξ_{ik,n-1}Δt.

Mapping a Generic Optimization Problem to the Equivalent Network Model

Let us consider an optimization problem of the following generic form:

$${min}_{{p}_{ik} ∈ {ℝ}_{+}} ℋ ( \{ {p}_{i k} \} ) s . t . \vert {p}_{i k} \vert \leq γ , γ ∈ {ℝ}_{+} ∀ i , k \qquad Eqn . ( 60 )$$

Consider pᵢₖ=pᵢₖ⁺−pᵢₖ⁻∀i, where both pᵢₖ⁺, pᵢₖ⁻≥0. Since by triangle inequality, |oᵢₖ|≤|pᵢₖ⁺|+|pᵢₖ⁻|, enforcing pᵢₖ⁺+pᵢₖ⁻=γ ∀i would automatically ensure |pᵢₖ|≤1 ∀i. Thus we have,

$${argmin}_{{p}_{ik}} ℋ ( \{ {p}_{i k} \} ) ≡ {argmin}_{\{ {p}_{ik}^{+} , {p}_{ik}^{-} \}} ℋ ( \{ {p}_{i k}^{+} , {p}_{i k}^{-} \} ) \qquad Eqn . ( 61 )$$

s.t.|pᵢₖ|≤γ,pᵢₖ∈ [symbol] s.t. pᵢₖ⁺+pᵢₖ⁻=pᵢₖ⁺,pᵢₖ⁻≥0

Finally, we replace

$${p}_{ik}^{+} ← \frac{{p}_{i k}^{+}}{γ} , {p}_{i k}^{-} ← \frac{{p}_{ik}^{-}}{γ}$$

to arrive at the following equivalent optimization problem over a probabilistic domain:

$${min}_{\{ {p}_{ik}^{+} , {p}_{ik}^{-} \}} ℋ ( \{ {p}_{i k}^{+} , {p}_{i k}^{-} \} ) s . t . {p}_{i k}^{+} + {p}_{i k}^{-} = 1 ∀ i , k . \qquad Eqn . ( 62 )$$

Computing Systems and Devices

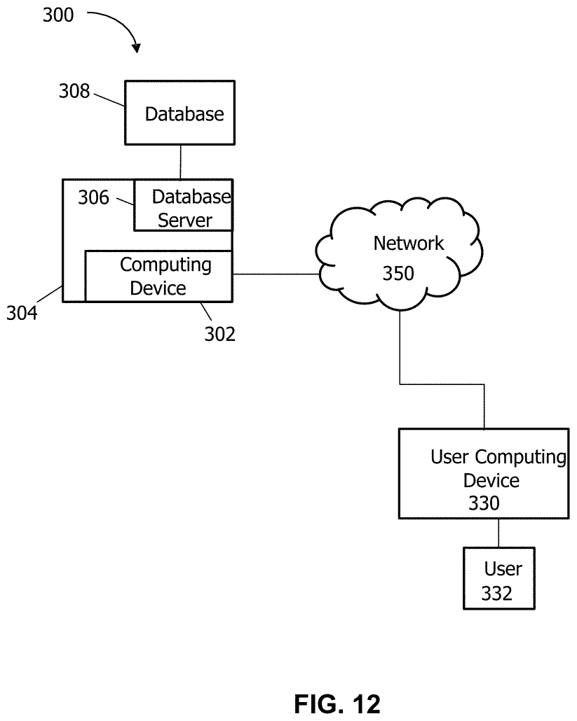

FIG. 12 depicts a simplified block diagram of a computing device 300 for implementing the methods described herein. As illustrated in FIG. 12, the computing device 300 may be configured to implement at least a portion of the tasks associated with disclosed method. The computer system 300 may include a computing device 302. In one aspect, the computing device 302 is part of a server system 304, which also includes a database server 306. The computing device 302 is in communication with a database 308 through the database server 306. The computing device 302 is communicably coupled to a user computing device 330 through a network 350. The network 350 may be any network that allows local area or wide area communication between the devices. For example, the network 350 may allow communicative coupling to the Internet through at least one of many interfaces including, but not limited to, at least one of a network, such as the Internet, a local area network (LAN), a wide area network (WAN), an integrated services digital network (ISDN), a dial-up-connection, a digital subscriber line (DSL), a cellular phone connection, and a cable modem. The user computing device 330 may be any device capable of accessing the Internet including, but not limited to, a desktop computer, a laptop computer, a personal digital assistant (PDA), a cellular phone, a smartphone, a tablet, a phablet, wearable electronics, smart watch, or other web-based connectable equipment or mobile devices.

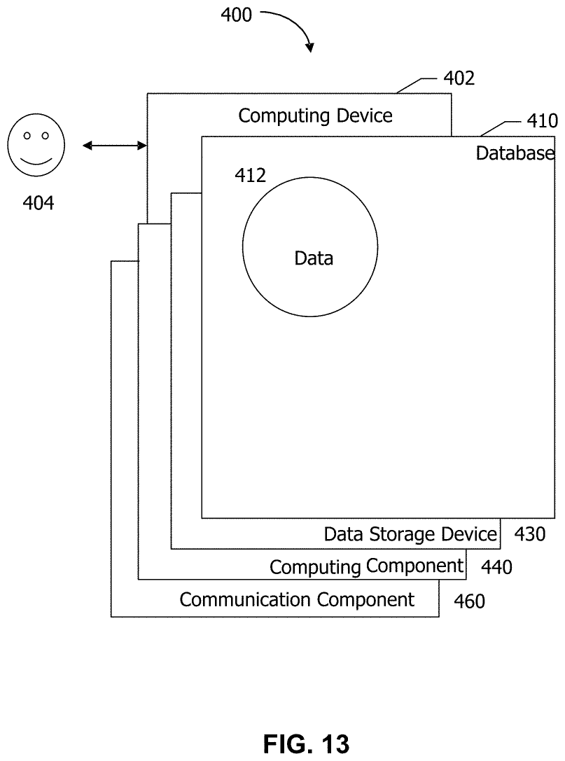

In other aspects, the computing device 302 is configured to perform a plurality of tasks associated with the disclosed method. FIG. 13 depicts a component configuration 400 of computing device 402, which includes database 410 along with other related computing components. In some aspects, computing device 402 is similar to computing device 302 (shown in FIG. 12). A user 404 may access components of computing device 402. In some aspects, database 410 is similar to database 308 (shown in FIG. 12).

In one aspect, database 410 includes various data 412. Non-limiting examples of suitable algorithm data 412 includes any values of parameters defining the disclosed method, such as any of the parameters from the equations described above.

Computing device 402 also includes a number of components which perform specific tasks. In the example aspect, computing device 402 includes data storage device 430, computing component 440, and communication component 460. Data storage device 430 is configured to store data received or generated by computing device 402, such as any of the data stored in database 410 or any outputs of processes implemented by any component of computing device 402. Computing component 440 is configured to perform the tasks associated with the method described herein in various aspects.

Communication component 460 is configured to enable communications between computing device 402 and other devices (e.g. user computing device 330 shown in FIG. 12) over a network, such as network 350 (shown in FIG. 12), or a plurality of network connections using predefined network protocols such as TCP/IP (Transmission Control Protocol/Internet Protocol).

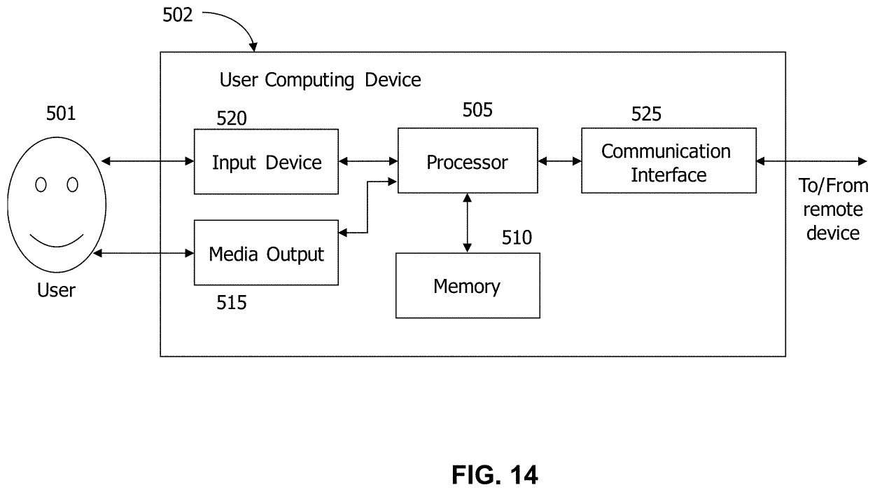

FIG. 14 depicts a configuration of a remote or user computing device 502, such as user computing device 330 (shown in FIG. 12). Computing device 502 may include a processor 505 for executing instructions. In some aspects, executable instructions may be stored in a memory area 510. Processor 505 may include one or more processing units (e.g., in a multi-core configuration). Memory area 510 may be any device allowing information such as executable instructions and/or other data to be stored and retrieved. Memory area 510 may include one or more computer-readable media.

Computing device 502 may also include at least one media output component 515 for presenting information to a user 501. Media output component 515 may be any component capable of conveying information to user 501. In some aspects, media output component 515 may include an output adapter, such as a video adapter and/or an audio adapter. An output adapter may be operatively coupled to processor 505 and operatively coupleable to an output device such as a display device (e.g., a liquid crystal display (LCD), organic light emitting diode (OLED) display, cathode ray tube (CRT), or “electronic ink” display) or an audio output device (e.g., a speaker or headphones). In some aspects, media output component 515 may be configured to present an interactive user interface (e.g., a web browser or client application) to user 501.

In some aspects, computing device 502 may include an input device 520 for receiving input from user 501. Input device 520 may include, for example, a keyboard, a pointing device, a mouse, a stylus, a touch sensitive panel (e.g., a touch pad or a touch screen), a camera, a gyroscope, an accelerometer, a position detector, and/or an audio input device. A single component such as a touch screen may function as both an output device of media output component 515 and input device 520.

Computing device 502 may also include a communication interface 525, which may be communicatively coupleable to a remote device. Communication interface 525 may include, for example, a wired or wireless network adapter or a wireless data transceiver for use with a mobile phone network (e.g., Global System for Mobile communications (GSM), 3G, 4G or Bluetooth) or other mobile data network (e.g., Worldwide Interoperability for Microwave Access (WIMAX)).

Stored in memory area 510 are, for example, computer-readable instructions for providing a user interface to user 501 via media output component 515 and, optionally, receiving and processing input from input device 520. A user interface may include, among other possibilities, a web browser and client application. Web browsers enable users 501 to display and interact with media and other information typically embedded on a web page or a website from a web server. A client application allows users 501 to interact with a server application associated with, for example, a vendor or business.

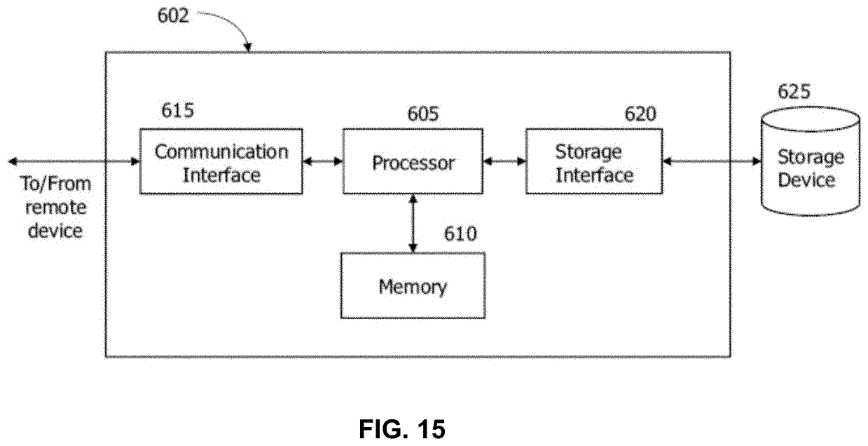

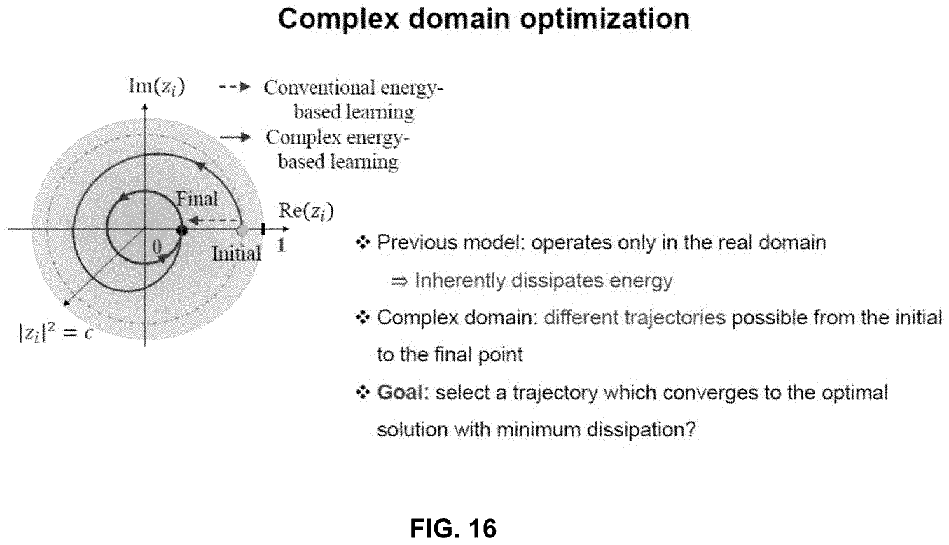

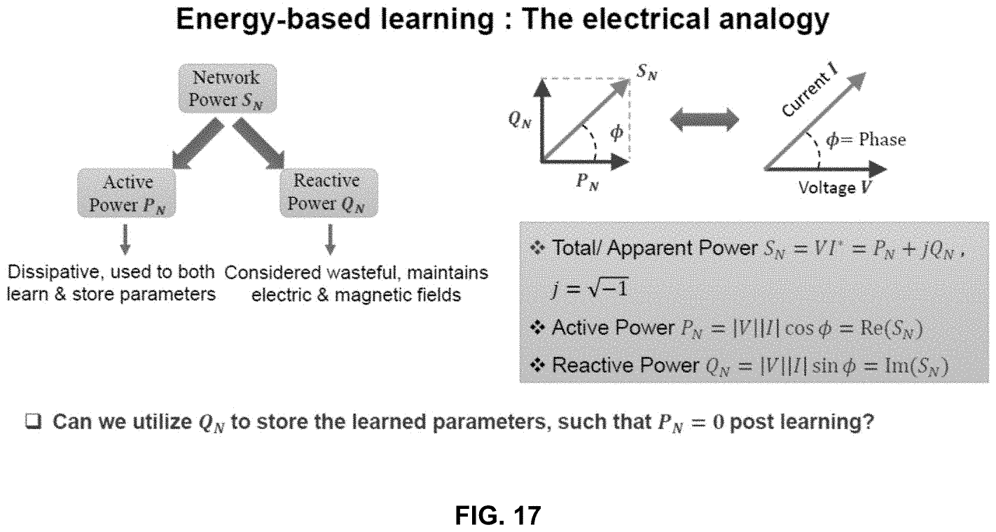

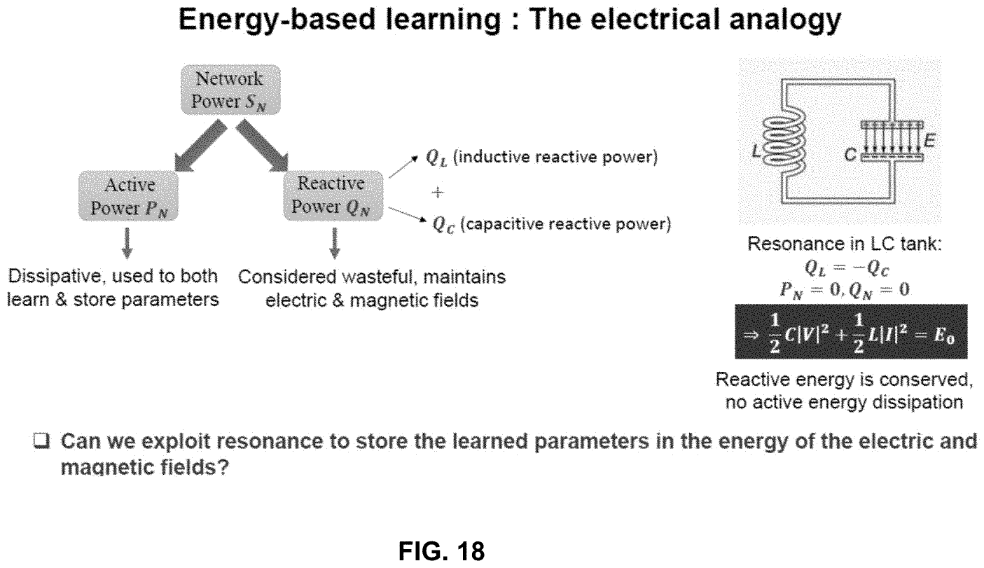

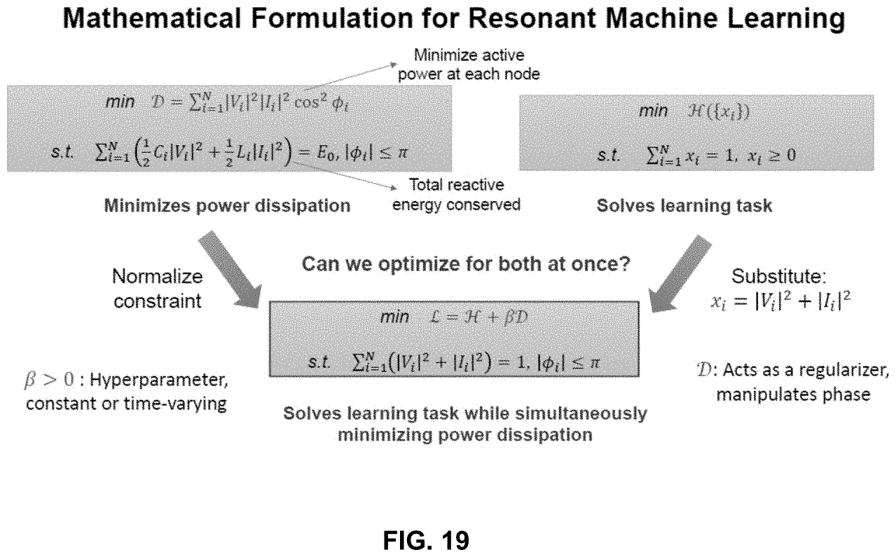

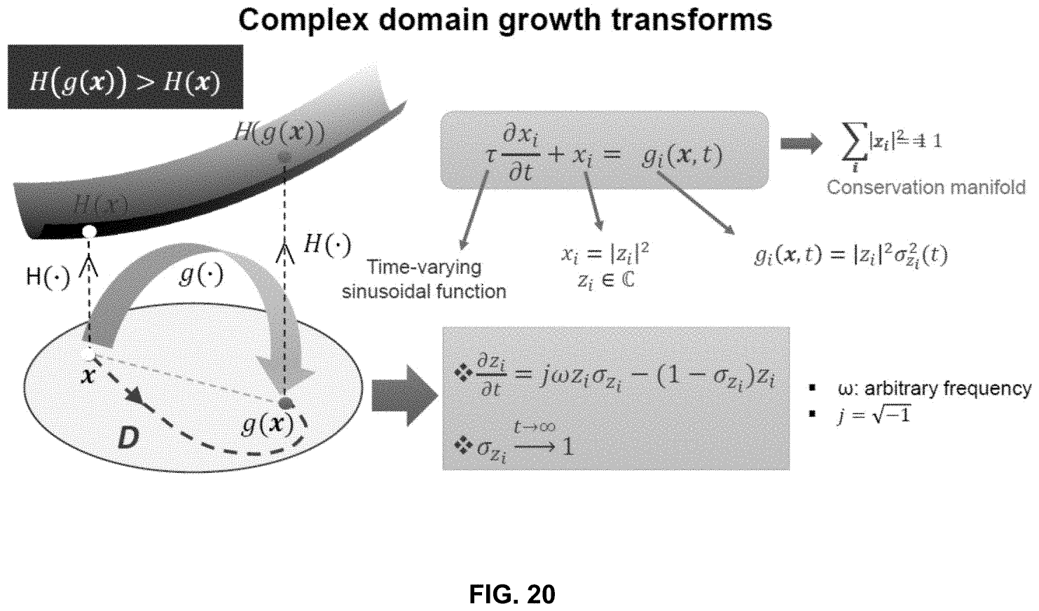

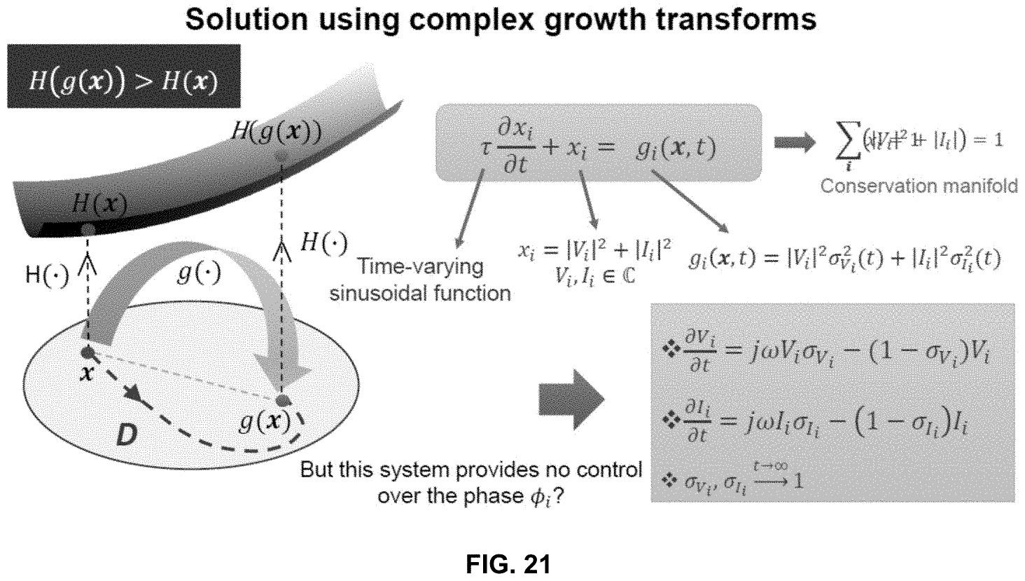

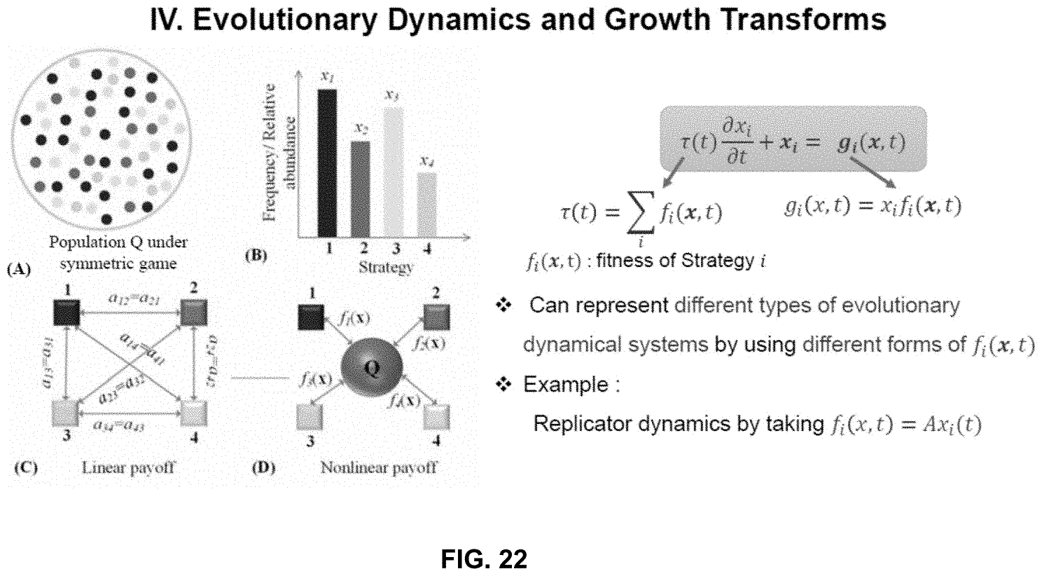

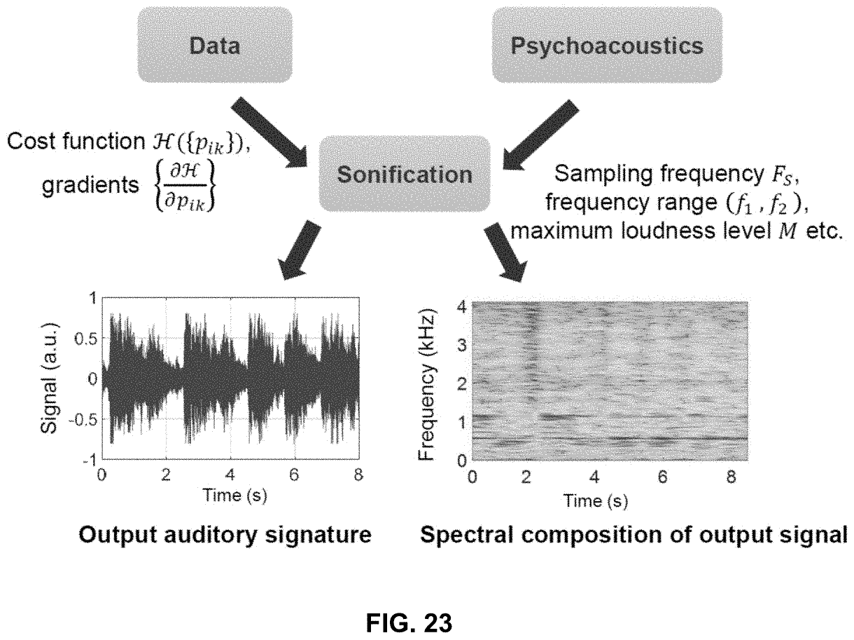

FIG. 15 illustrates an example configuration of a server system 602. Server system 602 may include, but is not limited to, database server 306 and computing device 302 (both shown in FIG. 12). In some aspects, server system 602 is similar to server system 304 (shown in FIG. 12). Server system 602 may include a processor 605 for executing instructions. Instructions may be stored in a memory area 625, for example. Processor 605 may include one or more processing units (e.g., in a multi-core configuration).

Processor 605 may be operatively coupled to a communication interface 615 such that server system 602 may be capable of communicating with a remote device such as user computing device 330 (shown in FIG. 12) or another server system 602. For example, communication interface 615 may receive requests from user computing device 330 via a network 350 (shown in FIG. 12).

Processor 605 may also be operatively coupled to a storage device 625. Storage device 625 may be any computer-operated hardware suitable for storing and/or retrieving data. In some aspects, storage device 625 may be integrated in server system 602. For example, server system 602 may include one or more hard disk drives as storage device 625. In other aspects, storage device 625 may be external to server system 602 and may be accessed by a plurality of server systems 602. For example, storage device 625 may include multiple storage units such as hard disks or solid state disks in a redundant array of inexpensive disks (RAID) configuration. Storage device 625 may include a storage area network (SAN) and/or a network attached storage (NAS) system.

In some aspects, processor 605 may be operatively coupled to storage device 625 via a storage interface 620. Storage interface 620 may be any component capable of providing processor 605 with access to storage device 625. Storage interface 620 may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing processor 605 with access to storage device 625.

Memory areas 510 (shown in FIG. 14) and 610 may include, but are not limited to, random access memory (RAM) such as dynamic RAM (DRAM) or static RAM (SRAM), read-only memory (ROM), erasable programmable read-only memory (EPROM), electrically erasable programmable read-only memory (EEPROM), and non-volatile RAM (NVRAM). The above memory types are example only, and are thus not limiting as to the types of memory usable for storage of a computer program.

The computer systems and computer-implemented methods discussed herein may include additional, less, or alternate actions and/or functionalities, including those discussed elsewhere herein. The computer systems may include or be implemented via computer-executable instructions stored on non-transitory computer-readable media. The methods may be implemented via one or more local or remote processors, transceivers, servers, and/or sensors (such as processors, transceivers, servers, and/or sensors mounted on vehicle or mobile devices, or associated with smart infrastructure or remote servers), and/or via computer executable instructions stored on non-transitory computer-readable media or medium.

In some aspects, a computing device is configured to implement machine learning, such that the computing device “learns” to analyze, organize, and/or process data without being explicitly programmed. Machine learning may be implemented through machine learning (ML) methods and algorithms. In one aspect, a machine learning (ML) module is configured to implement ML methods and algorithms. In some aspects, ML methods and algorithms are applied to data inputs and generate machine learning (ML) outputs. Data inputs may include but are not limited to: images or frames of a video, object characteristics, and object categorizations. Data inputs may further include: sensor data, image data, video data, telematics data, authentication data, authorization data, security data, mobile device data, geolocation information, transaction data, personal identification data, financial data, usage data, weather pattern data, “big data” sets, and/or user preference data. ML outputs may include but are not limited to: a tracked shape output, categorization of an object, categorization of a type of motion, a diagnosis based on motion of an object, motion analysis of an object, and trained model parameters ML outputs may further include: speech recognition, image or video recognition, medical diagnoses, statistical or financial models, autonomous vehicle decision-making models, robotics behavior modeling, fraud detection analysis, user recommendations and personalization, game AI, skill acquisition, targeted marketing, big data visualization, weather forecasting, and/or information extracted about a computer device, a user, a home, a vehicle, or a party of a transaction. In some aspects, data inputs may include certain ML outputs.

In some aspects, at least one of a plurality of ML methods and algorithms may be applied, which may include but are not limited to: linear or logistic regression, instance-based algorithms, regularization algorithms, decision trees, Bayesian networks, cluster analysis, association rule learning, artificial neural networks, deep learning, dimensionality reduction, and support vector machines. In various aspects, the implemented ML methods and algorithms are directed toward at least one of a plurality of categorizations of machine learning, such as supervised learning, unsupervised learning, and reinforcement learning.

In one aspect, ML methods and algorithms are directed toward supervised learning, which involves identifying patterns in existing data to make predictions about subsequently received data. Specifically, ML methods and algorithms directed toward supervised learning are “trained” through training data, which includes example inputs and associated example outputs. Based on the training data, the ML methods and algorithms may generate a predictive function which maps outputs to inputs and utilize the predictive function to generate ML outputs based on data inputs. The example inputs and example outputs of the training data may include any of the data inputs or ML outputs described above.

In another aspect, ML methods and algorithms are directed toward unsupervised learning, which involves finding meaningful relationships in unorganized data. Unlike supervised learning, unsupervised learning does not involve user-initiated training based on example inputs with associated outputs. Rather, in unsupervised learning, unlabeled data, which may be any combination of data inputs and/or ML outputs as described above, is organized according to an algorithm-determined relationship.

In yet another aspect, ML methods and algorithms are directed toward reinforcement learning, which involves optimizing outputs based on feedback from a reward signal. Specifically ML methods and algorithms directed toward reinforcement learning may receive a user-defined reward signal definition, receive a data input, utilize a decision-making model to generate a ML output based on the data input, receive a reward signal based on the reward signal definition and the ML output, and alter the decision-making model so as to receive a stronger reward signal for subsequently generated ML outputs. The reward signal definition may be based on any of the data inputs or ML outputs described above. In one aspect, a ML module implements reinforcement learning in a user recommendation application. The ML module may utilize a decision-making model to generate a ranked list of options based on user information received from the user and may further receive selection data based on a user selection of one of the ranked options. A reward signal may be generated based on comparing the selection data to the ranking of the selected option. The ML module may update the decision-making model such that subsequently generated rankings more accurately predict a user selection.

As will be appreciated based upon the foregoing specification, the above-described aspects of the disclosure may be implemented using computer programming or engineering techniques including computer software, firmware, hardware or any combination or subset thereof. Any such resulting program, having computer-readable code means, may be embodied or provided within one or more computer-readable media, thereby making a computer program product, i.e., an article of manufacture, according to the discussed aspects of the disclosure. The computer-readable media may be, for example, but is not limited to, a fixed (hard) drive, diskette, optical disk, magnetic tape, semiconductor memory such as read-only memory (ROM), and/or any transmitting/receiving medium, such as the Internet or other communication network or link. The article of manufacture containing the computer code may be made and/or used by executing the code directly from one medium, by copying the code from one medium to another medium, or by transmitting the code over a network.

These computer programs (also known as programs, software, software applications, “apps”, or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal used to provide machine instructions and/or data to a programmable processor.

As used herein, a processor may include any programmable system including systems using micro-controllers, reduced instruction set circuits (RISC), application specific integrated circuits (ASICs), logic circuits, and any other circuit or processor capable of executing the functions described herein. The above examples are example only, and are thus not intended to limit in any way the definition and/or meaning of the term “processor.”

As used herein, the terms “software” and “firmware” are interchangeable, and include any computer program stored in memory for execution by a processor, including RAM memory, ROM memory, EPROM memory, EEPROM memory, and non-volatile RAM (NVRAM) memory. The above memory types are example only, and are thus not limiting as to the types of memory usable for storage of a computer program.

In one aspect, a computer program is provided, and the program is embodied on a computer readable medium. In one aspect, the system is executed on a single computer system, without requiring a connection to a sever computer. In a further aspect, the system is being run in a Windows® environment (Windows is a registered trademark of Microsoft Corporation, Redmond, Wash.). In yet another aspect, the system is run on a mainframe environment and a UNIX® server environment (UNIX is a registered trademark of X/Open Company Limited located in Reading, Berkshire, United Kingdom). The application is flexible and designed to run in various different environments without compromising any major functionality.

In some aspects, the system includes multiple components distributed among a plurality of computing devices. One or more components may be in the form of computer-executable instructions embodied in a computer-readable medium. The systems and processes are not limited to the specific aspects described herein. In addition, components of each system and each process can be practiced independent and separate from other components and processes described herein. Each component and process can also be used in combination with other assembly packages and processes. The present aspects may enhance the functionality and functioning of computers and/or computer systems.

Definitions and methods described herein are provided to better define the present disclosure and to guide those of ordinary skill in the art in the practice of the present disclosure. Unless otherwise noted, terms are to be understood according to conventional usage by those of ordinary skill in the relevant art.

In some embodiments, numbers expressing quantities of ingredients, properties such as molecular weight, reaction conditions, and so forth, used to describe and claim certain embodiments of the present disclosure are to be understood as being modified in some instances by the term “about.” In some embodiments, the term “about” is used to indicate that a value includes the standard deviation of the mean for the device or method being employed to determine the value. In some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable. The numerical values presented in some embodiments of the present disclosure may contain certain errors necessarily resulting from the standard deviation found in their respective testing measurements. The recitation of ranges of values herein is merely intended to serve as a shorthand method of referring individually to each separate value falling within the range. Unless otherwise indicated herein, each individual value is incorporated into the specification as if it were individually recited herein. The recitation of discrete values is understood to include ranges between each value.

In some embodiments, the terms “a” and “an” and “the” and similar references used in the context of describing a particular embodiment (especially in the context of certain of the following claims) can be construed to cover both the singular and the plural, unless specifically noted otherwise. In some embodiments, the term “or” as used herein, including the claims, is used to mean “and/or” unless explicitly indicated to refer to alternatives only or the alternatives are mutually exclusive.

The terms “comprise,” “have” and “include” are open-ended linking verbs. Any forms or tenses of one or more of these verbs, such as “comprises,” “comprising,” “has,” “having,” “includes” and “including,” are also open-ended. For example, any method that “comprises,” “has” or “includes” one or more steps is not limited to possessing only those one or more steps and can also cover other unlisted steps. Similarly, any composition or device that “comprises,” “has” or “includes” one or more features is not limited to possessing only those one or more features and can cover other unlisted features.

All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the present disclosure and does not pose a limitation on the scope of the present disclosure otherwise claimed. No language in the specification should be construed as indicating any non-claimed element essential to the practice of the present disclosure.

Groupings of alternative elements or embodiments of the present disclosure disclosed herein are not to be construed as limitations. Each group member can be referred to and claimed individually or in any combination with other members of the group or other elements found herein. One or more members of a group can be included in, or deleted from, a group for reasons of convenience or patentability. When any such inclusion or deletion occurs, the specification is herein deemed to contain the group as modified thus fulfilling the written description of all Markush groups used in the appended claims.

Any publications, patents, patent applications, and other references cited in this application are incorporated herein by reference in their entirety for all purposes to the same extent as if each individual publication, patent, patent application or other reference was specifically and individually indicated to be incorporated by reference in its entirety for all purposes. Citation of a reference herein shall not be construed as an admission that such is prior art to the present disclosure.

Having described the present disclosure in detail, it will be apparent that modifications, variations, and equivalent embodiments are possible without departing the scope of the present disclosure defined in the appended claims. Furthermore, it should be appreciated that all examples in the present disclosure are provided as non-limiting examples.

### EXAMPLES

The following examples illustrate various aspects of the disclosure.

### Example 1: Resonance in an LC Tank

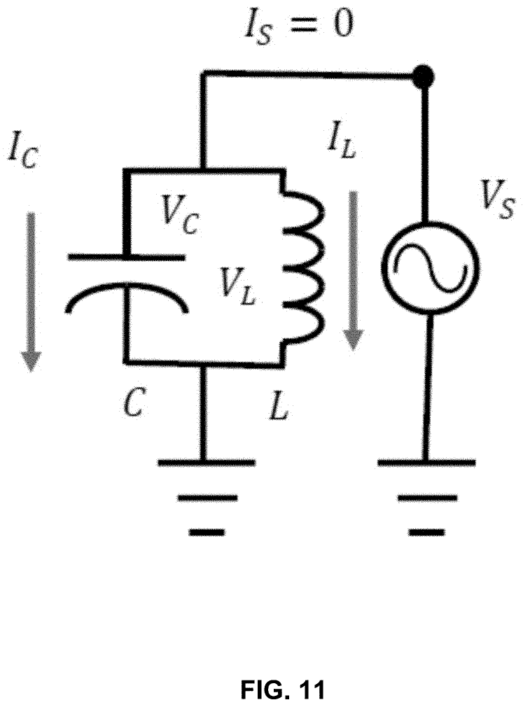

Consider the parallel LC tank circuit shown in FIG. 11, with V_{C} and V_{L} being the voltages across the capacitor C and inductor L respectively. I_{C} and I_{L} denote the corresponding currents flowing through the elements. Thus, V_{S}=V_{L}=V_{C} and I_{S}=I_{L}+I_{C}. Considering the LC tank to be driven by the voltage source V_{S} at a frequency ω, the following condition exists in steady-state:

$${I}_{s} ( ω ) = \frac{{V}_{s} ( ω )}{j ω L} [ 1 - {ω}^{2} L C ] \qquad Eqn . ( 63 )$$

Resonant condition of the circuit is achieved when

$$ω = \frac{1}{\sqrt{L C}} ⇒ {I}_{s} ( ω ) = {0}_{-} \qquad Eqn . ( 64 )$$

This result implies that the apparent power, S_{N}=P_{N}+jQ_{N}=V_{S}I_{S}*+V_{L}I_{L}*+V_{C}I_{C}* where the active power P_{N}=0. Additionally at resonance, the reactive power

$${Q}_{N} = {Q}_{C} + {Q}_{L} = {V}_{L} {I}_{L}^{*} + {V}_{C} {I}_{C}^{*} = - \frac{j}{ω L} {\vert V ( ω ) \vert}^{2} + \frac{j}{ω L} {\vert V ( ω ) \vert}^{2} = 0 .$$

Here Q_{C} and QL are the reactive powers associated with the capacitance and inductance respectively.

### Example 2: Mapping a Generic Optimization Problem to the Equivalent Network Model

Consider an optimization problem defined over a probabilistic domain, given by the following generic form:

$${min}_{\{ {x}_{i} \}} ℋ ( \{ {x}_{i} \} ) s . t . {\sum }_{i = 1}^{N} {x}_{i} = 1 , {x}_{i} \geq 0 \qquad Eqn . ( 65 )$$

Eqn. (65) may be mapped to the electrical network-based model described above by replacing xᵢ=|Vᵢ|²+|Iᵢ|², which leads to the following problem in the {|Vᵢ|², |Iᵢ|²} domain:

$${min}_{\{ \vert {V}_{i} \vert , \vert {I}_{i} \vert \}} ℋ ( \{ \vert {V}_{i} \vert , \vert {I}_{i} \vert \} ) s . t . {\sum }_{i = 1}^{N} ( {\vert {V}_{i} \vert}^{2} + {\vert {I}_{i} \vert}^{2} ) = 1 \qquad Eqn . ( 66 )$$

Note that the method also works for optimization problems defined over non-probabilistic domains, of the following form:

$${min}_{\{ {x}_{i} \}} ℋ ( \{ {x}_{i} \} ) s . t . \vert {x}_{i} \vert \leq 1 , {x}_{i} ∈ ℝ ∀ i = 1 , … , N . \qquad Eqn . ( 67 )$$

This can be done by considering xᵢ=xᵢ⁺−xᵢ⁻ ∀i, where both xᵢ⁺, xᵢ⁻≥0. Since by triangle inequality, |xᵢ|=|xᵢ⁺|+|xᵢ⁻|, enforcing xᵢ⁺+xᵢ⁻=1 ∀i would automatically ensure |xᵢ|≤1 ∀i, resulting in the following expression:

$${arg min}_{\{ {x}_{i} \}} ℋ ( \{ {x}_{i} \} ) ≡ {argmin}_{\{ {x}_{i}^{+} , {x}_{i}^{-} \}} ℋ ( \{ {x}_{i}^{+} , {x}_{i}^{-} \} ) s . t . \vert {x}_{i} \vert \leq 1 , {x}_{i} ∈ ℝ s . t . {x}_{i}^{+} + {x}_{i}^{-} = 1 , {x}_{i}^{+} , {x}_{i}^{-} \geq 0 \qquad Eqn . ( 68 )$$

The replacements xᵢ⁺=|Vᵢ|², xᵢ⁻=|Iᵢ|₂ may be performed to obtain the equivalent problem in the {|Vᵢ|², |Iᵢ|²} domain:

$${argmin}_{\{ \vert {V}_{i} \vert , \vert {I}_{i} \vert \}} ℋ ( \{ \vert {V}_{i} \vert , \vert {I}_{i} \vert \} ) \text{s} . t . {\vert {V}_{i} \vert}^{2} + {\vert {I}_{i} \vert}^{2} = 1 , ∀ i = 1 , … , N \qquad Eqn . ( 69 )$$

For example, the variables {xᵢ} can represent the Lagrangian multipliers in the primal space of a support vector machine network, or the weights and biases of a generic neural network.

### Example 3: Complex Growth Transform Dynamical Systems

Consider the optimization problem in Equation (65) again. We can use the Baum-Eagon inequality to converge to the optimal point of H in steady state, by using updates of the form:

$${x}_{i} ← \frac{{x}_{i} ( \frac{\partial ℋ ( \{ {x}_{i} \} )}{\partial ℋ {x}_{i}} + λ )}{{Σ}_{k = 1}^{N} {x}_{k} ( - \frac{\partial ℋ ( \{ {x}_{k } \} )}{\partial ℋ {x}_{k}} + λ )} , \qquad Eqn . ( 70 )$$

Here, H is assumed Lipschitz continuous on the domain D={xᵢ, . . . , xₙ:Σᵢ₌₁^{N}xᵢ=1, xᵢ≥0 ∀i}⊂ [symbol] ₊^{N}. The constant λ∈R+ is chosen such that

$$\vert - \frac{\partial ℋ ( \{ {x}_{i} \} )}{\partial ℋ {x}_{i}} + λ \vert > 0 , ∀ i .$$

The optimization problem given by Equation (10) may be solved by using the growth transforms discussed above. The outline of the proof is as follows: (1) starting with a generic magnitude domain optimization problem without any phase regularizer, derive the form for the growth trans-form dynamical system which would converge to the optimal point asymptotically; (2) derive a complex domain counterpart of the above, again without phase constraints; (3) derive the complex domain dynamical system by incorporating a phase regularizer in the objective function.

Since the time evolutions of Vᵢ and Iᵢ are symmetric because of the conservation constraints, for the rest of the section we will consider only the update equations for the voltages and similar results would also apply to the updates for Iᵢ.

1) Condition 1: Considering β=0 in Equation (10) and [symbol] {|Vi|, |Ii|}) to be Lipschitz continuous over the domain D=+{|Vᵢ|, |Iᵢ|:Σᵢ₌₁^{N}(|Vᵢ²+|Iᵢ|²)=1}, we can use the growth transforms to arrive at the following discrete-time update equations in terms of the voltage and current magnitudes:

|V_{i,n}|²←g_{V}_{_{i,n−1}}({|V_{i,n-1}|²,|I_{i,n-1}|²}) Eqn. (71)

$$\begin{matrix}{g}_{{V}_{i , n - 1}} ( \{ {\vert {V}_{i , n - 1} \vert}^{2} , {\vert {I}_{i , n - 1} \vert}^{2} \} ) = \frac{{\vert {V}_{i , n - 1} \vert}^{2}}{{μ}_{n - 1}} ( - \frac{\partial ℋ}{\partial {\vert {V}_{i , n - 1} \vert}^{2}} + λ ) & Eqn . ( 72 ) \\ {μ}_{n - 1} = {\sum }_{i = 1}^{N} ( {\vert {V}_{k , n - 1} \vert}^{2} [ - \frac{\partial ℋ}{\partial {\vert {V}_{k , n - 1} \vert}^{2}} + λ ] + {\vert {I}_{k , n - 1} \vert}^{2} [ - \frac{\partial ℋ}{\partial {\vert {I}_{k , n - 1} \vert}^{2}} + λ ] ) & Eqn . ( 73 )\end{matrix}$$

where Δt is the time increment between successive updates. λ∈R+ is chosen to ensure

$$( - \frac{\partial ℋ}{\partial \vert {V}_{i}^{2} \vert} + λ ) > 0 and ( - \frac{\partial ℋ}{\partial \vert {I}_{i}^{2} \vert} + λ ) > 0 , ∀ i .$$

Writing g_{V}_{_{i,n−1}}=g_{V}_{_{i,n−1}}({|V_{i,n-1}|², |I_{i,n-1}|²}) for notational convenience and taking g_{V}_{_{i,n−1}}=|V_{i,n-1}|²σ_{V}_{_{i,n−1}}² the following expression is obtained:

|V_{i,n}|²←|V_{i,n-1}|²σ_{V}_{_{i,n−1}}² Eqn. (74).

Condition 2: Considering β=0 in Equation (10) and

Vᵢ, Iᵢ∈D^{c}={Vᵢ, Iᵢ∈ [symbol] : Σᵢ₌₁^{N}(|Vᵢ|²+|Iᵢ|²)=1}, a time evolution of the form given below converges to limit cycles corresponding to the optimal point of a Lipschitz continuous objective function [symbol] ({|Vᵢ|,|Iᵢ|}):

V_{i,n}←V_{i,n-1}σ_{V}_{_{i,n−1}}e^{jθ},I_{i,n}←I_{i,n-1}σ_{I}_{_{i,n−1}}e^{j(θ+ϕ}^{ᵢ}⁾ Eqn. (75)

where σ_{V}_{ᵢ}, σ_{I}_{₁}→1 ∀i=1, . . . , N in steady state, θ is the instantaneous global phase difference of the system of phasors with respect to an absolute stationary reference frame, and ϕᵢ is the instantaneous phase difference between Vᵢ and Iᵢ.

The expression in Eqn. (75) may be proven as follows. Since

|V_{i,n}|²=V_{i,n}V_{i,n}*,|V_{i,n}²=I_{i,n}I_{i,n}*,

V_{i,n}V_{i,n}*←[V_{i,n-1}σ_{V}_{_{i,n−1}}e^{jθ}]×[V_{i,n-}σ_{V}_{_{i,n−1}}e^{jθ]*}

I_{i,n}I_{i,n}*←[I_{i,n-1}σ_{I}_{_{i,n−1}}e^{j(θ+ϕ}^{ᵢ}⁾]×[I_{i,n-1}σ_{I}_{_{i,n−1}}e^{j(θ+ϕ}si⁾]* Eqn. (76)

where σ_{V}_{_{i,n−1}} is used to represent σ_{V}_{_{i,n−1}}({V_{i,n}V_{i,n}*, I_{i,n},I_{i,n}*}) for ease of notation, and similarly for

Considering [symbol] ({VᵢVᵢ*,IᵢIᵢ*}) to be analytic in D^{C} and applying Wirtinger's calculus, since

$$\frac{\partial ℋ}{\partial {V}_{i , n - 1}} = \frac{\partial ℋ}{\partial {V}_{i , n - 1} {V}_{i , n - 1}^{*}} \cdot ( \frac{\partial {V}_{i , n - 1} {V}_{i , n - 1}^{*}}{\partial {V}_{i , n - 1}} ) = \frac{\partial ℋ}{\partial {V}_{i , n - 1} {V}_{i , n - 1}^{*}} \cdot {V}_{i , n - 1}^{*} \qquad Eqn . ( 77 )$$

the following expression is obtained:

$$\begin{matrix} {σ}_{{V}_{i , n - 1}} = \sqrt{\frac{1}{{η}_{i , n - 1}} ( - \frac{\partial ℋ}{\partial {V}_{i , n - 1}} + λ {V}_{i , n - 1}^{*} )} \\ where & Eqn . ( 78 ) \\ {η}_{i} = {V}_{i , n - 1}^{*} {\sum }_{k = 1}^{N} \text{(} {V}_{k , n - 1} [ - \frac{\partial ℋ}{\partial {V}_{k , n - 1}} + λ {V}_{k , n - 1}^{*} ] + {I}_{k , n - 1} [ - \frac{\partial ℋ}{\partial {I}_{k , n - 1}} + λ {I}_{k , n - 1}^{*} ] & Eqn . ( 79 )\end{matrix}$$

The discrete time update equations for is thus given by:

V_{i,n}←V_{i,n-1}σ_{V}_{_{i,n−1}}e^{jθ} Eqn. (80)

Similar expressions can also be derived for the current phasors.

Lemma: A continuous-time variant of the model given by Equation (75) is given by:

$$\frac{\partial {V}_{i} ( t )}{\partial t} = j ω {σ}_{{V}_{i}} ( t ) {V}_{i} ( t ) - Δ {σ}_{{V}_{i}} ( t ) {V}_{i} ( t ) \qquad Eqn . ( 81 )$$

By way of proof, the difference equations for the voltage phasors are given by:

V_{i,n}−V_{i,n-1}←V_{i,n-1}σ_{V}_{_{i,n−1}}[e^{jθ}−1]+V_{i,n-1}[σ_{V}_{_{i,n−1}}−1] Eqn. (82)

Eqn. (51) may be rewritten as:

V_{i,n}−V_{i,n-1}←V_{i,n-1}σ_{V}_{_{i,n−1}}[e^{jωΔt}−1]−V_{i,n-1}Δσ_{V}_{_{i,n−1}} Eqn. (83)

where Δσ_{V}_{_{i,n−1}}=1−Δσ_{V}_{_{i,n−1}} and θ=ΩΔt, where ω is the common oscillation frequency of all the phasors, and Δt is the time increment.

In the limiting case, when Δt→0, the above expression reduces to the following continuous time differential equation for the complex variable Vᵢ(t):

$$\frac{\partial {V}_{i} ( t )}{\partial t} = j ω {σ}_{{V}_{i}} ( t ) {V}_{i} ( t ) - Δ {σ}_{{V}_{i}} ( t ) {V}_{i} ( t ) \qquad Eqn . ( 84 )$$

In the steady state, since H is Lipschitz continuous in D,

$${σ}_{{V}_{i}} ( t ) {\to }^{t \to ∞} 1 ,$$

the dynamical system above thus reduces to:

$$\frac{\partial {V}_{i} ( t )}{\partial t} = j ω {V}_{i} ( t ) \qquad Eqn . ( 85 )$$

which implies that the steady state response of the complex variable Vᵢ(t) corresponds to steady oscillations with a constant angular frequency of ω.

The difference equations in terms of the nodal currents can be similarly written as:

I_{i,n}−I_{i,n-1}←I_{i,n-1}σ_{I}_{_{i,n−1}}[e^{j(ω+ωϕ}^{ᵢ}^{)Δt}−1]−I_{i,n}Δσ_{I}_{_{i,n−1}}, of Eqn. (86)

where

$${ω}_{{ϕ}_{i}} = \frac{d {ϕ}_{i}}{dt} .$$

The equivalent continuous domain differential equation is then given by:

$$\frac{\partial {I}_{i} ( t )}{\partial t} = j ( ω + {ω}_{{ϕ}_{i}} ) {σ}_{{I}_{i}} ( t ) {I}_{i} ( t ) - Δ {σ}_{{I}_{i}} ( t ) {I}_{i} ( t ) \qquad Eqn . ( 87 )$$

Condition 3: Considering β≠0 in Equation (10), additional phase constraints can be incorporated in the dynamical system represented by using the update rules in Equations (15)-(18). In steady state, for |Vᵢ|²|Iᵢ|² #0, the system settles to ϕᵢ=±π/2 ∀i. Additionally, for sufficiently small values of β (or if β is slowly increased during the optimization process), the system converges to the optimal point of the modified objective function [symbol] ({|Vᵢ|, |Iᵢ|}).

By way of proof, since [symbol] ({|Vᵢ|, |Iᵢ|, ϕᵢ}) is Lipschitz continuous in both |Vᵢ|² and |Iᵢ|², the same form of the update equations proved in Lemma 2 as described above can be applied. For arriving at the updates for the phase angles ϕᵢ, a similar approach to that shown above in Equation (37) may be used. ϕᵢ may be split as ϕᵢ=ϕᵢ⁺−ϕᵢ⁻, ϕᵢ⁺−ϕᵢ⁻ϕᵢ⁺, ϕᵢ⁻>0, which implies that ϕᵢ⁺+ϕᵢ⁻=π. The growth transform dynamical system may then be applied to obtain:

$$\begin{matrix}{τ}_{i} {ω}_{{ϕ}_{i}} + {ϕ}_{i} ( t ) = {g}_{{ϕ}_{i}} ( t ) \\ where \\ {ω}_{{ϕ}_{i}} = \frac{d {ϕ}_{i} ( t )}{{dt }^{-}} \\ and & Eqn . ( 88 ) \\ {g}_{{ϕ}_{i}} = π \frac{{ϕ}_{i}^{+} ( \frac{\partial ℒ}{\partial {ϕ}_{i}^{+}} + λ ) - {ϕ}_{i}^{-} ( \frac{\partial ℒ}{\partial {ϕ}_{i}^{-}} + λ )}{{ϕ}_{i}^{+} ( \frac{\partial ℒ}{\partial {ϕ}_{i}^{+}} + λ ) + {ϕ}_{i}^{-} ( \frac{\partial ℒ}{\partial {ϕ}_{i}^{-}} + λ )} & Eqn . ( 89 )\end{matrix}$$

Since

$$\frac{\partial ℒ}{\partial {ϕ}_{i}} = \frac{\partial ℒ}{\partial {ϕ}_{i}^{+}} = - \frac{\partial ℒ}{\partial {ϕ}_{i}^{{ }^{-}}} ,$$

the above can be simplified to

$${g}_{{ϕ}_{i}} = π \frac{λ {ϕ}_{i} - π \frac{\partial ℒ}{\partial {ϕ}_{i}}}{- {ϕ}_{i} \frac{\partial ℒ}{\partial {ϕ}_{i}} + λ π} .$$

This result implies that the voltage and current phasors corresponding to the i^{th} node in the network may be phase shifted by an additional amount ϕᵢ with respect to the absolute reference.

Since for optimality, ϕᵢ±π/2 for |Vᵢ|²|Iᵢ|²≠0 in the steady state, the net energy dissipation in steady state is zero, i.e., g_{ϕ}_{ᵢ}Σₙ₌₁^{N}|Vᵢ|²|Iᵢ|² cos²ϕᵢ=0. Also, in the steady state, for sufficiently small values of the hyperparameter β,

$${minimize}_{\{ \vert {V}_{i} \vert , \vert {I}_{i} \vert , {ϕ}_{i} \}} ℒ ( \{ \vert {V}_{i} \vert , \vert {I}_{i} \vert , {ϕ}_{i} \} ) \underline{=} {minimize}_{\{ \vert {V}_{i} \vert , \vert {I}_{i} \vert \}} ℋ ( \{ \vert {V}_{i} \vert , \vert {I}_{i} \vert \} ) \qquad Eqn . ( 90 )$$

which implies that the system reaches the optimal solution with zero active power in the post-learning stage.

What is claimed is:

1. A resonant machine learning processor comprising a network of internal nodes, each internal node comprising an LC tank, each LC tank comprising a variable capacitor with capacitance Cᵢ connected electrically in parallel with a variable inductor with inductance Lᵢ, each internal node electrically connected to a ground node and to each remaining internal node of the network of internal nodes, each node further comprising a normalized voltage phasor Vᵢ, a normalized current phasor Iᵢ, and a phase angle ϕᵢ defined across each node of the network of internal nodes, wherein:
a. during learning a plurality of learning parameters, the capacitance Cᵢ and the inductance Lᵢ of each node is modulated to adjust a relative magnitude of the normalized voltage phasor Vᵢ and the normalized current phasor Iᵢ to optimize a total active network power and to maintain a total network reactive network power at essentially zero until a steady state network resonance is achieved; and
b. after completion of learning, the steady state network resonance is maintained, and the plurality of learned network parameters are stored and sustained using resonant magnetic fields and resonant magnetic fields produced within the LC tanks of the network in internal nodes;
wherein the steady state network resonance is maintained without dissipating power.

2. The resonant machine learning processor of claim 1, wherein optimizing the total active network power and maintaining the total network reactive network power at essentially zero comprises modulating the capacitance Cᵢ and the inductance Lᵢ of each internal node according to a system objective function subject to at least one constraint, comprising:
$${mini}_{\{ \vert {V}_{i} \vert , \vert {I}_{i} \vert , {ϕ}_{i} \}} ℒ ( \{ \vert {V}_{i} \vert , \vert {I}_{i} \vert , {ϕ}_{i} \} ) = ℋ ( \{ \vert {V}_{i} \vert , \vert {I}_{i} \vert \} ) + h Ψ ( \{ \vert {V}_{i} \vert , \vert {I}_{i} \vert \} ) + β {\sum }_{i = 1}^{N} {\vert {V}_{i} \vert}^{2} {\vert {I}_{i} \vert}^{2} {cos}^{2} {ϕ}_{i}$$
subject to:
Σᵢ₌₁^{N}(|Vᵢ|²+|Iᵢ|²)=1,|ϕᵢ|≤π,β≥0
wherein: [symbol]
is a loss function defined over the plurality of learning parameters αᵢ=|Vᵢ|²+|Iᵢ|²; Ψ is a regularization or penalty function; h is a hyperparameter that acts as a tradeoff between [symbol] (·) and Ψ(·); β is a hyperparameter that acts as a tradeoff between convergence of the network of internal nodes and dissipation of active power Σᵢ₌₁^{N}|Vᵢ∥Iᵢ|cos ϕᵢ; and N is the number of internal nodes.

3. The resonant machine learning processor of claim 1, wherein the resonant machine learning processor is a resonant support vector machine processor, wherein optimizing the total active network power and maintaining the total network reactive network power at essentially zero comprises modulating the capacitance Cᵢ and the inductance Lᵢ of each internal node according to a system objective function [symbol] _{SVM} subject to at least one constraint, comprising:
$${mini}_{\{ \vert {V}_{i} \vert , \vert {I}_{i} \vert , {ϕ}_{i} \}} {ℒ}_{SVM} = \frac{1}{2} {\sum }_{i = 1}^{N} {\sum }_{j = 1}^{N} ( {\vert {V}_{i} \vert}^{2} + {\vert {I}_{i} \vert}^{2} ) K ( {x}_{i} , {x}_{j} ) \times ( {\vert {V}_{j} \vert}^{2} + {\vert {I}_{j} \vert}^{2} ) + h {\sum }_{i = 1}^{N} Ψ ( \vert {V}_{i} \vert , \vert {I}_{i} \vert , v ) + β {\sum }_{i = 1}^{N} {\vert {V}_{i} \vert}^{2} {\vert {I}_{i} \vert}^{2} {cos}^{2} {ϕ}_{i}$$
subject to:
Σᵢ₌₁^{N}(|Vᵢ|²+|Iᵢ|²)=1,|ϕᵢ|≤π,β≥0
wherein:
the system function [symbol] _{SVM} is defined over a set of learning variables αᵢ=|Vᵢ|²+|Iᵢ|²; K (xᵢ, xⱼ) is a kernel function defined in terms of X=[xᵢ, . . . , xⱼ, . . . , x_{N}]; X is a D-dimensional input dataset of size N; v∈(0,1) is a parameter specifying a size of a control surface; Ψ is a penalty function; h defines a steepness of the penalty function; β is a hyperparameter that acts as a tradeoff between convergence of the plurality of nodes and dissipation of active power Σᵢ₌₁^{N}|Vᵢ∥Iᵢ|cos ϕᵢ; and N is the number of internal nodes.

4. A resonant machine-learning network system comprising a computing device, the computing device comprising at least one processor and a memory storing a plurality of modules, each module comprising instructions executable on the at least one processor, the plurality of modules comprising:
a. a resonant machine learning network module to define a plurality of interconnected nodes, wherein each node comprises a normalized voltage phasor Vᵢ, a normalized current phasor Iᵢ, and a phase angle ϕᵢ defined across each node of the plurality of nodes;
b. a complex growth transform module to update the plurality of nodes according to complex growth transform model; and
c. a resonant network convergence module to converge the plurality of nodes to a steady state solution by optimizing a system objective function [symbol] subject to at least one constraint.

5. The system of claim 4, wherein the system objective function [symbol] subject to at least one constraint comprises:
$${mini}_{\{ \vert {V}_{i} \vert , \vert {I}_{i} \vert , {ϕ}_{i} \}} ℒ ( \{ \vert {V}_{i} \vert , \vert {I}_{i} \vert , {ϕ}_{i} \} ) = ℋ ( \{ \vert {V}_{i} \vert , \vert {I}_{i} \vert \} ) + h Ψ ( \{ \vert {V}_{i} \vert , \vert {I}_{i} \vert \} ) + β {\sum }_{i = 1}^{N} {\vert {V}_{i} \vert}^{2} {\vert {I}_{i} \vert}^{2} {cos}^{2} {ϕ}_{i}$$
subject to:
Σᵢ₌₁^{N}(|Vᵢ|²+|Iᵢ|²)=1,|ϕᵢ|≤π,β≥0
wherein: [symbol]
is a loss function defined over a set of learning variables αᵢ=|Vᵢ|²+|Iᵢ|²; Ψ is a regularization or penalty function; h is a hyperparameter that acts as a tradeoff between [symbol] (·) and Ψ(·); β is a hyperparameter that acts as a tradeoff between convergence of the plurality of nodes and dissipation of active power Σᵢ₌₁^{N}|Vᵢ∥Iᵢ|cos ϕᵢ; and N is the number of interconnected nodes.

6. The system of claim 5, wherein the complex growth transform model comprises a system of update equations, the system of update equations comprising:
$$\frac{\partial {V}_{i} ( t )}{\partial t} = j ω {σ}_{{V}_{i}} ( t ) {v}_{i} ( t ) - Δ {σ}_{{V}_{i}} ( t ) {v}_{i} ( t ) ;$$
$$\frac{\partial {I}_{i} ( t )}{\partial t} = j ( ω + {ω}_{{ϕ}_{i}} ) {σ}_{{I}_{i}} ( t ) {I}_{i} ( t ) - Δ {σ}_{{I}_{i}} ( t ) {I}_{i} ( t ) ;$$
$$and$$
$${τ}_{i} {ω}_{{ϕ}_{i}} + {ϕ}_{i} ( t ) = {g}_{{ϕ}_{i}} ( i ) ;$$
wherein:
$${σ}_{{V}_{i}} ( t ) = \sqrt{\frac{1}{{V}_{i}^{*} η} ( - \frac{\partial ℒ}{\partial {V}_{i}} + λ {V}_{i}^{*} )} ;$$
$${σ}_{{I}_{i}} ( t ) = \sqrt{\frac{1}{{I}_{i}^{*} η} ( - \frac{\partial ℒ}{\partial {I}_{i}} + λ {I}_{i}^{*} )} , \\ {ω}_{{ϕ}_{i}} = \frac{d {ϕ}_{i} ( t )}{dt} , \\ Δ {σ}_{{V}_{i}} ( t ) = 1 - {σ}_{{V}_{i}} ( t ) , \\ Δ {σ}_{{I}_{i}} ( t ) = 1 - {σ}_{{I}_{i}} ( t ) , \\ {g}_{{ϕ}_{i}} ( t ) = π \frac{λ {ϕ}_{i} - π \frac{\partial ℒ}{\partial {ϕ}_{i}}}{- {ϕ}_{i} \frac{\partial ℒ}{\partial {ϕ}_{i}} + λ π} , \\ η = {\sum }_{k = 1}^{N} ( {V}_{k} ( - \frac{\partial ℒ}{\partial {V}_{k}} + λ {V}_{k}^{*} ) + {I}_{k} ( - \frac{\partial ℒ}{\partial {I}_{k}} + λ {I}_{k}^{*} ) )$$
ω is an angular frequency of the plurality of nodes, τᵢ is a time constant associated with the development of ϕᵢ, and ( )* denotes a complex conjugate of a phasor.

7. The system of claim 6, wherein the complex growth transform model further comprises an annealing procedure, the annealing procedure comprising providing a value of β according to an annealing schedule defining a plurality of values of β at a plurality of times during optimization of the system objective function [symbol] subject.

8. The system of claim 7, wherein the annealing schedule is selected from one of:
a. a constant schedule wherein the value of β remains constant;
b. a switching schedule, wherein the value of β switches from a first value to a second value at a switching time; and
c. a logistic schedule, wherein the value of β changes according to a logistic curve.

9. The system of claim 4, wherein the plurality of interconnected nodes is divided into M subgroups, each node comprising the voltage phasor Vᵢₖ, the current phasor Iᵢₖ, and the phase angle ϕᵢₖ defined across each node, wherein k=1, . . . , M.

10. The system of claim 9, wherein the system objective function [symbol] subject to at least one constraint comprises:
$${min}_{\{ \vert {V}_{i k} \vert , \vert {I}_{i k} \vert , {ϕ}_{i k} \} \}} ℒ ( \{ \vert {V}_{i k} \vert , \vert {I}_{i k} \vert , {ϕ}_{i k} \} ) = ℋ ( \{ \vert {V}_{i k} \vert , \vert {I}_{i k} \vert \} ) + h Ψ ( \{ \vert {V}_{i k} \vert , \vert {I}_{i k} \vert \} ) + β {\sum }_{i = 1}^{N} \vert {V}_{i k} {\vert}^{2} \vert {I}_{i k} {\vert}^{2} {cos}^{2} {ϕ}_{i k}$$
subject to:
Σᵢ₌₁^{N}^{ₖ}(|Vᵢₖ|²+|Iᵢₖ|²)=1,|ϕᵢₖ|≤π, and β≥0
wherein: [symbol]
is a loss function defined over the set of learning variables αᵢₖ=|Vᵢₖ|²+|Iᵢₖ|²; Ψ is a regularization or penalty function; h is a hyperparameter that acts as a tradeoff between [symbol] (·) and Ψ(·); β is a hyperparameter that acts as a tradeoff between convergence of the plurality of nodes and dissipation of active power Σᵢ₌₁^{N}|Vᵢₖ∥Iᵢₖ|cos ϕᵢₖ; and Nₖ is the number of interconnected nodes within the k^{th} subgroup.

11. The system of claim 10, wherein the complex growth transform model comprises a system of update equations, the system of update equations comprising:
$$\frac{\partial {V}_{i k} ( t )}{\partial t} = j {ω}_{k} {σ}_{{V}_{i k}} ( t ) {v}_{i k} ( t ) - Δ {σ}_{{V}_{i k}} ( t ) {v}_{i k} ( t ) ;$$
$$\frac{\partial {I}_{i k} ( t )}{\partial t} = j ( {ω}_{k} + {ω}_{{ϕ}_{i k}} ) {σ}_{i k} ( t ) {I}_{i k} ( t ) - {Δσ}_{{I}_{ik}} ( t ) {I}_{i k} ( t ) ;$$
$$and$$
$${τ}_{i k} {ω}_{{ϕ}_{i k}} + {ϕ}_{i k} ( t ) = {g}_{{ϕ}_{i k}} ( t ) ;$$
wherein
$${σ}_{{V}_{i k}} ( t ) = \sqrt{\frac{1}{{V}_{i k}^{*} {η}_{k}} ( - \frac{\partial ℒ}{\partial {V}_{i k}} + λ {V}_{i k}^{*} )} ;$$
$${σ}_{{I}_{i k}} ( t ) = \sqrt{\frac{1}{{I}_{i k}^{*} {η}_{k}} ( - \frac{\partial ℒ}{\partial {I}_{i k}} + λ {I}_{i k}^{*} )} ;$$
$${ω}_{{ϕ}_{i k}} = \frac{d {ϕ}_{i k} ( t )}{dt} ;$$
$$Δ {σ}_{{V}_{i k}} ( t ) = 1 - {σ}_{{V}_{i k}} ( t ) ;$$
$${Δσ}_{{I}_{i k}} ( t ) = 1 - {σ}_{{I}_{i} k} ( t ) ;$$
$${g}_{{ϕ}_{i k}} ( t ) = π \frac{λ {ϕ}_{i k} - π \frac{\partial ℒ}{\partial {ϕ}_{i k}}}{- {ϕ}_{i k} \frac{\partial ℒ}{\partial {ϕ}_{i k}} + λ π} ;$$
$${η}_{k} = {Σ}_{l = 1}^{{N}_{k}} ( {V}_{lk} ( - \frac{\partial ℒ}{\partial {V}_{lk}} + λ {V}_{lk}^{*} ) + {I}_{lk} ( - \frac{\partial ℒ}{\partial {I}_{lk}} + λ {I}_{lk}^{*} ) ) ;$$
ωₖ is an angular frequency of the nodes within the k^{th} subgroup; τᵢₖ is a time constant associated with the development of ϕᵢₖ; and ( )* denotes a complex conjugate of a phasor.

12. The system of claim 4, wherein the system is a resonant SVM system and wherein an SVM system objective function [symbol] _{SVM} subject to at least one constraint comprises:
$${mini}_{\{ \vert {V}_{i} \vert , \vert {I}_{i} \vert , {ϕ}_{i} \}} {ℒ}_{SVM} = \frac{1}{2} {\sum }_{i = 1}^{N} {\sum }_{j = 1}^{N} ( {\vert {V}_{i} \vert}^{2} + {\vert {I}_{i} \vert}^{2} ) K ( {x}_{i} , {x}_{j} ) \times ( {\vert {V}_{j} \vert}^{2} + {\vert {I}_{j} \vert}^{2} ) + h {\sum }_{i = 1}^{N} Ψ ( \vert {V}_{i} \vert , \vert {I}_{i} \vert , v ) + β {\sum }_{i = 1}^{N} {\vert {V}_{i} \vert}^{2} {\vert {I}_{i} \vert}^{2} {cos}^{2} {ϕ}_{i}$$
subject to:
Σᵢ₌₁^{N}(|Vᵢ|²+|Iᵢ|²)=1,|ϕᵢ|≤π,β≥0
wherein:
the SVM system objective function [symbol] _{SVM} is defined over a set of learning variables αᵢ=|Vᵢ|²+|Iᵢ|²; K(xᵢ,xⱼ) is a kernel function defined in terms of X=[xᵢ, . . . , xⱼ, . . . , x_{N}]; X is a D-dimensional input dataset of size N; v∈(0,1) is a parameter specifying a size of a control surface; Ψ is a penalty function; h defines a steepness of the penalty function; β is a hyperparameter that acts as a tradeoff between convergence of the plurality of nodes and dissipation of active power Σᵢ₌₁^{N}|Vᵢ∥Iᵢ|cos ϕᵢ; and N is the number of interconnected nodes.

13. The system of claim 12, wherein the complex growth transform model comprises a system of update equations, the system of update equations comprising:
$$\frac{\partial {V}_{i} ( t )}{\partial t} = j ω {σ}_{{V}_{i}} ( t ) {V}_{i} ( t ) - Δ {σ}_{{V}_{i}} ( t ) {V}_{i} ( t ) ;$$
$$\frac{\partial {I}_{i} ( t )}{\partial t} = j ( ω + {ω}_{{ϕ}_{i}} ) {σ}_{{I}_{i}} ( t ) {I}_{i} ( t ) - Δ {σ}_{{I}_{i}} ( t ) {I}_{i} ( t ) ;$$
$$and$$
$${τ}_{i} {ω}_{{ϕ}_{i}} + {ϕ}_{i} ( t ) = {g}_{{ϕ}_{i}} ( t ) ;$$
wherein
$${σ}_{{V}_{i}} ( t ) = \sqrt{\frac{1}{{V}_{i}^{*} η} ( - \frac{\partial ℒ}{\partial {V}_{i}} + λ {V}_{i}^{*} )} ;$$
$${σ}_{{I}_{i}} ( t ) = \sqrt{\frac{1}{{I}_{i}^{*} η} ( - \frac{\partial ℒ}{\partial {I}_{i}} + λ {I}_{i}^{*} )} ;$$
$${ω}_{{ϕ}_{i}} = \frac{d {ϕ}_{i} ( t )}{dt} ;$$
$${Δσ}_{{V}_{i}} ( t ) = 1 - {σ}_{{V}_{i}} ( t ) ;$$
$${Δσ}_{{I}_{i}} ( t ) = 1 - {σ}_{{I}_{i}} ( t ) ;$$
$${g}_{{ϕ}_{i}} ( t ) = π \frac{λ {ϕ}_{i} - π \frac{\partial ℒ}{\partial {ϕ}_{i}}}{- {ϕ}_{i} \frac{\partial ℒ}{\partial {ϕ}_{i}} + λπ} ;$$
$$η = {\sum }_{k = 1}^{N} ( {V}_{k} ( - \frac{\partial ℒ}{\partial {V}_{k}} + λ {V}_{k}^{*} ) + {I}_{k} ( - \frac{\partial ℒ}{\partial {I}_{k}} + λ {I}_{k}^{*} ) ) ;$$
ω is an angular frequency of the plurality of nodes; τᵢ is a time constant associated with the development of ϕᵢ; and ( ) * denotes a complex conjugate of a phasor.
